(19) United States
(12) Patent Application Publication
(10) Pub. No.: US 2026/0082699 A1
(43) Pub. Date: Mar. 19, 2026

(54) SEMICONDUCTOR DEVICE

(71) Applicant: Semiconductor Energy Laboratory Co., Ltd., Atsugi-shi, Kanagawa-ken (JP)

(72) Inventors: Masami JINTYOU, Shimotsuga (JP); Yukinori SHIMA, Tatebayashi (JP); Junichi KOEZUKA, Tochigi (JP)

(21) Appl. No.: 19/136,998

(22) PCT Filed: Dec. 18, 2023
(86) PCT No.: PCT/IB2023/062848

§ 371 Date: Jun. 9, 2025

(30) Foreign Application Priority Data
Dec. 23, 2022 (JP) 2022-207298

(51) Int. Cl. H10D 86/40; H10D 86/60; H10K 59/121

(52) U.S. Cl. CPC H10D 86/451; H10D 86/423; H10D 86/60; H10D 86/481; H10K 59/1213

(57) ABSTRACT

A semiconductor device including a transistor with a high on-state current is provided. The semiconductor device includes a first transistor, a first insulating layer, and a second insulating layer. The second insulating layer is provided in contact with a top surface of part of the first insulating layer. The first transistor includes a metal oxide layer, a third insulating layer, and a first conductive layer. The metal oxide layer is in contact with a top surface of the first insulating layer and a top surface and a side surface of the second insulating layer. The third insulating layer is in contact with a top surface and a side surface of the metal oxide layer, the top surface of the first insulating layer, and the top surface and the side surface of the second insulating layer. The first conductive layer includes a region overlapping with the side surface of the second insulating layer with the third insulating layer and the metal oxide layer therebetween. The second insulating layer includes a fourth insulating layer and a fifth insulating layer over the fourth insulating layer. The first insulating layer and the fifth insulating layer each contain nitrogen. The fourth insulating layer contains oxygen.

### TECHNICAL FIELD

One embodiment of the present invention relates to a semiconductor device and a manufacturing method thereof. One embodiment of the present invention relates to a transistor and a manufacturing method thereof. One embodiment of the present invention relates to a display device including a semiconductor device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method of driving any of them, and a manufacturing method of any of them.

In this specification and the like, a semiconductor device refers to a device that utilizes semiconductor characteristics, and means a circuit including a semiconductor element (e.g., a transistor, a diode, or a photodiode), a device including the circuit, and the like. The semiconductor device also means any device that can function by utilizing semiconductor characteristics. For example, an integrated circuit, a chip including an integrated circuit, and an electronic component including a chip in a package are examples of the semiconductor device. Moreover, a memory device, a display device, a light-emitting apparatus, a lighting device, and an electronic device themselves are semiconductor devices and each of them includes a semiconductor device in some cases.

### BACKGROUND ART

Semiconductor devices that include transistors are applied to a wide range of electronic devices. Uses for a display device are diversified in recent years, and for example, the display device is used for a portable information terminal, a television device (also referred to as a television receiver), digital signage, and a PID (Public Information Display). Examples of the display device include a display device including an organic EL (Electro Luminescence) element or a light-emitting diode (LED), a display device including a liquid crystal element, and electronic paper performing display by an electrophoretic method.

In a display device, when the area occupied by transistors is reduced, the pixel size can be reduced and definition can be increased. Furthermore, when the area occupied by transistors is reduced, the aperture ratio can be increased. Thus, minute transistors have been required.

As devices requiring high-definition display devices, for example, devices for virtual reality (VR), augmented reality (AR), substitutional reality (SR), or mixed reality (MR) have been actively developed.

Patent Document 1 discloses a high-definition display device using an organic EL element.

### REFERENCE

### Patent Document

[Patent Document 1] PCT International Publication No. 2016/038508

### SUMMARY OF THE INVENTION

### Problems to be Solved by the Invention

One object of one embodiment of the present invention is to provide a transistor having a minute size. Another object is to provide a transistor having a short channel length. Another object is to provide a transistor having a high on-state current. Another object is to provide a transistor having favorable electrical characteristics. Another object is to provide a semiconductor device that occupies a small area. Another object is to provide a semiconductor device having small wiring resistance. Another object is to provide a semiconductor device or a display device having low power consumption. Another object is to provide a transistor, a semiconductor device, or a display device having high reliability. Another object is to provide a high-definition display device. Another object is to provide a method for manufacturing a semiconductor device or a display device having high productivity. Another object is to provide a novel transistor, a novel semiconductor device, a novel display device, and manufacturing methods thereof.

Note that the description of these objects does not preclude the existence of other objects. One embodiment of the present invention does not necessarily achieve all of these objects. Other objects can be derived from the description of the specification, the drawings, and the claims.

### Means for Solving the Problems

One embodiment of the present invention is a semiconductor device including a first transistor, a first insulating layer, and a second insulating layer. The second insulating layer is provided in contact with a top surface of part of the first insulating layer. The first transistor includes a metal oxide layer, a third insulating layer, and a first conductive layer. The metal oxide layer is in contact with a top surface of the first insulating layer and a top surface and a side surface of the second insulating layer. The third insulating layer is in contact with a top surface and a side surface of the metal oxide layer, the top surface of the first insulating layer, and the top surface and the side surface of the second insulating layer. The first conductive layer includes a region overlapping with the side surface of the second insulating layer with the third insulating layer and the metal oxide layer therebetween. The second insulating layer includes a fourth insulating layer and a fifth insulating layer over the fourth insulating layer. The first insulating layer and the fifth insulating layer each contain nitrogen. The fourth insulating layer contains oxygen.

The above-described semiconductor device preferably includes a second transistor. The second transistor preferably includes the metal oxide layer, the third insulating layer, and a second conductive layer. The second conductive layer preferably includes a region overlapping with the side surface of the second insulating layer with the third insulating layer and the metal oxide layer therebetween. The first transistor and the second transistor preferably share the metal oxide layer in a region in contact with the first insulating layer.

The above-described semiconductor device preferably includes a second transistor. The second transistor preferably includes the metal oxide layer, the third insulating layer, and a second conductive layer. The second conductive layer preferably includes a region overlapping with the side surface of the second insulating layer with the third insulating layer and the metal oxide layer therebetween. The first transistor and the second transistor preferably share the metal oxide layer in a region in contact with the fifth insulating layer.

The above-described semiconductor device preferably includes a capacitor. The capacitor preferably includes the metal oxide layer, the third insulating layer, and a second conductive layer over the third insulating layer. The second conductive layer preferably includes a portion overlapping with the third insulating layer in a region in which the metal oxide layer is in contact with the first insulating layer.

The above-described semiconductor device preferably includes a capacitor. The capacitor preferably includes the metal oxide layer, the third insulating layer, and a second conductive layer over the third insulating layer. The second conductive layer preferably includes a portion overlapping with the third insulating layer in a region in which the metal oxide layer is in contact with the fifth insulating layer.

In the above semiconductor device, the second insulating layer preferably includes a sixth insulating layer. The sixth insulating layer is preferably positioned between the first insulating layer and the fourth insulating layer. The sixth insulating layer preferably contains nitrogen. The first insulating layer preferably has a higher hydrogen concentration than the sixth insulating layer.

In the above semiconductor device, the second insulating layer preferably includes a seventh insulating layer. The seventh insulating layer is preferably positioned between the fourth insulating layer and the fifth insulating layer. The seventh insulating layer preferably contains nitrogen. The fifth insulating layer preferably has a higher hydrogen concentration than the seventh insulating layer.

In the above semiconductor device, the third insulating layer preferably includes a layer containing aluminum oxide or silicon nitride.

### Effect of the Invention

One embodiment of the present invention can provide a transistor having a minute size. Alternatively, a transistor having a short channel length can be provided. Alternatively, a transistor having a high on-state current can be provided. Alternatively, a transistor having favorable electrical characteristics can be provided. Alternatively, a semiconductor device that occupies a small area can be provided. Alternatively, a semiconductor device having small wiring resistance can be provided. Alternatively, a semiconductor device or a display device having low power consumption can be provided. Alternatively, a transistor, a semiconductor device, or a display device having high reliability can be provided. Alternatively, a high-definition display device can be provided. Alternatively, a method for manufacturing a semiconductor device or a display device having high productivity can be provided. Alternatively, a novel transistor, a novel semiconductor device, a novel display device, and manufacturing methods thereof can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a top view illustrating an example of a semiconductor device. FIG. 1B is a cross-sectional view illustrating an example of a semiconductor device.

FIG. 2A and FIG. 2B are perspective views illustrating an example of a semiconductor device.

FIG. 3A and FIG. 3B are cross-sectional views illustrating examples of a semiconductor device.

FIG. 4A is a top view illustrating an example of a semiconductor device. FIG. 4B is a cross-sectional view illustrating an example of a semiconductor device.

FIG. 5A and FIG. 5B are perspective views illustrating an example of a semiconductor device.

FIG. 6 is a cross-sectional view illustrating an example of a semiconductor device.

FIG. 7A and FIG. 7B are cross-sectional views illustrating an example of a semiconductor device.

FIG. 8 is a cross-sectional view illustrating an example of a semiconductor device.

FIG. 9A is a cross-sectional view illustrating an example of a semiconductor device. FIG. 9B is a perspective view illustrating an example of a semiconductor device.

FIG. 10A and FIG. 10B are cross-sectional views illustrating examples of a semiconductor device.

FIG. 11A is a top view illustrating an example of a semiconductor device. FIG. 11B is a cross-sectional view illustrating an example of a semiconductor device.

FIG. 12A and FIG. 12B are cross-sectional views illustrating examples of a semiconductor device.

FIG. 13A is a top view illustrating an example of a semiconductor device. FIG. 13B is a perspective view illustrating an example of a semiconductor device.

FIG. 14A is a top view illustrating an example of a semiconductor device. FIG. 14B is a perspective view illustrating an example of a semiconductor device.

FIG. 15A is a top view illustrating an example of a semiconductor device. FIG. 15B is a cross-sectional view illustrating an example of a semiconductor device.

FIG. 16A and FIG. 16B are perspective views illustrating an example of a semiconductor device.

FIG. 17A is a top view illustrating an example of a semiconductor device. FIG. 17B is a cross-sectional view illustrating an example of a semiconductor device.

FIG. 18 is a top view illustrating an example of a semiconductor device.

FIG. 19A and FIG. 19B are diagrams illustrating an example of a semiconductor device.

FIG. 20 is a perspective view illustrating an example of a semiconductor device.

FIG. 21A is a top view illustrating an example of a semiconductor device. FIG. 21B is a cross-sectional view illustrating an example of a semiconductor device.

FIG. 22 is a perspective view illustrating an example of a semiconductor device.

FIG. 23 is a top view illustrating an example of a semiconductor device.

FIG. 24 is a perspective view illustrating an example of a semiconductor device.

FIG. 25A to FIG. 25E are circuit diagrams showing structure examples of semiconductor devices.

FIG. 26 is a top view illustrating an example of a semiconductor device.

FIG. 27 is a cross-sectional view illustrating an example of a semiconductor device.

FIG. 28A and FIG. 28B are perspective views illustrating an example of a semiconductor device.

FIG. 29 is a cross-sectional view illustrating an example of a semiconductor device.

FIG. 30 is a top view illustrating an example of a semiconductor device.

FIG. 31 is a top view illustrating an example of a semiconductor device.

FIG. 32 is a cross-sectional view illustrating an example of a semiconductor device.

FIG. 33A and FIG. 33B are perspective views illustrating an example of a semiconductor device.

FIG. 34A is a top view illustrating an example of a semiconductor device. FIG. 34B is a perspective view illustrating an example of a semiconductor device.

FIG. 35A and FIG. 35B are perspective views illustrating an example of a semiconductor device.

FIG. 36A is a top view illustrating an example of a semiconductor device. FIG. 36B is a perspective view illustrating an example of a semiconductor device.

FIG. 37A and FIG. 37B are perspective views illustrating an example of a semiconductor device.

FIG. 38 is a top view illustrating an example of a semiconductor device.

FIG. 39A and FIG. 39B are cross-sectional views illustrating an example oof a semiconductor device.

FIG. 40 is a perspective view illustrating an example of a semiconductor device.

FIG. 41 is a top view illustrating an example of a semiconductor device.

FIG. 42A and FIG. 42B are cross-sectional views illustrating examples of a semiconductor device.

FIG. 43 is a top view illustrating an example of a semiconductor device.

FIG. 44A and FIG. 44B are cross-sectional views illustrating examples of a semiconductor device.

FIG. 45A and FIG. 45B are equivalent circuit diagrams of a semiconductor device. FIG. 45C is a top view illustrating an example of the semiconductor device.

FIG. 46 is a cross-sectional view illustrating an example of a semiconductor device.

FIG. 47A and FIG. 47B are perspective views illustrating an example of a semiconductor device.

FIG. 48A to FIG. 48E are cross-sectional views illustrating an example of a method for manufacturing a semiconductor device.

FIG. 49A to FIG. 49D are cross-sectional views illustrating an example of a method for manufacturing a semiconductor device.

FIG. 50 is a perspective view illustrating an example of a display device.

FIG. 51A and FIG. 51B are cross-sectional views each illustrating an example of a display device.

FIG. 52 is a cross-sectional view illustrating an example of a display device.

FIG. 53A to FIG. 53C are cross-sectional views illustrating an example of a display device.

FIG. 54A and FIG. 54B are cross-sectional views each illustrating an example of a display device.

FIG. 55 is a cross-sectional view illustrating an example of a display device.

FIG. 56 is a cross-sectional view illustrating an example of a display device.

FIG. 57 is a cross-sectional view illustrating an example of a display device.

FIG. 58 is a cross-sectional view illustrating an example of a display device.

FIG. 59 is a cross-sectional view illustrating an example of a display device.

FIG. 60A to FIG. 60F are cross-sectional views illustrating an example of a method for manufacturing a display device.

FIG. 61A to FIG. 61D are diagrams illustrating examples of electronic devices.

FIG. 62A to FIG. 62F are diagrams illustrating examples of electronic devices.

FIG. 63A to FIG. 63G are diagrams illustrating examples of electronic devices.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and description thereof is not repeated. The same hatching pattern is used for portions having similar functions, and the portions are not especially denoted by reference numerals in some cases.

In this specification and the like, when a plurality of components are denoted with the same reference numerals, and in particular need to be distinguished from each other, an identification sign such as “_1”, “[n]”, or “[m,n]” is sometimes added to the reference numerals. Components denoted with identification signs such as “_1”, “[n]”, and “[m,n]” in the drawings and the like are sometimes described without such identification signs in this specification and the like when the components do not need to be distinguished from each other.

The position, size, range, and the like of each component illustrated in drawings do not represent the actual position, size, range, and the like in some cases for easy understanding. Thus, the disclosed invention is not necessarily limited to the position, size, range, and the like disclosed in the drawings.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or the scope of claims in some cases.

Note that the term “film” and the term “layer” can be used interchangeably depending on the case or the circumstances. For example, the term “conductive layer” can be replaced with the term “conductive film”. As another example, the term “insulating film” can be replaced with the term “insulating layer”.

A transistor is a kind of semiconductor elements and can achieve a function of amplifying current or voltage, a switching operation for controlling conduction or non-conduction, and the like. An IGFET (Insulated Gate Field Effect Transistor) and a thin film transistor (TFT) are in the category of a transistor in this specification.

Functions of a “source” and a “drain” are sometimes replaced with each other when a transistor of opposite polarity is used or when the direction of current is changed in circuit operation, for example. Thus, the terms “source” and “drain” can be switched in this specification and the like. Note that a source and a drain of a transistor can be rephrased as a source terminal and a drain terminal, a source electrode and a drain electrode, or the like as appropriate depending on the circumstances.

In this specification and the like, “electrically connected” includes the case where connection is made through an “object having any electric function”. Here, there is no particular limitation on the “object having any electric function” as long as electric signals can be transmitted and received between components that are connected through the object. Examples of the “object having any electric function” include a switching element such as a transistor, a resistor, a coil, and other elements with a variety of functions as well as an electrode and a wiring.

Unless otherwise specified, off-state current in this specification and the like refers to leakage current between a source and a drain of a transistor in an off state (also referred to as a non-conduction state or a cut-off state). Unless otherwise specified, the off state refers to a state where voltage V_{gs} between a gate and a source is lower than threshold voltage Vₜₕ in an n-channel transistor (higher than Vₜₕ in a p-channel transistor).

In this specification and the like, the expression “having substantially the same top surface shapes” means that at least outlines of stacked layers partly overlap with each other. For example, the case of processing the upper layer and the lower layer with use of the same mask pattern or mask patterns that are partly the same is included. However, in some cases, the outlines do not completely overlap with each other and the upper layer is positioned inward from the lower layer or the upper layer is positioned outward from the lower layer; such a case is also represented by the expression “top surface shapes are substantially the same”. The state of “having the same top surface shape” or “having substantially the same top surface shapes” can be rephrased as the state where “end portions are aligned with each other” or “end portions are substantially aligned with each other”.

In this specification and the like, a tapered shape refers to such a shape that at least part of a side surface of a component is inclined with respect to a substrate surface or a formation surface. For example, the tapered shape preferably includes a region where the angle formed by the inclined side surface and the substrate surface or the formation surface (such an angle is also referred to as a taper angle) is less than 90°. Note that the side surface, the substrate surface, and the formation surface of the component are not necessarily completely flat and may be substantially flat with a slight curvature or substantially flat with slight unevenness.

In this specification and the like, a device formed using a metal mask or an FMM (fine metal mask, high-definition metal mask) may be referred to as a device having an MM (metal mask) structure. In this specification and the like, a device formed without using a metal mask or an FMM may be referred to as a device having an MML (metal maskless) structure. Note that a device having the MML structure can be manufactured without using a metal mask, and thus can break through the resolution limit due to alignment accuracy of the metal mask. Furthermore, the manufacturing facilities for metal masks and washing process for metal masks can be unnecessary in the MML structure. A device having the MML structure can reduce manufacturing costs, and thus is suitable for mass production.

In this specification and the like, a structure in which light-emitting layers of light-emitting elements (also referred to as light-emitting devices) having different emission wavelengths are separately formed is sometimes referred to as an SBS (Side By Side) structure. The SBS structure can optimize materials and structures of light-emitting elements and thus can increase the degree of freedom in selecting materials and structures, so that the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other on the basis of the cross-sectional shape, properties, or the like in some cases. One layer may have two or three functions of the carrier-injection layer, the carrier-transport layer, and the carrier-blocking layer in some cases.

In this specification and the like, the light-emitting element includes an EL layer between a pair of electrodes. The EL layer includes at least a light-emitting layer. Here, examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving element (also referred to as a light-receiving device) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a sacrificial layer (may be referred to as a mask layer) is positioned above at least a light-emitting layer (specifically, a layer processed into an island shape among layers included in an EL layer) and has a function of protecting the light-emitting layer in the manufacturing process.

In this specification and the like, step disconnection refers to a phenomenon in which a layer, a film, or an electrode is split because of the shape of the formation surface (e.g., a step).

### Embodiment 1

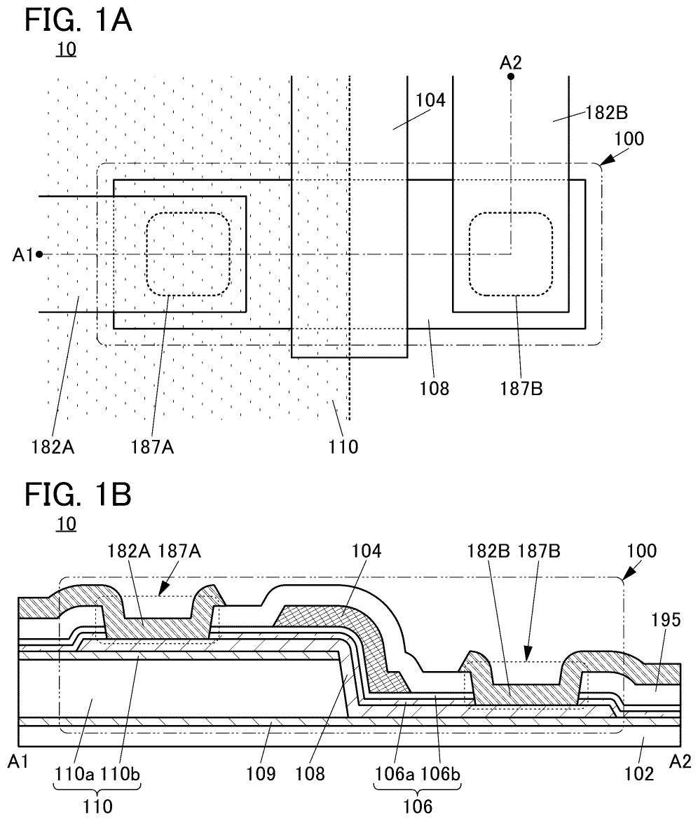

In this embodiment, a semiconductor device of one embodiment of the present invention is described with reference to FIG. 1 to FIG. 47.

One embodiment of the present invention is a semiconductor device including a transistor, a capacitor, a first insulating layer, and a second insulating layer. The second insulating layer is preferably provided in contact with a top surface of part of the first insulating layer. The transistor includes a metal oxide layer, a third conductive layer, and a first conductive layer. The metal oxide layer is in contact with a top surface of the first conductive layer and a top surface and a side surface of the second insulating layer. The third insulating layer functions as a gate insulating layer of the transistor and is in contact with a top surface and a side surface of the metal oxide layer, the top surface of the first insulating layer, and the top surface and the side surface of the second insulating layer. The first conductive layer functions as a gate electrode of the transistor and includes a region overlapping with the side surface of the second insulating layer with the third insulating layer and the metal oxide layer therebetween. The second insulating layer includes a fourth insulating layer and a fifth insulating layer over the fourth insulating layer. The first insulating layer and the fifth insulating layer each contain nitrogen. The fourth insulating layer contains oxygen.

A region of the metal oxide layer that is in contact with the fourth insulating layer functions as a channel formation region of the transistor. The channel formation region is provided along a side surface of the fourth insulating layer. The channel length of the transistor corresponds to the length of the side surface of the fourth insulating layer in contact with the metal oxide layer in a cross-sectional view. Thus, the channel length can be a value smaller than the resolution limit of a light exposure apparatus, which enables the transistor to have a minute size. This enables the transistor to have a high on-state current.

When impurities from the first insulating layer are supplied to a region of the metal oxide layer that is in contact with the first insulating layer, the region has an increased carrier concentration, resulting in higher conductivity. This enables the region to function as one of a source electrode and a drain electrode of the transistor. Similarly, when impurities from the fifth insulating layer are supplied to a region of the metal oxide layer that is in contact with the fifth insulating layer, the region has an increased carrier concentration, resulting in higher conductivity. This enables the region to function as the other of the source electrode and the drain electrode of the transistor. When the metal oxide layer includes the region functioning as the source electrode and the region functioning as the drain electrode, it is not necessary to provide a source electrode and a drain electrode separately from the metal oxide layer, which reduces the area occupied by the semiconductor device.

### Structure Example 1

### Structure Example 1-1

FIG. 1A illustrates a top view (also referred to as a plan view) of a semiconductor device 10 of one embodiment of the present invention. FIG. 1B shows a cross-sectional view of a cut plane along the dashed-dotted line A1-A2 in FIG. 1A. Note that in FIG. 1A, some components (a gate insulating layer and the like) of the semiconductor device 10 are not illustrated. Some components are not illustrated in top views of transistors in the following drawings, as in FIG. 1A.

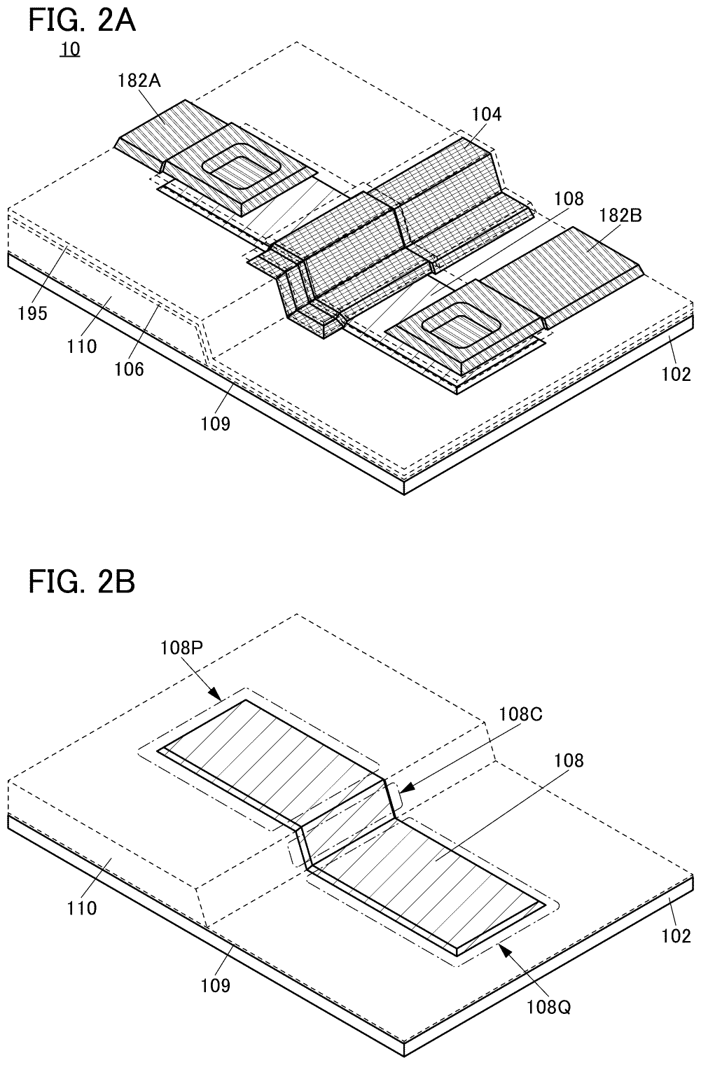

FIG. 2A is a perspective view of the semiconductor device 10. In FIG. 2A, insulating layers are transparent and their outlines are indicated by dashed lines.

The semiconductor device 10 includes a transistor 100, an insulating layer 109, and an insulating layer 110. The insulating layer 109 is provided over a substrate 102, and the insulating layer 110 is provided over the insulating layer 109. The insulating layer 110 is provided in contact with a top surface of part of the insulating layer 109, and an end portion of the insulating layer 110 is in contact with the top surface of the insulating layer 109. It can also be said that the semiconductor device 10 includes a region where the insulating layer 110 is provided and a region where the insulating layer 110 is not provided. The transistor 100 is provided over the insulating layer 109 and the insulating layer 110. The transistor 100 is provided across the region where the insulating layer 110 is provided and the region where the insulating layer 110 is not provided.

The transistor 100 includes a conductive layer 104, an insulating layer 106, and a layer 108. The layer 108 contains a semiconductor material. The layer 108 includes a channel formation region, a region functioning as a source electrode, and a region functioning as a drain electrode. In the transistor 100, part of the insulating layer 106 functions as a gate insulating layer (also referred to as a first gate insulating layer), and the conductive layer 104 functions as a gate electrode (also referred to as a first gate electrode).

FIG. 2B is a perspective view selectively illustrating the substrate 102, the insulating layer 109, the insulating layer 110, and the layer 108. As illustrated in FIG. 1A, FIG. 1B, FIG. 2A, and FIG. 2B, the layer 108 is provided across the region where the insulating layer 110 is provided and the region where the insulating layer 110 is not provided. It can also be said that the layer 108 includes a region overlapping with the insulating layer 110 and a region not overlapping with the insulating layer 110. The layer 108 is provided along a step due to the region where the insulating layer 110 is provided and the region where the insulating layer 110 is not provided. The layer 108 includes a region in contact with a top surface and a side surface of the insulating layer 110 and the top surface of the insulating layer 109. The layer 108 has a shape along the shapes of the top surface and the side surface of the insulating layer 110 and the top surface of the insulating layer 109.

The insulating layer 106 is provided over the layer 108, the insulating layer 109, and the insulating layer 110. The insulating layer 106 includes a region in contact with a top surface and a side surface of the layer 108, a top surface of the insulating layer 109, and a top surface and the side surface of the insulating layer 110. The insulating layer 106 has a shape along the shapes of the top surface and the side surface of the layer 108, the top surface of the insulating layer 109, and the top surface of the insulating layer 110.

The conductive layer 104 is provided over the insulating layer 106 and includes a region in contact with the top surface of the insulating layer 106. The conductive layer 104 is provided along the step due to the region where the insulating layer 110 is provided and the region where the insulating layer 110 is not provided. The conductive layer 104 includes a region overlapping with the side surface of the insulating layer 110 with the insulating layer 106 and the layer 108 therebetween.

A semiconductor material used for the layer 108 is not particularly limited. For example, a single-element semiconductor or a compound semiconductor can be used. Examples of the single-element semiconductor include silicon and germanium. Examples of the compound semiconductor include gallium arsenide and silicon germanium. Other examples of the compound semiconductor include an organic semiconductor, a nitride semiconductor, and an oxide semiconductor. These semiconductor materials may include an impurity as a dopant.

There is no particular limitation on the crystallinity of a semiconductor material used for the layer 108, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case degradation of the transistor characteristics can be inhibited.

Silicon can be used for the layer 108. Examples of silicon include single crystal silicon, polycrystalline silicon, microcrystalline silicon, and amorphous silicon. An example of polycrystalline silicon is low-temperature polysilicon (LTPS). A transistor including amorphous silicon in a channel formation region can be formed over a large glass substrate, and can be manufactured at low cost. A transistor including polycrystalline silicon in a channel formation region has high field-effect mobility and enables high-speed operation. A transistor including microcrystalline silicon in a channel formation region has higher field-effect mobility and enables higher speed operation than a transistor including amorphous silicon.

The layer 108 preferably contains a metal oxide (also referred to as an oxide semiconductor) exhibiting semiconductor characteristics. In the case where a metal oxide is used for the layer 108, the layer 108 can be referred to as a metal oxide layer.

The bandgap of a metal oxide used for the layer 108 is preferably greater than or equal to 2.0 eV, further preferably greater than or equal to 2.5 eV.

A transistor including an oxide semiconductor (hereinafter referred to as an OS transistor) has much higher field-effect mobility than a transistor including amorphous silicon. In addition, the OS transistor has an extremely low off-state current, and charge accumulated in a capacitor that is connected in series to the transistor can be retained for a long period. Furthermore, the power consumption of the semiconductor device can be reduced with the OS transistor.

The insulating layer 110 and insulating layer 109 each preferably include one or more inorganic insulating films. Examples of a material that can be used for the inorganic insulating film include an oxide, a nitride, an oxynitride, and a nitride oxide. Examples of the oxide include silicon oxide, aluminum oxide, magnesium oxide, gallium oxide, germanium oxide, yttrium oxide, zirconium oxide, lanthanum oxide, neodymium oxide, hafnium oxide, tantalum oxide, cerium oxide, gallium zinc oxide, and hafnium aluminate. Examples of the nitride include silicon nitride and aluminum nitride. Examples of the oxynitride include silicon oxynitride, aluminum oxynitride, gallium oxynitride, yttrium oxynitride, and hafnium oxynitride. Examples of the nitride oxide include silicon nitride oxide and aluminum nitride oxide. The insulating layer 110 and the insulating layer 109 may be formed using the same material or different materials.

Note that in this specification and the like, an oxynitride refers to a material that contains more oxygen than nitrogen in its composition. A nitride oxide refers to a material that contains more nitrogen than oxygen in its composition.

Note that in this specification and the like, different materials mean materials, the constituent elements of which are partially or entirely different from each other, or materials having the same constituent elements and different compositions.

The insulating layer 110 includes a region in contact with the layer 108. In the case where a metal oxide is used for the layer 108, at least part of the region of the insulating layer 110 that is in contact with the layer 108 preferably contains oxygen to improve the characteristics of the interface between the layer 108 and the insulating layer 110. Specifically, the portion of the insulating layer 110 that is in contact with the channel formation region in the layer 108 preferably contains oxygen. One or more of an oxide and an oxynitride can be suitably used for the portion of the insulating layer 110 that is in contact with the channel formation region in the layer 108.

The insulating layer 110 preferably has a stacked-layer structure. FIG. 1B and the like illustrate an example in which the insulating layer 110 includes an insulating layer 110a and an insulating layer 110b over the insulating layer 110a. For each of the insulating layer 110a and the insulating layer 110b, a material that can be used for the insulating layer 110 and the insulating layer 109 can be used. The layer 108 is in contact with the top surface of the insulating layer 109, a side surface of the insulating layer 110a, and a top surface and a side surface of the insulating layer 110b.

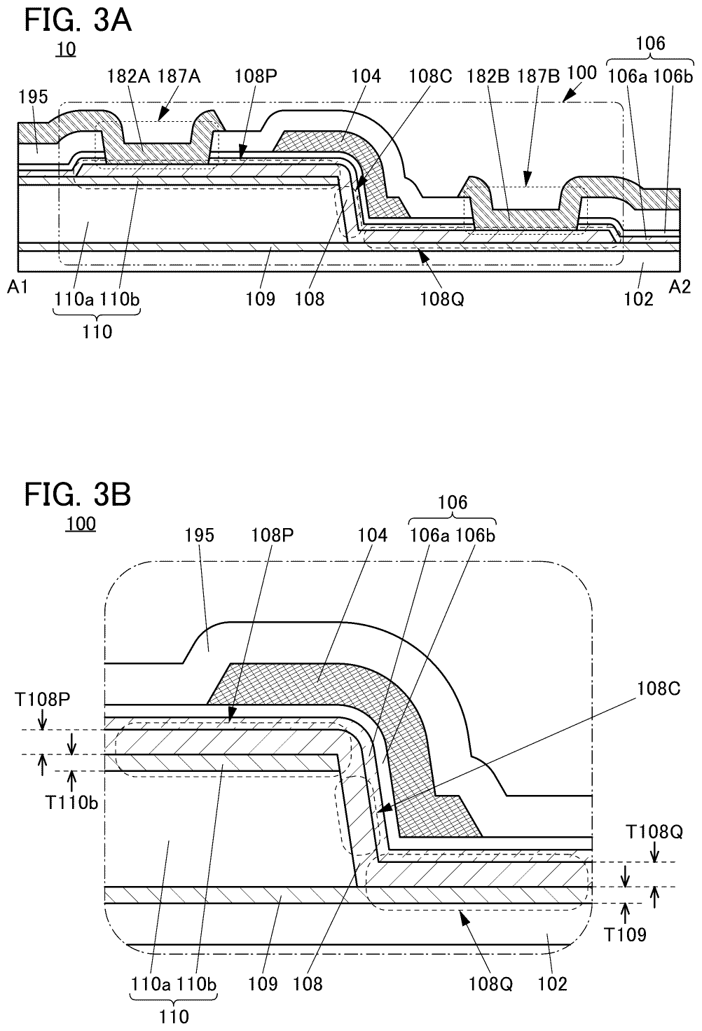

As illustrated in FIG. 3A, the layer 108 includes a region 108C in contact with the insulating layer 110a. The region 108C functions as the channel formation region of the transistor 100. Since the layer 108 is in contact with the side surface of the insulating layer 110a, the region 108C is provided in the portion of the layer 108 that is in contact with the side surface of the insulating layer 110a. That is, the channel formation region is provided along the side surface of the insulating layer 110a. The conductive layer 104 functioning as the gate electrode includes a region overlapping with the region 108C with the insulating layer 106 functioning as the gate insulating layer therebetween. In addition, the conductive layer 104 includes a region overlapping with the side surface of the insulating layer 110a with the insulating layer 106 and the layer 108 therebetween.

It is preferable to use any one or more of the oxide and oxynitride described above for the insulating layer 110a. Specifically, one or both of silicon oxide and silicon oxynitride can be suitably used for the insulating layer 110a.

A film from which oxygen is released by heating is further preferably used as the insulating layer 110a. When oxygen is released from the insulating layer 110a by heat applied during the manufacturing process of the transistor 100, the oxygen can be supplied to the layer 108. Supply of oxygen from the insulating layer 110a to the layer 108, particularly to the region 108C functioning as the channel formation region, can repair oxygen vacancies (V_{O}), resulting in reduced oxygen vacancies (V_{O}); accordingly, the transistor can have favorable electrical characteristics and high reliability.

For example, the insulating layer 110a can be supplied with oxygen when heat treatment in an atmosphere containing oxygen or plasma treatment in an atmosphere containing oxygen is performed. Alternatively, an oxide film may be formed over the top surface of the insulating layer 110a by a sputtering method in an atmosphere containing oxygen to supply oxygen. After that, the oxide film may be removed. Note that Embodiment 2 described later shows an example in which oxygen is supplied to the insulating layer 110a by forming a metal oxide layer 130.

The insulating layer 110a is preferably formed by a film formation method such as a sputtering method or a plasma-enhanced chemical vapor deposition (PECVD) method. In particular, by a sputtering method not using a gas containing hydrogen as a film formation gas, a film having an extremely low hydrogen content can be formed. Consequently, supply of hydrogen to the region 108C is inhibited and the electrical characteristics of the transistor 100 can be stabilized.

Here, the use of a material having high conductivity for the layer 108 enables the transistor to have a high on-state current. However, the use of a material having high conductivity facilitates the formation of oxygen vacancies (V_{O}); the increased oxygen vacancies (V_{O}) in the channel formation region shift the threshold voltage of the transistor, which might increase the drain current flowing at a gate voltage of 0 V (hereinafter also referred to as cut-off current). For example, a shift of the threshold voltage in the negative direction might increase the cut-off current in the case of an n-channel transistor. Provision of the insulating layer 110a enables oxygen supply to at least the region 108C of the layer 108 that is in contact with the insulating layer 110a, i.e., the channel formation region, reducing the oxygen vacancies (V_{O}) in the channel formation region. This inhibits a shift of the threshold voltage and allows the transistor to have both a low cut-off current and a high on-state current. Consequently, a semiconductor device that achieves both low power consumption and high performance can be provided.

The layer 108 includes a region 108P in contact with the uppermost layer of the insulating layer 110 (here, the insulating layer 110b). The region 108P functions as one of the source electrode and the drain electrode of the transistor 100. The layer 108 includes a region 108Q in contact with the insulating layer 109. The region 108Q functions as the other of the source electrode and the drain electrode of the transistor 100.

For the insulating layer 110b in contact with the region 108P, a material that releases impurities is preferably used. In the case of using a metal oxide for the layer 108, one or more of hydrogen, boron, carbon, nitrogen, fluorine, phosphorus, sulfur, arsenic, aluminum, magnesium, silicon, and a noble gas can be used as an element included in the impurities (hereinafter also referred to as an impurity element). Typical examples of a noble gas include helium, neon, argon, krypton, and xenon. The impurity element is preferably one or more of hydrogen, boron, phosphorus, aluminum, magnesium, and silicon, and hydrogen is particularly preferable. Specifically, for the insulating layer 110b, a material that releases one or both of hydrogen and water is preferably used. Note that in this specification and the like, hydrogen is sometimes described as an example of the impurity.

Oxygen bonded to a metal atom contained in the metal oxide reacts with hydrogen to be water, and thus forms an oxygen vacancy (V_{O}) in the metal oxide. Moreover, a defect where hydrogen enters an oxygen vacancy (hereinafter referred to as V_{O}H) functions as a donor and generates an electron functioning as a carrier. Bonding of part of hydrogen to oxygen bonded to a metal atom generates an electron functioning as a carrier. Accordingly, the metal oxide exhibits conductivity and can function as a conductor. Note that a metal oxide functioning as a conductor can be referred to as an oxide conductor (OC). In general, a metal oxide has a wide band gap and thus transmits visible light (i.e., a metal oxide has a visible-light-transmitting property). In addition, an oxide conductor is a metal oxide having a donor level in the vicinity of the conduction band. Therefore, an oxide conductor is less affected by absorption due to the donor level and has a visible-light-transmitting property comparable to that of a metal oxide.

When impurities released from the insulating layer 110b diffuse into the region 108P, the region 108P has a high carrier concentration and high conductivity. Accordingly, the region 108P functions as a conductor, and the region 108P can function as one of the source electrode and the drain electrode in the transistor 100.

The region 108P contains an element (impurity element) included in impurities released from the insulating layer 110b. Specifically, in the case of using a material that releases one or both of hydrogen and water from the insulating layer 110b, the region 108P contains hydrogen as an impurity element.

For the insulating layer 109 in contact with the region 108Q, a material that releases impurities is preferably used. For elements of the impurities (impurity elements), the description of the insulating layer 110d can be referred to. Note that the impurities released from the insulating layer 110d may be the same as or different from the impurities released from the insulating layer 109.

When impurities released from the insulating layer 109 diffuse into the region 108Q, the region 108Q has a high carrier concentration and high conductivity. Accordingly, the region 108Q functions as a conductor, and the region 108Q can function as the other of the source electrode and the drain electrode in the transistor 100.

The region 108Q contains an element (impurity element) included in impurities released from the insulating layer 109. Specifically, in the case of using a material that releases one or both of hydrogen and water from the insulating layer 109, the region 108Q contains hydrogen as an impurity element.

In the transistor 100, the region 108C of the layer 108 that is in contact with the insulating layer 110a functions as the channel formation region, and oxygen supplied from the insulating layer 110a reduces oxygen vacancies (V_{O}). Thus, the transistor can have favorable electrical characteristics. Meanwhile, the region 108P of the layer 108 that is in contact with the insulating layer 110b has high conductivity when supplied with impurities from the insulating layer 110b, and can function as one of the source electrode and the drain electrode. Meanwhile, the region 108Q of the layer 108 that is in contact with the insulating layer 109 has high conductivity when supplied with impurities from the insulating layer 109, and can function as the other of the source electrode and the drain electrode.

Since parts of the layer 108 (here, the region 108P and the region 108Q) function as the source electrode and the drain electrode, it is not necessary to provide the source electrode and the drain electrode separately from the layer 108, which reduces the area occupied by the semiconductor device. In addition, the manufacturing process of the semiconductor device can be simplified to reduce the manufacturing cost, and the yield of the semiconductor device can be increased.

Each of the region 108P functioning as one of the source electrode and the drain electrode and the region 108Q functioning as the other thereof preferably includes a region having a higher impurity element concentration than the region 108C functioning as the channel formation region. Specifically, each of the region 108P and the region 108Q preferably includes a portion having a higher hydrogen concentration than the region 108C. The impurity concentrations of the region 108P and the region 108Q may be the same or different from each other.

Each of a thickness T108P of the region 108P and a thickness T108Q of the region 108Q in the layer 108 are preferably greater than or equal to 5 nm and less than or equal to 500 nm, further preferably greater than or equal to 10 nm and less than or equal to 300 nm, still further preferably greater than or equal to 15 nm and less than or equal to 200 nm, yet still further preferably greater than or equal to 20 nm and less than or equal to 150 nm, yet still further preferably greater than or equal to 20 nm and less than or equal to 120 nm, yet still further preferably greater than or equal to 20 nm and less than or equal to 100 nm, for example. As illustrated in FIG. 3B, the thickness T108P can be the shortest distance between the top surface of the insulating layer 110 (specifically, the top surface of the insulating layer 110b) and the top surface of the layer 108 in the cross-sectional view. The thickness T108Q can be the shortest distance between the top surface of the insulating layer 109 and the top surface of the layer 108 in the cross-sectional view. Note that the thickness T108P and the thickness T108Q may be the same or different from each other.

When the thickness T108P is small, the electric resistance of the region 108P functioning as one of the source electrode and the drain electrode might be increased. Similarly, when the thickness T108Q of the region 108Q is small, the electric resistance of the region 108Q functioning as the other of the source electrode and the drain electrode might be increased. Meanwhile, when the thickness T108P and the thickness T108Q are large, the region 108C also has a large thickness and oxygen vacancies (V_{O}) in the channel formation region might be increased. With each of the thickness T108P and the thickness T108Q within the above range, the electric resistance of one of the source electrode and the drain electrode can be reduced and the transistor can have favorable electrical characteristics.

The sheet resistance (also referred to as surface resistivity or plane resistivity) of each of the region 108P and the region 108Q is preferably less than or equal to 1000 Ω/square (also referred to as Ω/sq), further preferably less than or equal to 500 Ω/square, still further preferably less than or equal to 300 Ω/square, yet still further preferably less than or equal to 200 Ω/square, yet still further preferably less than or equal to 100 Ω/square. Note that each of the region 108P and the region 108Q preferably has low electric resistance, so that the lower limit of the sheet resistance is not limited. The sheet resistances of the region 108P and the region 108Q may be the same or different from each other.

As described above, a material that releases impurities is preferably used for each of the insulating layer 110b in contact with the region 108P and the insulating layer 109 in contact with the region 108Q. For each of the insulating layer 110b and the insulating layer 109, any one or more of the oxide, oxynitride, nitride, and nitride oxide described above can be used. The insulating layer 110b and the insulating layer 109 each preferably contain nitrogen, and any one or more of the nitride and nitride oxide described above are preferably used. Specifically, silicon nitride or silicon nitride oxide can be suitably used for each of the insulating layer 110b and the insulating layer 109. Note that the insulating layer 110b and the insulating layer 109 may be formed using the same material or different materials.

The amount of impurities released from the insulating layer 110b can be adjusted by the thickness of the insulating layer 110b. Specifically, by increasing the thickness of the insulating layer 110b, the amount of impurities released from the insulating layer 110b is increased, so that the electrical resistivity of the region 108P can be reduced. Similarly, the amount of impurities released from the insulating layer 109 can be adjusted by the thickness of the insulating layer 109. As illustrated in FIG. 3B, a thickness T110b of the insulating layer 110b can be the shortest distance between the formation surface of the insulating layer 110b (here, the top surface of the insulating layer 110a) and the bottom surface of the layer 108 in the cross-sectional view. A thickness T109 of the insulating layer 109 can be the shortest distance between the formation surface of the insulating layer 109 (here, the top surface of the substrate 102) and the bottom surface of the layer 108 in the cross-sectional view. For example, the thickness of each of the insulating layer 110b and the insulating layer 109 is preferably greater than or equal to 10 nm and less than or equal to 500 nm, further preferably greater than or equal to 20 nm and less than or equal to 400 nm, further preferably greater than or equal to 50 nm and less than or equal to 300 nm, further preferably greater than or equal to 70 nm and less than or equal to 200 nm, further preferably greater than or equal to 70 nm and less than or equal to 150 nm, further preferably greater than or equal to 70 nm and less than or equal to 120 nm. Note that the thickness T110b and the thickness T109 may be the same or different from each other.

Here, impurities released from the insulating layer 110b diffuse into the region 108C through the region 108P in some cases. Similarly, impurities released from the insulating layer 109 diffuse into the region 108C through the region 108Q in some cases. However, since oxygen vacancies (V_{O}) in the region 108C are reduced by oxygen supplied from the insulating layer 110a, an increase in V_{O}H is inhibited in the region 108C even when impurities diffuse into the region 108C. In addition, even if oxygen vacancies (V_{O}) and V_{O}H are generated in the region 108C due to impurities diffusing into the region 108C, the oxygen vacancies (V_{O}) and V_{O}H are repaired by oxygen supplied from the insulating layer 110a; thus, an increase in oxygen vacancies (V_{O}) and V_{O}H is inhibited in the region 108C. Thus, at least the region 108C of the layer 108 that is in contact with the insulating layer 110a functions as the channel formation region, and the transistor can have favorable electrical characteristics and high reliability. Note that in the layer 108, an oxygen diffusion coefficient is smaller than a hydrogen diffusion coefficient, so that oxygen released from the insulating layer 110a does not easily increase the electric resistance of the region 108P and the region 108Q. Accordingly, the electric resistance of the region 108P and the region 108Q can be kept low.

In the case where the thickness T110b and the thickness T109 are large and the amount of impurities diffusing from the insulating layer 110b into the region 108C through the region 108P and the amount of impurities diffusing from the insulating layer 109 into the region 108C through the region 108Q are too large, the amount of oxygen vacancies (V_{O}) and V_{O}H generated by the impurities might be larger than the amount of oxygen vacancies (V_{O}) and V_{O}H repaired by oxygen supplied from the insulating layer 110a. By contrast, when the thickness T110b is small, the amount of impurities diffusing into the region 108P is reduced, which might increase the electric resistance of the region 108P. Similarly, when the thickness T109 is small, the amount of impurities diffusing into the region 108Q is reduced, which might increase the electric resistance of the region 108Q. The thickness T110b and the thickness T109 that are each within the above range can inhibit an increase in oxygen vacancies (V_{O}) and V_{O}H in the channel formation region and reduce the electric resistance of the region 108P and the region 108Q.

The impurity element concentration in each of the insulating layer 110b and the insulating layer 109 is preferably higher than or equal to 1×10²¹ atoms/cm³ and lower than or equal to 1× 10²³ atoms/cm³, further preferably higher than or equal to 1× 10²¹ atoms/cm³ and lower than or equal to 5×10²² atoms/cm³, still further preferably higher than or equal to 5×10²¹ atoms/cm³ and lower than or equal to 5×10²² atoms/cm³. Specifically, the hydrogen concentrations in each of the insulating layer 110b and the insulating layer 109 is preferably higher than or equal to 1×10²¹ atoms/cm³ and lower than or equal to 1×10²³ atoms/cm³, further preferably higher than or equal to 1×10²¹ atoms/cm³ and lower than or equal to 5×10²² atoms/cm³, still further preferably higher than or equal to 5×10²¹ atoms/cm³ and lower than or equal to 5×10²² atoms/cm³.

The impurity element concentration varies in the thickness direction of the layer (also referred to as “the layer has a concentration gradient”) in some cases. In the case where the impurity element concentration is analyzed in the thickness direction of the layer, the maximum value of the concentration in the layer is preferably within the range given above.

The insulating layer 110b and the insulating layer 109 having high impurity element concentrations might lead to excessively increased amounts of impurities diffusing from the insulating layer 110b to the region 108C through the region 108P and impurities diffusing from the insulating layer 109 to the region 108C through the region 108Q. When the impurity element concentrations in the insulating layer 110b and the insulating layer 109 are in the above range, the electrical resistance of the region 108P and the region 108Q can be reduced and an increase in oxygen vacancies (V_{O}) and V_{O}H in the region 108C can be inhibited.

Preferably, each of the insulating layer 110b and the insulating layer 109 is less likely to transmit oxygen. When the insulating layer 110a is interposed between the insulating layer 110b and the insulating layer 109, oxygen contained in the insulating layer 110a can be inhibited from diffusing to the insulating layer 110b side and from diffusing to the insulating layer 109 side, which increases the amount of oxygen supplied to the region 108C from the insulating layer 110a, reducing oxygen vacancies (V_{O}) and V_{O}H in the channel formation region. For example, silicon nitride or silicon nitride oxide can be suitably used for each of the insulating layer 110b and the insulating layer 109.

Here, although the structure is illustrated in which the insulating layer 110 has a two-layer structure including the insulating layer 110a and the insulating layer 110b, one embodiment of the present invention is not limited thereto. A structure may be employed in which the insulating layer 110a is not provided. The insulating layer 110 preferably includes at least the insulating layer 110a. Moreover, the insulating layer 110 may have a stacked-layer structure of three or more layers.

The region 108C functioning as the channel formation region of the transistor 100 includes a portion that overlaps with the conductive layer 104 functioning as the gate electrode with the insulating layer 106 functioning as the gate insulating layer therebetween. The conductive layer 104 is provided to cover the side surface of the insulating layer 110 in a region overlapping with the layer 108.

There is no particular limitation on the shape of the end portion of the insulating layer 110 though the shape is shown as a straight line in the top view (also referred to as plan view) in FIG. 1A and the like. The shape of the end portion of the insulating layer 110 may include a curve or a corner in the top view, for example. In the case where the shape of the end portion of the insulating layer 110 includes a curve, the layer 108 may be provided in the portion of the curve; in the case where the shape includes a corner, the layer 108 may be provided in the portion of the corner. There is no particular limitation on the top surface shape of the layer 108 though the top surface shape is rectangular in FIG. 1A and the like.

An insulating layer 195 is provided to cover the transistor 100 and the transistor 100a. The insulating layer 195 functions as a protective layer of the transistor 100 and the transistor 100a. For the insulating layer 195, a material that does not easily allow diffusion of impurities is preferably used. Provision of the insulating layer 195 can effectively inhibit diffusion of impurities into the transistor 100 from the outside and increase the reliability of the semiconductor device 10. Examples of the impurities include water and hydrogen. The insulating layer 195 includes, for example, one or both of an inorganic insulating layer and an organic insulating layer. The insulating layer 195 may have a stacked-layer structure of an inorganic insulating layer and an organic insulating layer.

Examples of a material that can be used for the inorganic insulating film included in the insulating layer 195 include an oxide, a nitride, an oxynitride, and a nitride oxide. Specific examples of a material that can be used for the inorganic insulating film are as listed in the description of the insulating layer 110 and the insulating layer 109. More specifically, one or more of silicon nitride, silicon nitride oxide, silicon oxynitride, aluminum oxide, aluminum oxynitride, aluminum nitride, hafnium oxide, and hafnium aluminate can be used for the insulating layer 195. One or both of an acrylic resin and a polyimide resin, which are organic materials, can be used for the insulating layer 195.

The insulating layer 195 and the insulating layer 106 have an opening 187A reaching the region 108P and an opening 187B reaching the region 108Q. A conductive layer 182A is provided to cover the opening 187A, and the conductive layer 182A is in contact with the region 108P in the opening 187A. In other words, the conductive layer 182A is electrically connected to one of the source electrode and the drain electrode of the transistor 100. A conductive layer 182B is provided to cover the opening 187B, and the conductive layer 182B is in contact with the region 108Q in the opening 187B. In other words, the conductive layer 182B is electrically connected to the other of the source electrode and the drain electrode of the transistor 100. The conductive layer 182A and the conductive layer 182B each function as a wiring.

The conductive layer 182A and the conductive layer 182B each functioning as a wiring are provided over the insulating layer 195. In the opening 187A and the opening 187B provided in the insulating layer 195 and the insulating layer 106, the conductive layer 182A and the conductive layer 182B are respectively in contact with the region 108P and the region 108Q, which function as the source electrode and the drain electrode of the transistor 100. The conductive layer 182A and the conductive layer 182B are provided in a layer different from the conductive layer 104. Accordingly, the wirings can be placed in their respective layers, leading to high layout flexibility and a reduction in the area occupied by a circuit. Note that the conductive layer 182A and the conductive layer 182B may be formed using the same layer as the conductive layer 104. For example, after the opening reaching the region 108P and the opening reaching the region 108Q are provided in the insulating layer 106, a film to be the conductive layer 104, the conductive layer 182A, and the conductive layer 182B is formed and the film is processed, whereby the conductive layer 104, the conductive layer 182A, and the conductive layer 182B can be formed. Accordingly, the manufacturing process of the semiconductor device can be simplified to reduce the manufacturing cost, and the yield of the semiconductor device can be increased.

There is no limitation on the top surface shape of the opening 187A and the opening 187B, and the shape can be a circular shape; an elliptical shape; a polygonal shape such as a triangular shape, a tetragonal shape (including a rectangular shape, a rhombic shape, and a square shape), or a pentagonal shape; or any of these polygonal shapes whose corners are rounded, for example. Note that the polygonal shape can be either a concave polygonal shape (a polygonal shape at least one of the interior angles of which is greater than) 180° or a convex polygonal shape (a polygonal shape all the interior angles of which are less than or equal to) 180°.

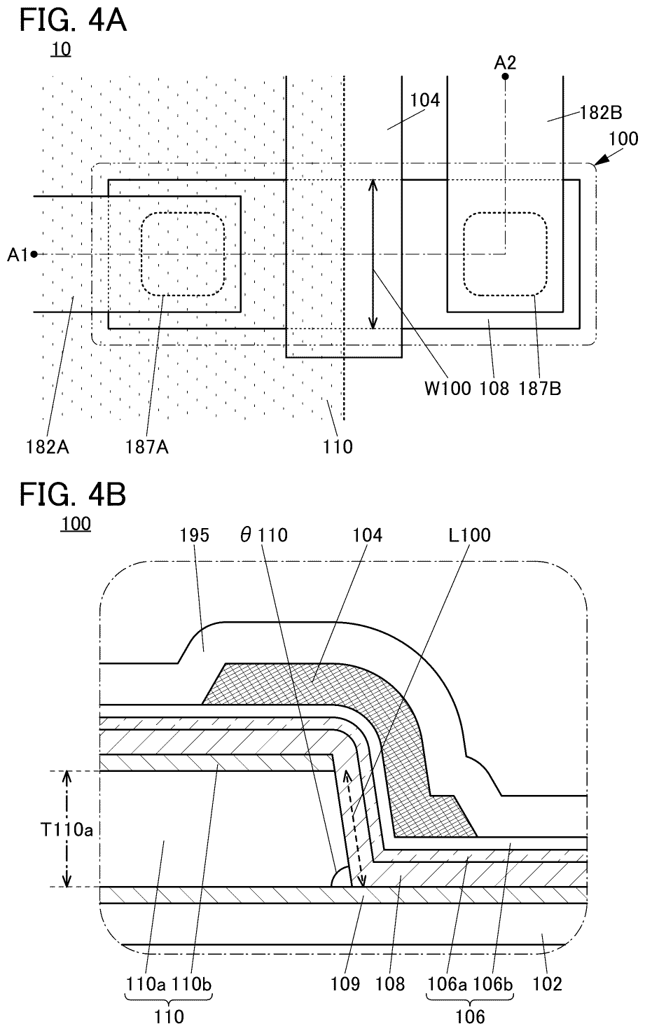

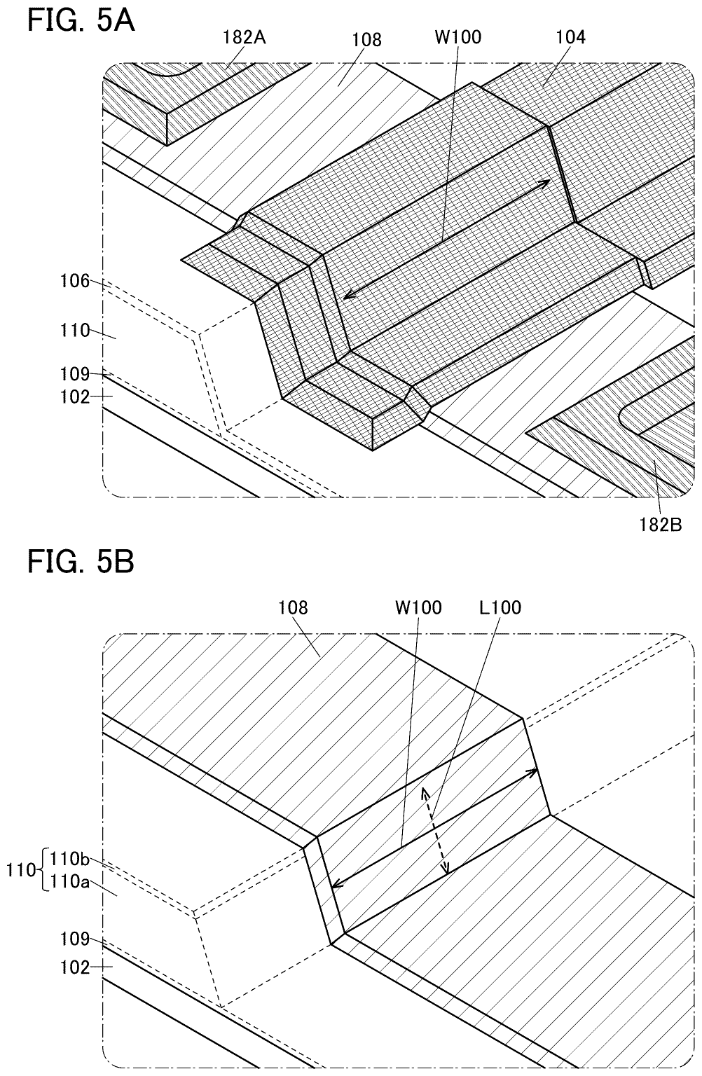

The channel length and channel width of the transistor 100 are described with reference to FIG. 4A to FIG. 5B. FIG. 4A is a top view, and FIG. 4B is an enlarged view of FIG. 1B. FIG. 5A is an enlarged view of FIG. 2A, and FIG. 5B is an enlarged view of FIG. 2B. Note that the insulating layer 195 is omitted in FIG. 5A.

In FIG. 4B and FIG. 5B, a channel length L100 of the transistor 100 is indicated by a dashed double-headed arrow. The channel length L100 of the transistor 100 corresponds to the length of the side surface of the region of the insulating layer 110a that is in contact with the layer 108 in the cross-sectional view. In other words, the channel length L100 depends on a thickness T110a of the insulating layer 110a and the angle θ110 formed by the side surface of the insulating layer 110a and the formation surface of the insulating layer 110a (which is the top surface of the insulating layer 109 here). Thus, for example, the channel length L100 can have a value smaller than that of the resolution limit of a light-exposure apparatus, which enables a transistor having a minute size. Specifically, it is possible to form a transistor with an extremely short channel length that cannot be achieved with a conventional light-exposure apparatus for mass production of flat panel displays (the minimum line width: approximately 2 μm or approximately 1.5 μm, for example). Moreover, a transistor with a channel length less than 10 nm can also be achieved without using an extremely expensive light-exposure apparatus used in the latest LSI technology.

The channel length L100 can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm. For example, the channel length L100 can be greater than or equal to 100 nm and less than or equal to 1 mm.

The reduction in the channel length L100 can increase the on-state current of the transistor 100. With use of the transistor 100, a circuit capable of high-speed operation can be manufactured. Furthermore, the area occupied by the circuit can be reduced. Thus, a small semiconductor device can be obtained. The application of the semiconductor device of one embodiment of the present invention to a large display device or a high-definition display device can reduce signal delay in wirings and reduce display unevenness even if the number of wirings is increased, for example. In addition, since the area occupied by the circuit can be reduced, the bezel of the display device can be narrowed.

By adjusting the thickness T110a and the angle θ110 of the insulating layer 110a, the channel length L100 can be controlled. In FIG. 4B, the thickness T110a of the insulating layer 110a is indicated by a dashed-dotted double-headed arrow.

The thickness T110a of the insulating layer 110a may be set as appropriate in consideration of a desired channel length L100. The thickness T110a of the insulating layer 110a can be, for example, greater than or equal to 5 nm, greater than or equal to 7 nm, or greater than or equal to 10 nm and can be less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm.

The angle θ110 is preferably less than or equal to 90°, further preferably less than 90°. By reducing the angle θ110, the coverage with a layer (e.g., the layer 108) formed over the insulating layer 110a can be improved. The smaller the angle θ110 is, the longer the channel length L100 is. The larger the angle θ110 is, the shorter the channel length L100 is.

The angle θ110 can be, for example, greater than or equal to 30°, greater than or equal to 35°, greater than or equal to 40°, greater than or equal to 45°, greater than or equal to 50°, greater than or equal to 55°, greater than or equal to 60°, greater than or equal to 65°, or greater than or equal to 70° and less than or equal to 90°, less than or equal to 85°, or less than or equal to 80°. The angle θ110 may be less than or equal to 75°, less than or equal to 70°, less than or equal to 65°, or less than or equal to 60°.

Although FIG. 1B and the like illustrate the structure in which the side surface of the insulating layer 110a is linear in the cross-sectional view, one embodiment of the present invention is not limited thereto. In the cross-sectional view, the side surface of the insulating layer 110 may be curved, or the side surface may include both a linear region and a curved region.

The channel width of the transistor 100 is the width of the region where the layer 108 and the conductive layer 104 overlap with each other in the direction orthogonal to the channel length direction. In FIG. 4A, FIG. 5A, and FIG. 5B, a channel width W100 of the transistor 100 is indicated by a solid double-headed arrow.

The width W100 varies in the depth direction in some cases. As the channel width W100, for example, the average value of the following three widths can be used: the width at the highest level of the insulating layer 110a in a cross-sectional view, the width at the lowest level of the insulating layer 110a in a cross-sectional view, and the width at the midpoint between these levels. Alternatively, as the channel width W100, for example, any of the width at the highest level of the insulating layer 110a in a cross-sectional view, the width at the lowest level of the insulating layer 110a in a cross-sectional view, and the width at the midpoint between these levels may be used.

In the case where the layer 108 and the conductive layer 104 are formed by a photolithography method, the channel width W100 is larger than or equal to the resolution limit of a light-exposure apparatus. The channel width W100 can be, for example, greater than or equal to 200 nm, greater than or equal to 300 nm, greater than or equal to 400 nm, or greater than or equal to 500 nm and can be less than 5 μm, less than or equal to 4.5 μm, less than or equal to 4 μm, less than or equal to 3.5 μm, less than or equal to 3 μm, less than or equal to 2.5 μm, less than or equal to 2 μm, less than or equal to 1.5 μm, or less than or equal to 1 μm.

When the channel length L100 of the transistor 100 is short, the amount of hydrogen released from the insulating layer 110b and the amount of hydrogen released from the insulating layer 109 are each preferably small. Specifically, the thickness T110b of the insulating layer 110b and the thickness T109 of the insulating layer 109 are each preferably small. For example, when the channel length L100 is less than or equal to 100 nm, the thickness T110b and the thickness T109 are each preferably greater than or equal to 1 nm and less than or equal to 50 nm, further preferably greater than or equal to 3 nm and less than or equal to 40 nm, still further preferably greater than or equal to 3 nm and less than or equal to 30 nm, yet still further preferably greater than or equal to 3 nm and less than or equal to 20 nm, yet still further preferably greater than or equal to 3 nm and less than or equal to 10 nm, yet still further preferably greater than or equal to 5 nm and less than or equal to 10 nm. Accordingly, the amount of hydrogen diffusing into the region 108C can be reduced, and the transistor can have favorable electrical characteristics and high reliability even with the short channel length L100.

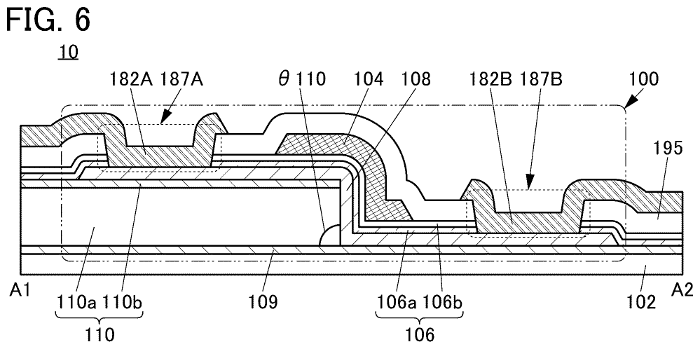

Although the angle θ110 of the insulating layer 110a is less than 90° in FIG. 1B and the like, one embodiment of the present invention is not limited thereto. As illustrated in FIG. 6, the angle θ110 may be 90° or approximately 90°. Accordingly, the channel length L100 of the transistor 100 can be made shorter. Thus, the area occupied by the semiconductor device can be reduced.

The transistor 100 is what is called a top-gate transistor including the gate electrode above the region 108C functioning as the channel formation region. In the transistor 100, the source electrode and the drain electrode are positioned at different heights from the surface of the substrate 102 over which the transistor 100 is formed, and drain current flows in a direction perpendicular or substantially perpendicular to the surface of the substrate 102. It can be also said that drain current flows in the vertical direction or the substantially vertical direction in the transistor 100. Accordingly, the transistor of one embodiment of the present invention can be referred to as a vertical-channel transistor or a vertical field-effect transistor (VFET).

The channel length of the transistor 100 can be controlled by the thickness of the insulating layer 110 (specifically, the insulating layer 110a). Accordingly, a transistor with a channel length smaller than the resolution limit of a light exposure apparatus used for manufacturing the transistor can be manufactured with high accuracy. Furthermore, variations in characteristics among a plurality of the transistors 100 are also reduced. Accordingly, the operation of the semiconductor device including the transistor 100 can be stabilized and the reliability thereof can be improved. When the variations in characteristics are reduced, the circuit design flexibility is increased and the operation voltage of the semiconductor device can be reduced. Thus, the power consumption of the semiconductor device can be reduced.

In the transistor of one embodiment of the present invention, since the layer 108 includes the channel formation region, the region functioning as a source electrode, and the region functioning as a drain electrode, it is not necessary to provide a source electrode and a drain electrode separately from the layer 108, which reduces the area occupied by the semiconductor device. Furthermore, since the source electrode and the drain electrode are provided at different heights and the channel formation region is provided in the region in contact with the side surface of the insulating layer 110a, the occupied area can be significantly smaller than that occupied by a so-called planar transistor in which a layer including the channel formation region, the source electrode, and the drain electrode are arranged in a planar shape.

When the semiconductor device of one embodiment of the present invention is used for a pixel circuit of a display device, the area occupied by the pixel circuit can be reduced and a high-definition display device can be provided, for example. When the semiconductor device of one embodiment of the present invention is used for a driver circuit (e.g., one or both of a gate line driver circuit and a source line driver circuit) of a display device, the area occupied by the driver circuit can be reduced and the display device can have a narrow bezel.

### [Layer 108]

Metal oxides that can be used for the layer 108 are specifically described. Examples of the metal oxide include indium oxide, gallium oxide, and zinc oxide. The metal oxide preferably contains at least indium or zinc. The metal oxide preferably contains two or three elements selected from indium, an element M, and zinc. The element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably any one or more kinds of the above elements, further preferably one or more kinds selected from aluminum, gallium, tin, and yttrium, and still further preferably one or more kinds of gallium and tin. In this specification and the like, a metal element and a metalloid element may be collectively referred to as a “metal element”, and a “metal element” described in this specification and the like may refer to a metalloid element.

For example, for the layer 108, an indium zinc oxide (In—Zn oxide), an indium tin oxide (also referred to as In—Sn oxide or ITO), an indium titanium oxide (In—Ti oxide), an indium gallium oxide (In—Ga oxide), an indium tungsten oxide (also referred to as In—W oxide or IWO), an indium gallium aluminum oxide (In—Ga—Al oxide), an indium gallium tin oxide (also referred to as In—Ga—Sn oxide), a gallium zinc oxide (also referred to as Ga—Zn oxide or GZO), an aluminum zinc oxide (also referred to as Al—Zn oxide or AZO), an indium aluminum zinc oxide (also referred to as In—Al—Zn oxide or IAZO), an indium tin zinc oxide (also referred to as In—Sn—Zn oxide or ITZO (registered trademark)), an indium titanium zinc oxide (In—Ti—Zn oxide), an indium gallium zinc oxide (also referred to as In—Ga—Zn oxide or IGZO), an indium gallium tin zinc oxide (also referred to as In—Ga—Sn—Zn oxide or IGZTO), or an indium gallium aluminum zinc oxide (also referred to as In—Ga—Al—Zn oxide, IGAZO, IGZAO, or IAGZO) can be used. Alternatively, an indium tin oxide containing silicon (also referred to as ITSO), gallium tin oxide (Ga—Sn oxide), an aluminum tin oxide (Al—Sn oxide), or the like can be used.

By increasing the proportion of the number of indium atoms in the total number of atoms of all the metal elements contained in the metal oxide, the field-effect mobility of the transistor can be increased. In addition, the transistor can have a high on-state current.

Note that the metal oxide may contain, instead of indium or in addition to indium, one or more kinds of metal elements belonging to a period of a higher number in the periodic table. The larger the overlap between orbits of metal elements is, the more likely it is that the metal oxide will have high carrier conductivity. Thus, a transistor including a metal element belonging to a period of a higher number in the periodic table can have high field-effect mobility in some cases. Examples of the metal element belonging to a period of a higher number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. By containing a nonmetallic element, the metal oxide sometimes has an increased carrier concentration, a reduced band gap, or the like, in which case the transistor can have increased field-effect mobility. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor is suppressed, and the reliability of the transistor can be increased.

By increasing the proportion of the number of element M atoms in the total number of atoms of all the metal elements contained in the metal oxide, oxygen vacancies (V_{O}) can be inhibited from being formed in the metal oxide. Accordingly, generation of carriers due to oxygen vacancies (V_{O}) is inhibited, which makes the off-state current of the transistor low. Furthermore, a change in electrical characteristics of the transistor is suppressed, and the reliability of the transistor can be increased.

Electrical characteristics and reliability of a transistor depend on the composition of the metal oxide used for the layer 108. Thus, by varying the composition of the metal oxide in accordance with the electrical characteristics and reliability required for the transistor, the semiconductor device can have both good electrical characteristics and high reliability.

When a metal oxide is In-M-Zn oxide, the atomic proportion of In is preferably higher than or equal to the atomic proportion of the element M in the In-M-Zn oxide. Examples of the atomic ratio of the metal elements of such In-M-Zn oxide include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:1, In:M:Zn=10:1:3, In:M:Zn=10:1:4, In:M:Zn=10:1:6, In:M:Zn=10:1:7, In:M:Zn=10:1:8, In:M:Zn=5:2:5, In:M:Zn=10:1:10, In:M:Zn=20:1:10, and In:M:Zn=40:1:10 and a composition in the neighborhood of any of these atomic ratios. Note that a composition in the neighborhood includes the range of ±30% of an intended atomic ratio. By increasing the atomic proportion of indium in the metal oxide, the on-state current, field-effect mobility, or the like of the transistor can be increased.

The atomic proportion of In may be lower than the atomic proportion of the element M in the In-M-Zn oxide. Examples of the atomic ratio of the metal elements in such In-M-Zn oxide include In:M:Zn=1:3:2, In:M:Zn=1:3:3, and In:M:Zn=1:3:4 and a composition in the neighborhood of any of these atomic ratios. By increasing the atomic proportion of M in the metal oxide, generation of oxygen vacancies (V_{O}) can be inhibited.

In the case where a plurality of metal elements are contained as the element M, the sum of the proportions of the numbers of atoms of the metal elements can be the proportion of the number of element M atoms.

In this specification and the like, the proportion of the number of indium atoms in the total number of atoms of all the metal elements contained is sometimes referred to as the content percentage of indium. The same applies to other metal elements.

The use of a material with a high content percentage of indium for the layer 108 enables an increase in the on-state current, field-effect mobility, or the like of the transistor. Furthermore, with the element M, generation of oxygen vacancies (V_{O}) can be inhibited. The content percentage of the element M (the proportion of the number of element M atoms in the total number of atoms of all the metal elements contained) is preferably greater than or equal to 0.1% and less than or equal to 3% or less than or equal to 2%. Accordingly, the transistor can have favorable electrical characteristics. For example, a metal oxide with In:M:Zn=40:1:10 or the neighborhood thereof is preferably used. The element M is preferably any one or more kinds of the above elements, further preferably one or more kinds selected from aluminum, gallium, tin, and yttrium. Specifically, a metal oxide with In:Sn:Zn=40:1:10 or the neighborhood thereof can be suitably used. Alternatively, a metal oxide with In:Al:Zn=40:1:10 or the neighborhood thereof can be suitably used.

Here, in the case where a metal oxide having a polycrystalline structure is used for the layer 108, the crystal grain boundary becomes a recombination center and captures carriers and thus decreases the on-state current of the transistor, in some cases. In the case where a metal oxide with a composition that tends to form a polycrystalline structure is used, the metal oxide preferably contains an element that hinders crystallization. For example, indium tin oxide containing silicon (ITSO) is less likely to have a polycrystalline structure than indium tin oxide (ITO) and can be suitably used for the layer 108. In the case where ITSO is used, the content percentage of silicon (the proportion of the number of silicon atoms in the total number of atoms of all the metal elements contained) is preferably higher than or equal to 1%, higher than or equal to 3%, or higher than or equal to 5% and lower than or equal to 20% or lower than or equal to 15%. Specifically, a metal oxide with In:Sn:Si=45:5:4 or In:Sn:Si=95:5:8 or a composition in the neighborhood thereof can be suitably used.

For analysis of the composition of the layer 108, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES) can be used, for example. Alternatively, a combination of those methods may be used for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage or difficult to quantify, or the element M may be below the lower detection limit.

A sputtering method or an atomic layer deposition (ALD) method can be suitably used to form the metal oxide. Note that in the case where the metal oxide is formed by a sputtering method, the composition of the formed metal oxide may be different from the composition of a sputtering target. In particular, the content percentage of zinc in the formed metal oxide may be reduced to approximately 50% of that of the sputtering target.

The layer 108 may have a stacked-layer structure including two or more metal oxide layers. The two or more metal oxide layers included in the layer 108 may have the same composition or substantially the same compositions. Employing a stacked-layer structure of metal oxide layers having the same composition can reduce the manufacturing cost because the metal oxide layers can be formed using the same sputtering target.

The two or more metal oxide layers included in the layer 108 may have different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being formed over the first metal oxide layer can be suitably employed. In addition, it is particularly preferable to use gallium, aluminum, or tin as the element M. The elements M in the first metal oxide layer and the second metal oxide layer may be the same or different. For example, the first metal oxide layer and the second metal oxide layer may be IGZO layers having different compositions.

For example, a stacked-layer structure of a first metal oxide layer having In:Zn=4:1 [atomic ratio] or a composition in the neighborhood thereof and a second metal oxide layer having In:M:Zn=1:1:1 [atomic ratio] or a composition in the neighborhood thereof and being formed over the first metal oxide layer can be suitably employed.

For example, a stacked-layer structure of any one selected from indium oxide, indium gallium oxide, and IGZO, and any one selected from IAZO, IAGZO, and ITZO (registered trademark) may be employed.

Note that when the first metal oxide layer containing a first metal oxide and the second metal oxide layer containing a second metal oxide form a stacked-layer structure and the first metal oxide and the second metal oxide have the same or substantially the same compositions, the boundary (interface) between the first metal oxide layer and the second metal oxide layer cannot clearly be observed in some cases.

It is preferable to use a metal oxide having crystallinity for the layer 108. Examples of the structure of a metal oxide having crystallinity include a CAAC (c-axis aligned crystal) structure, a polycrystalline structure, and a nano-crystal (nc) structure. With use of a metal oxide having crystallinity for the layer 108, the density of defect states in the layer 108 can be reduced, which enables the semiconductor device to have high reliability.

For the layer 108, a CAAC-OS or an nc-OS is preferably used.

The CAAC-OS includes a plurality of layered crystals. The c-axes of the crystals are aligned in the normal direction of the formation surface. The layer 108 preferably includes layered crystals parallel or substantially parallel to the formation surface. For example, the layer 108 preferably includes layered crystals parallel or substantially parallel to the top surface of the insulating layer 110 in the region in contact with the top surface of the insulating layer 110, and layered crystals parallel or substantially parallel to the side surface of the insulating layer 110 in the region in contact with the side surface of the insulating layer 110. In particular, the layer 108 preferably includes layered crystals parallel or substantially parallel to the side surface of the insulating layer 110a. With this structure, the layered crystals of a layer 108b are formed substantially parallel to the channel length direction of the transistor 100, so that the on-state current of the transistor can be increased.

When a metal oxide having high crystallinity is used for the channel formation region, the density of defect states in the channel formation region can be reduced. By contrast, when a metal oxide having low crystallinity is used, a transistor through which a large amount of current can flow can be achieved.

In the case where the metal oxide is formed by a sputtering method, the crystallinity of the formed metal oxide can be increased as the substrate temperature at the time of formation is higher. For example, the substrate temperature at the time of formation can be adjusted by the temperature of the stage on which the substrate is placed at the time of formation. As the proportion of the flow rate of an oxygen gas to the total flow rate of the film formation gas used for formation (hereinafter also referred to as the oxygen flow rate ratio) or the oxygen partial pressure in a processing chamber is higher, the metal oxide can be formed to have higher crystallinity.

The crystallinity of the layer 108 can be analyzed with X-ray diffraction (XRD), a transmission electron microscope (TEM), or electron diffraction (ED), for example. Alternatively, a combination of those methods may be used for the analysis.

In the case where a metal oxide is used for the layer 108, V_{O}H in the region 108C functioning as the channel formation region is preferably reduced as much as possible so that the layer 108 becomes a highly purified intrinsic or substantially highly purified intrinsic layer. In order to obtain such a metal oxide with sufficiently reduced V_{O}H, it is important to remove impurities such as water and hydrogen in the metal oxide (this treatment is sometimes referred to as dehydration or dehydrogenation treatment) and supply oxygen to the metal oxide to repair an oxygen vacancy (V_{O}). When a metal oxide with sufficiently reduced impurities such as V_{O}H is used for a channel formation region of a transistor, the transistor can have stable electrical characteristics. Supplying oxygen to the metal oxide to repair an oxygen vacancy (V_{O}) is sometimes referred to as oxygen adding treatment.

When a metal oxide is used for the layer 108, the carrier concentration of the metal oxide in the region 108C functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, yet still further preferably lower than 1×10¹² cm⁻³. Note that the lower limit of the carrier concentration in the region 108C is not particularly limited and can be, for example, 1×10⁻⁹ cm⁻³.

A change in electrical characteristics of an OS transistor due to radiation irradiation is small, i.e., an OS transistor has high tolerance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

The layer 108 may contain a layered substance that functions as a semiconductor. The layered substance is a general term of a group of materials having a layered crystal structure. The layered crystal structure is a structure in which layers formed by covalent bonding or ionic bonding are stacked with bonding such as the Van der Waals bonding, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the layered substances include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a channel formation region of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### [Conductive Layer 104]

The conductive layer 104 may have a single-layer structure or a stacked-layer structure of two or more layers. For the conductive layer 104, for example, one or more of chromium, copper, aluminum, gold, silver, zinc, tantalum, titanium, tungsten, manganese, nickel, iron, cobalt, molybdenum, ruthenium, and niobium, or an alloy containing one or more of these metals as its components can be used. For the conductive layer 104, a low-resistance conductive material that contains one or more of copper, silver, gold, and aluminum can be suitably used. Copper or aluminum is particularly preferable because of its high mass-productivity.

For the conductive layer 104, one or more of a metal oxide (an oxide conductor) and a metal nitride (a nitride conductor) that have conductivity can be used. Examples of an oxide conductor (OC) include indium oxide, zinc oxide, In—Sn oxide (ITO), In—Zn oxide, In—W oxide, In—W—Zn oxide, In—Ti oxide, In—Ti—Sn oxide, In—Sn—Si oxide (also referred to as ITO containing silicon or ITSO), zinc oxide to which gallium is added, and In—Ga—Zn oxide. An oxide conductor containing indium is particularly preferable because of its high conductivity. Examples of the nitride conductor include tantalum nitride, titanium nitride, tungsten nitride, ruthenium nitride, a nitride containing titanium and aluminum, and a nitride containing tantalum and aluminum.

The conductive layer 104 may have a stacked-layer structure. The conductive layer 104, for example, may have a stacked-layer structure of a conductive film including the above-described oxide conductor (metal oxide) and a conductive film including a metal or an alloy. The use of the conductive film including a metal or an alloy can reduce the wiring resistance.

A Cu—X alloy film (X is Mn, Ni, Cr, Fe, Co, Mo, Ta, or Ti) may be used for the conductive layer 104. The use of a Cu—X alloy film leads to a reduction in manufacturing cost because the Cu—X alloy film can be processed by a wet etching method.

The conductive layer 182A and the conductive layer 182B can each be formed using a material that can be used for the conductive layer 104. Note that the conductive layer 182A and the conductive layer 182B may be formed using the same material as the conductive layer 104 or may be formed using a material different from that for the conductive layer 104.

### [Insulating Layer 106]

The insulating layer 106 may have either a single-layer structure or a stacked-layer structure of two or more layers. The insulating layer 106 preferably includes one or more inorganic insulating films. Examples of a material that can be used for the inorganic insulating film include an oxide, a nitride, an oxynitride, and a nitride oxide. For the insulating layer 106, a material that can be used for the insulating layer 110 can be used.

The insulating layer 106 includes regions in contact with the layer 108, the insulating layer 109, and the insulating layer 110. In the case where a metal oxide is used for the layer 108, at least the film of the insulating layer 106 that is in contact with the layer 108 is preferably any of the above-described oxide and oxynitride. It is further preferable that a film from which oxygen is released by heating be used as the insulating layer 106. Specifically, in the case where the insulating layer 106 has a single-layer structure, silicon oxide, silicon oxynitride, or aluminum oxide is preferably used for the insulating layer 106.

The insulating layer 106 preferably has a stacked-layer structure. FIG. 1B and the like illustrate a structure in which the insulating layer 106 has a stacked-layer structure of an insulating layer 106a and an insulating layer 106b over the insulating layer 106a.

In the case where the insulating layer 106 has a stacked-layer structure, the insulating layer (here, the insulating layer 106a) on the side in contact with the layer 108 preferably contains an oxide or an oxynitride. For example, one or more of silicon oxide, silicon oxynitride, and aluminum oxide can be suitably used for the insulating layer 106a.

As one or more layers included in the insulating layer 106, a layer through which oxygen is less likely to pass is preferably used. Providing a layer functioning as a barrier film inhibiting oxygen diffusion inhibits oxygen contained in the insulating layer 110a from diffusing into the insulating layer 106 side through a region of the insulating layer 110a that is in contact with the insulating layer 106. This increases the amount of oxygen supplied from the insulating layer 110a to the region 108C, whereby oxygen vacancies (V_{O}) and V_{O}H in the channel formation region can be reduced. Moreover, oxygen contained in the insulating layer 110a and oxygen contained in the layer 108 are inhibited from diffusing into the conductive layer 104 through the insulating layer 106, so that oxidation of the conductive layer 104 can be inhibited. Consequently, the transistor can have favorable electrical characteristics and high reliability. One or more of the above-described nitride and nitride oxide are preferably used for the layer functioning as a barrier film against oxygen. Alternatively, one or more of an oxide and an oxynitride may be used for the layer, and aluminum oxide can be suitably used, for example.

Note that in this specification and the like, a barrier film refers to a film having a barrier property. A barrier property means one or both of a function of inhibiting diffusion of (also referred to as having low permeability to) a target substance and a function of capturing or fixing (also referred to as gettering) a target substance. For example, an insulating layer having a barrier property can be referred to as a barrier insulating layer.

In the case where the insulating layer 106 has a stacked-layer structure, silicon oxynitride can be used for the insulating layer 106a and silicon nitride can be used for the insulating layer 106b, for example. Alternatively, silicon oxynitride can be used for the insulating layer 106a and aluminum oxide can be used for the insulating layer 106b. Alternatively, aluminum oxide can be used for the insulating layer 106a and silicon oxynitride can be used for the insulating layer 106b. Alternatively, aluminum oxide can be used for the insulating layer 106a and silicon nitride can be used for the insulating layer 106b.

A transistor having a minute size and including a thin gate insulating layer may have a large leakage current. When a high dielectric constant material (also referred to as a high-k material) is used for the gate insulating layer, the voltage at the time of operation of the transistor can be reduced while the physical thickness is maintained. Examples of the high-k material that can be used for the insulating layer 106 include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

### [Substrate 102]

Although there is no great limitation on a material of the substrate 102, it is necessary that the substrate have heat resistance high enough to withstand at least heat treatment performed later. For example, a single crystal semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or an organic resin substrate may be used as the substrate 102. The substrate 102 may be provided with a semiconductor element. Note that the shape of the semiconductor substrate and an insulating substrate may be a circular shape or a shape with corners.

A flexible substrate may be used as the substrate 102, and the transistor 100 and the like may be formed directly on the flexible substrate. Alternatively, a separation layer may be provided between the substrate 102 and the transistor 100 and the like. With the separation layer, part or the whole of a semiconductor device completed thereover can be separated from the substrate 102 and transferred onto another substrate. In such a case, the transistor 100 and the like can be transferred to a substrate having low heat resistance or a flexible substrate as well.

A structure example which is partly different from that of Structure example 1-1 shown above will be described below. Note that description of the same portions as those in Structure example 1-1 shown above is omitted below in some cases. Furthermore, in drawings that are referred to later, the same hatching pattern is applied to portions having functions similar to those in Structure example 1-1 shown above, and the portions are not denoted by reference numerals in some cases.

### Structure Example 1-2

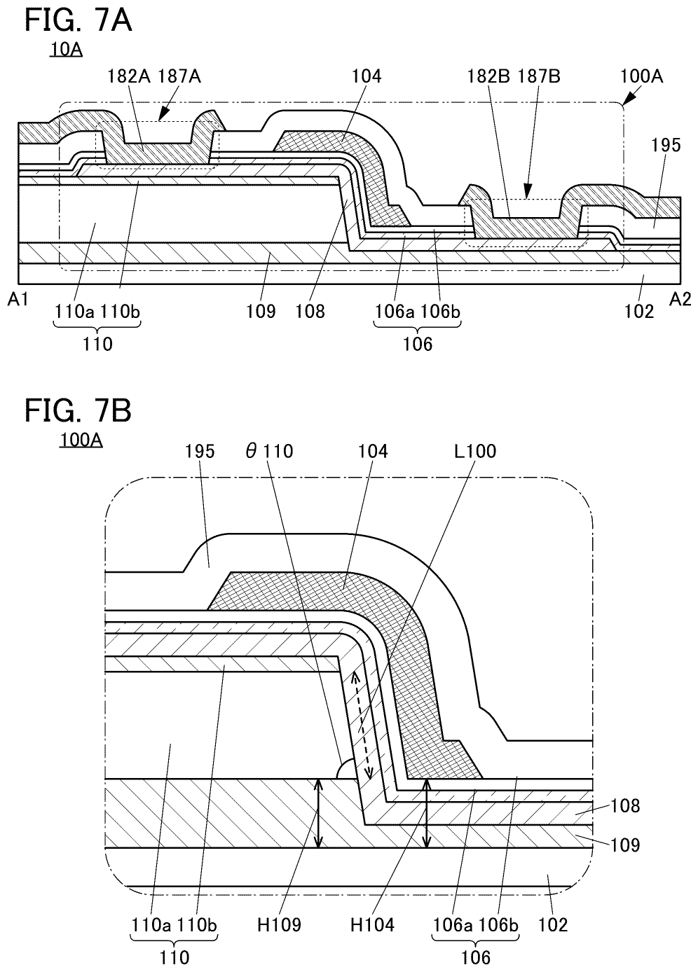

FIG. 7A is a cross-sectional view of a semiconductor device 10A of one embodiment of the present invention. FIG. 1A can be referred to for a top view of the semiconductor device 10A. FIG. 7A is a cross-sectional view of a cross section of a cut plane along the dashed-dotted line A1-A2 in FIG. 1A.

The semiconductor device 10 includes a transistor 100A, the insulating layer 109, and the insulating layer 110. The semiconductor device 10A is different from the semiconductor device 10 illustrated in FIG. 1B and the like mainly in that the thickness of a region of the insulating layer 109 that is in contact with the bottom surface of the layer 108 is different from the thickness of a region of the insulating layer 109 that is not in contact with the layer 108.

For the transistor 100A, the above description of the transistor 100 can be referred to.

As illustrated in FIG. 7A and the like, the thickness of the region of the insulating layer 109 that is in contact with the bottom surface of the layer 108 is preferably smaller than the thickness of the region of the insulating layer 109 that is not in contact with the layer 108.

FIG. 7B is an enlarged view of FIG. 7A. FIG. 7B illustrates a height H104 from the formation surface of the insulating layer 109 (here, the top surface of the substrate 102) to the lowest position of the bottom surface of the conductive layer 104. FIG. 7B also illustrates a height H109 from the formation surface of the insulating layer 109 (here, the top surface of the substrate 102) to the highest position of the region where the insulating layer 109 and the insulating layer 110a are in contact with each other. As illustrated in FIG. 7B, the height H104 to the lowest position of the bottom surface of the conductive layer 104 is preferably equal to the height H109 to the highest position of the region where the insulating layer 109 and the insulating layer 110a are in contact with each other or smaller than the height H109.

When the height H104 to the lowest position of the bottom surface of the conductive layer 104 is equal to the height H109 to the highest position of the region where the insulating layer 109 and the insulating layer 110a are in contact with each other or smaller than the height H109, the electric field of the gate electrode applied to the channel formation region in the vicinity of the insulating layer 109 can be increased and the on-state current of the transistor 100A can be increased. In addition, the electric field of the gate electrode applied to the channel formation region can be more uniform.

Here, in the case where the electric field of the gate electrode applied to the channel formation region is not uniform, the electrical characteristics in the case where the region 108P is the source electrode and the region 108Q is the drain electrode and the electrical characteristics in the case where the region 108P is the drain electrode and the region 108Q is the source electrode might be different from each other. By making the electric field of the gate electrode applied to the channel formation region of the transistor 100A more uniform, the electrical characteristics in the both cases can be made equivalent to each other. Thus, the transistor 100A can be suitably used in a circuit structure where a source and a drain are interchanged with each other.

The thickness of the insulating layer 109 is adjusted as appropriate so that the height H104 is equal to the height H109 or smaller than the height H109.

Note that the structure of the insulating layer 109 described in Structure example 1-2 can also be applied to other structure examples.

### Structure Example 1-3

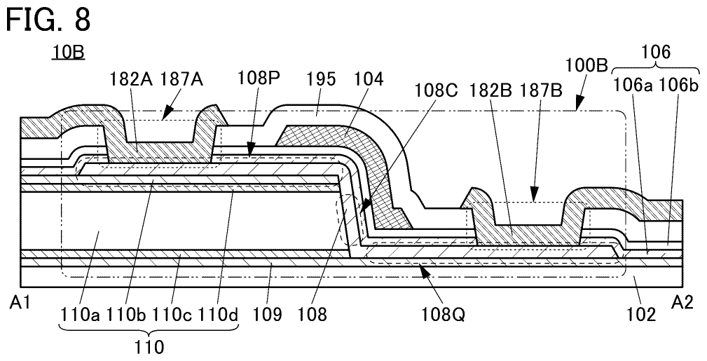

FIG. 8 is a cross-sectional view of a semiconductor device 10B of one embodiment of the present invention. FIG. 1A can be referred to for a top view of the semiconductor device 10B. FIG. 8 is a cross-sectional view of a cross section of a cut plane along the dashed-dotted line A1-A2 in FIG. 1A.

The semiconductor device 10B includes a transistor 100B, the insulating layer 109, and the insulating layer 110. The semiconductor device 10B is different from the semiconductor device 10 illustrated in FIG. 1B and the like mainly in that the insulating layer 110 includes the insulating layer 110c and the insulating layer 110d.

For the transistor 100B, the above description of the transistor 100 can be referred to.

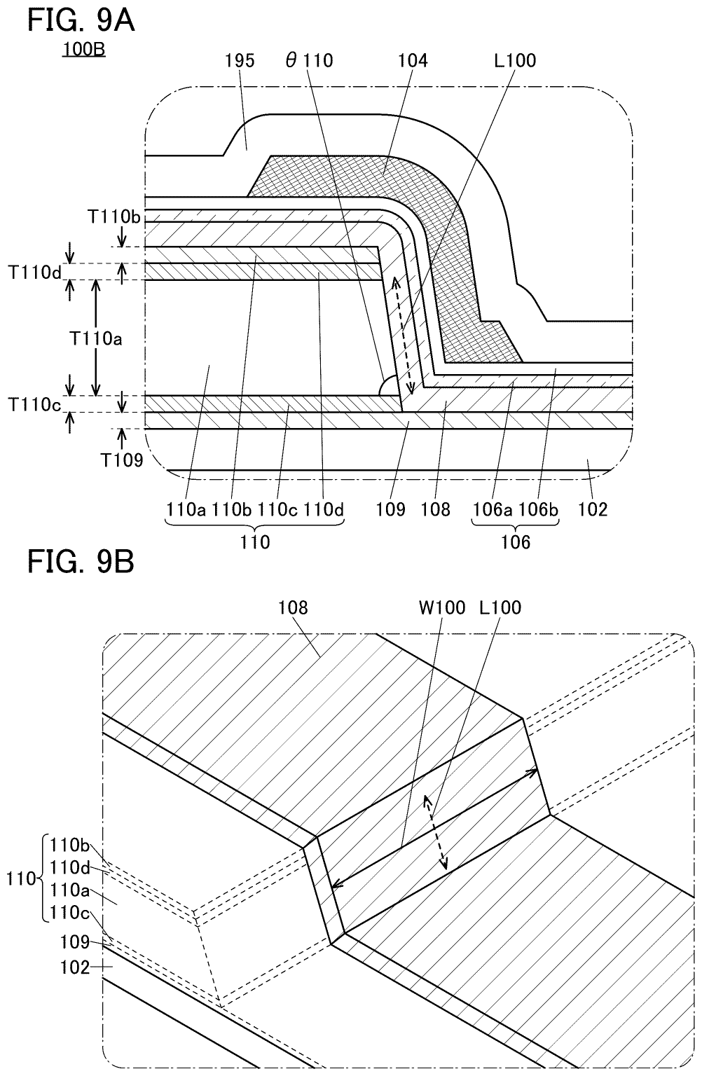

FIG. 8 is an enlarged view of FIG. 9A. FIG. 9B is a perspective view selectively illustrating the substrate 102, the insulating layer 109, the insulating layer 110, and the layer 108. The insulating layer 110c is provided between the insulating layer 109 and the insulating layer 110a. The insulating layer 110d is provided between the insulating layer 110b and the insulating layer 110a. The layer 108 is in contact with the top surface of the insulating layer 109, the side surface of the insulating layer 110c, the side surface of the insulating layer 110a, the side surface of the insulating layer 110d, and the top surface and the side surface of the insulating layer 110b.

Preferably, the insulating layer 110c and the insulating layer 110d each release a small amount of impurities (e.g., hydrogen and water) and are less likely to transmit impurities. Specifically, the amount of impurities released from the insulating layer 110c is preferably smaller than the amount of impurities released from the insulating layer 109. The amount of impurities released from the insulating layer 110d is preferably smaller than the amount of impurities released from the insulating layer 110b. Moreover, each of the insulating layer 110c and the insulating layer 110d is preferably less likely to transmit impurities. In this case, impurities contained in the insulating layer 109 can be inhibited from diffusing into the region 108C through the insulating layer 110c and the insulating layer 110a. Similarly, impurities contained in the insulating layer 110b can be inhibited from diffusing into the region 108C through the insulating layer 110d and the insulating layer 110a. Thus, the transistor can have favorable electrical characteristics and high reliability.

For each of the insulating layer 110c and the insulating layer 110d, a film that is less likely to transmit oxygen is preferably used. In that case, oxygen contained in the insulating layer 110a is inhibited from diffusing into the insulating layer 109 side through the insulating layer 110c and to the insulating layer 110b side through the insulating layer 110d. Furthermore, the amount of oxygen supplied from the insulating layer 110a to the region 108C is increased, whereby oxygen vacancies (V_{O}) and V_{O}H in the channel formation region can be reduced.

For each of the insulating layer 110c and the insulating layer 110d, a material that can be used for the insulating layer 109 and the insulating layer 110 can be used. For each of the insulating layer 110c and the insulating layer 110d, in particular, a material that can be used for the insulating layer 109 and the insulating layer 110b can be used. The insulating layer 110c and the insulating layer 110d each preferably contain nitrogen, and any one or more of the nitride and nitride oxide described above are preferably used. For example, silicon nitride or silicon nitride oxide can be suitably used for each of the insulating layer 110c and the insulating layer 110d. Alternatively, any one or more of an oxide and an oxynitride may be used for each of the insulating layer 110c and the insulating layer 110d. Aluminum oxide can be suitably used for each of the insulating layer 110c and the insulating layer 110d, for example. For the insulating layer 110b, the insulating layer 110c, the insulating layer 110d, and the insulating layer 109, the same material or different materials may be used.

A thickness T110c of the insulating layer 110c and the thickness T110d of the insulating layer 110d are each preferably greater than or equal to 3 nm and less than or equal to 500 nm, further preferably greater than or equal to 5 nm and less than or equal to 300 nm, still further preferably greater than or equal to 10 nm and less than or equal to 200 nm, yet still further preferably greater than or equal to 15 nm and less than or equal to 150 nm, yet still further preferably greater than or equal to 20 nm and less than or equal to 100 nm, for example. As illustrated in FIG. 9A, the thickness T110c can be the shortest distance between the formation surface of the insulating layer 110c (here, the top surface of the insulating layer 109) and the top surface of the insulating layer 110c in the cross-sectional view. The thickness T110d can be the shortest distance between the formation surface of the insulating layer 110d (here, the top surface of the insulating layer 110a) and the top surface of the insulating layer 110d in the cross-sectional view. Note that the thickness T110c and the thickness T110d may be the same or different from each other.

The larger thickness T110c of the insulating layer 110c increases the amount of impurities released from the insulating layer 110c itself, and the larger thickness T110d of the insulating layer 110d similarly increases the amount of impurities released from the insulating layer 110d itself, so that a larger amount of impurities might diffuse into the region 108C. Meanwhile, when the thickness T110c is small, impurities contained in the insulating layer 109 might diffuse into the region 108C through the insulating layer 110c and the insulating layer 110a. When the thickness T110d is small, impurities contained in the insulating layer 110b might diffuse into the region 108C through the insulating layer 110d and the insulating layer 110a. Moreover, oxygen contained in the insulating layer 110a might diffuse into the insulating layer 109 side through the insulating layer 110c and the insulating layer 110b side through the insulating layer 110d. When the thickness T110c and the thickness T110d are each within the above range, the diffusion of impurities into the region 108C can be inhibited and the amount of oxygen supplied to the region 108C can be increased, so that oxygen vacancies (V_{O}) and V_{O}H in the region 108C can be reduced.

When the channel length L100 of the transistor 100B is short, materials that release a smaller amount of hydrogen are preferably used for the insulating layer 110c and the insulating layer 110d. In the case where materials that release even a small amount of hydrogen are used for the insulating layer 110c and the insulating layer 110d, their thicknesses are preferably small. For example, when the channel length L100 is less than or equal to 100 nm, the thickness T110c of the insulating layer 110c and the thickness T110d of the insulating layer 110d are each preferably greater than or equal to 1 nm and less than or equal to 50 nm, further preferably greater than or equal to 3 nm and less than or equal to 40 nm, still further preferably greater than or equal to 5 nm and less than or equal to 30 nm, yet still further preferably greater than or equal to 5 nm and less than or equal to 20 nm, yet still further preferably greater than or equal to 5 nm and less than or equal to 15 nm, yet still further preferably greater than or equal to 5 nm and less than or equal to 10 nm. Accordingly, the amount of hydrogen diffusing into the region 108C can be reduced, and the transistor can have favorable electrical characteristics and high reliability even with the short channel length L100.

The insulating layer 109 preferably includes a region having a higher impurity element concentration than the insulating layer 110c. The insulating layer 110b preferably includes a region having a higher impurity element concentration than the insulating layer 110d. Specifically, the insulating layer 109 preferably includes a region having a higher hydrogen concentration than the insulating layer 110c. The insulating layer 110b preferably includes a region having a higher hydrogen concentration than the insulating layer 110d. The impurity element concentrations of these insulating layers can be analyzed by secondary ion mass spectrometry (SIMS), for example.

The insulating layer 110c preferably has a lower impurity element concentration than the insulating layer 109. The insulating layer 110d preferably has a lower impurity element concentration than the insulating layer 110b. Furthermore, the insulating layer 110c and insulating layer 110d each preferably has an impurity element concentration lower than 1×10²¹ atoms/cm³. Specifically, the hydrogen concentration in each of the insulating layer 110c and the insulating layer 110d is preferably lower than 1×10²¹ atoms/cm³. Note that the insulating layer 110c and insulating layer 110d preferably has a low impurity element concentration, so that the lower limit of the impurity element concentration is not limited. The concentration of each of the above-described impurity elements is preferably low in the insulating layer 110c and the insulating layer 110d. For example, the carbon concentration in each of the insulating layer 110c and the insulating layer 110d is preferably lower than 1×10²¹ atoms/cm³.

Even in the case where the same material is used for the insulating layer 109 and the insulating layer 110c, using different film formation conditions enables adjustment of the amount of hydrogen to be released. Specifically, the film formation conditions for the insulating layer 109 may be different from those for the insulating layer 110c in any one or more of the film formation power (or film formation power density), the film formation pressure, the kind of film formation gas, the flow rate ratio of a film formation gas, the film formation temperature, and the distance between the substrate and the electrode during formation. For example, by setting the film formation power density for the insulating layer 109 lower than the film formation power density for the insulating layer 110c, the hydrogen content in the insulating layer 109 can be made higher than the hydrogen content in the insulating layer 110c. Accordingly, the amount of hydrogen released from the insulating layer 109 due to heat applied thereto can be increased. Similarly, in the case where the same material is used for the insulating layer 110b and the insulating layer 110d, for example, the film formation power density for the insulating layer 110b is set lower than the film formation power density for the insulating layer 110d, in which case the insulating layer 110b can have a higher hydrogen content than the insulating layer 110d.

The film formation gas used for formation of the insulating layer 109 preferably contains a larger amount of hydrogen than the film formation gas used for formation of the insulating layer 110c. Specifically, in the case of forming a silicon nitride film or a silicon nitride oxide film as each of the insulating layer 109 and the insulating layer 110c by a PECVD method, the proportion of a flow rate of an ammonia gas to the whole film formation gas used for formation of the insulating layer 109 (hereinafter also referred to as ammonia flow rate ratio) is preferably higher than the proportion of a flow rate of an ammonia gas to the whole film formation gas used for forming the insulating layer 110c. The formation of the insulating layer 109 under the condition where the ammonia flow rate ratio is high can increase the hydrogen content in the insulating layer 109. Furthermore, the amount of hydrogen released from the insulating layer 109 due to heat applied thereto can be increased. Similarly, the film formation gas used for the formation of the insulating layer 110b preferably includes more hydrogen than the film formation gas used for the formation of the insulating layer 110d.

The film density of the insulating layer 110c is preferably higher than the film density of the insulating layer 109. In this case, impurities contained in the insulating layer 109 can be inhibited from diffusing into the region 108C through the insulating layer 110c and the insulating layer 110a. Similarly, oxygen contained in the insulating layer 110a can be inhibited from diffusing into the insulating layer 109 side through the insulating layer 110c. Furthermore, the film density of the insulating layer 110d is preferably higher than the film density of the insulating layer 110b. In this case, impurities contained in the insulating layer 110b can be inhibited from diffusing into the region 108C through the insulating layer 110d and the insulating layer 110a. Similarly, oxygen contained in the insulating layer 110a can be inhibited from diffusing into the insulating layer 110b side through the insulating layer 110d. Note that the film density of the insulating layer 110c and the film density of the insulating layer 110d may be the same or different from each other.

The film density can be evaluated by Rutherford backscattering spectrometry (RBS) or X-ray reflection (XRR), for example. A difference in film density can be evaluated using a transmission electron microscopy (TEM) image of a cross section in some cases. In TEM observation, a transmission electron (TE) image is dark-colored (dark) when the film density is high, and a transmission electron (TE) image is pale (bright) when the film density is low. Thus, in some cases, the transmission electron (TE) image of the insulating layer 110c is a dark-colored (dark) image compared to the insulating layer 109 and the transmission electron (TE) image of the insulating layer 110d is a dark-colored (dark) image compared to the insulating layer 110b. Note that since the insulating layer 109 and the insulating layer 110c have different film densities even when including the same materials, it is sometimes possible to identify the boundary between the insulating layer 109 and the insulating layer 110c by a difference in contrast in a TEM image of a cross section. The same applies to the case where the insulating layer 110b and the insulating layer 110d include the same materials.

The amount of impurities released from the insulating layer 110c is preferably smaller than the amount of impurities released from the insulating layer 109. The amount of impurities released from the insulating layer 110d is preferably smaller than the amount of impurities released from the insulating layer 110b.

Although impurities released from the insulating layer 110c itself are preferably smaller in amounts, the impurities released from the insulating layer 110c might lower the electrical resistance of the region of the layer 108 that is in contact with the insulating layer 110c. Similarly, although impurities released from the insulating layer 110d itself are preferably smaller in amounts, the impurities released from the insulating layer 110d might lower the electrical resistance of the region of the layer 108 that in contact with the insulating layer 110d. These regions (hereinafter also referred to as low-resistance regions) are each a region whose electric resistance is lower than that of the region 108C, a region whose carrier concentration is higher than that of the region 108C, and a region whose oxygen vacancy density is higher than that of the region 108C. Furthermore, these regions are each a region whose electric resistance is higher than those of the region 108P and the region 108Q, a region whose carrier concentration is lower than those of the region 108P and the region 108Q, and a region whose oxygen vacancy density is lower than those of the region 108P and the region 108Q. The low-resistance regions, which are positioned between the region 108C functioning as the channel formation region and the region 108P and the region 108Q functioning as the source electrode and the drain electrode, can function as buffer regions for relieving a drain electric field. Providing the low-resistance regions hinders generation of a high electric field in the vicinity of the drain electrode, so that generation of hot carriers is inhibited and degradation of the transistor can be inhibited. For example, in the case where the region 108Q functions as the drain electrode and the region 108P functions as the source electrode, the region of the layer 108 that is in contact with the insulating layer 110d is the low-resistance region, which hinders generation of a high electric field in the vicinity of the drain electrode, so that generation of hot carriers is inhibited and degradation of the transistor can be inhibited.

When a material that releases a small amount of impurities is used for the insulating layer 110c, the region of the layer 108 that is in contact with the insulating layer 110c may have electric resistance, carrier concentration, and oxygen defect density that are equivalent to those of the region 108C. In this case, the region of the layer 108 in contact with the insulating layer 110c may function as the channel formation region together with the region 108C in contact with the insulating layer 110a. Similarly, the region of the layer 108 that is in contact with the insulating layer 110d may also function as the channel formation region.

The structure of the insulating layer 110 described in Structure example 1-3 can also be applied to other structure examples.

### Structure Example 1-4

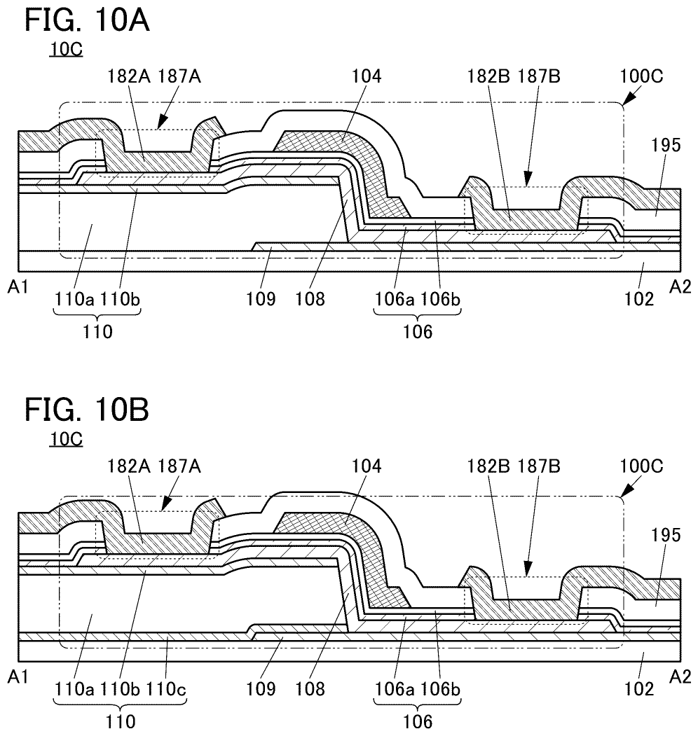

A schematic cross-sectional view of a semiconductor device 10C that is one embodiment of the present invention is illustrated in FIG. 10A. FIG. 1A can be referred to for a top view of the semiconductor device 10C. Note that the insulating layer 109 is omitted in FIG. 1A. FIG. 10A is a cross-sectional view of a cross section of a cut plane along the dashed-dotted line A1-A2 in FIG. 1A.

The semiconductor device 10C includes the transistor 100C, the insulating layer 109, and the insulating layer 110. The semiconductor device 10C is different from the semiconductor device 10 illustrated in FIG. 1B and the like mainly in that the side surface of the insulating layer 109 is in contact with the insulating layer 110.

For the transistor 100C, the above description of the transistor 100 can be referred to.

An end portion of the insulating layer 109 is in contact with the top surface of the substrate 102. The insulating layer 110 is provided to cover the substrate 102 and the insulating layer 109 and includes a region in contact with the top surface of the substrate 102 and a region in contact with the top surface and the side surface of the insulating layer 109.

The insulating layer 109 preferably includes a region in contact with the insulating layer 110. Thus, a region in contact with the insulating layer 109 and a region in contact with the insulating layer 110 can be continuously provided in the layer 108.

Although FIG. 10A illustrates the structure in which the insulating layer 110 has a two-layer structure of the insulating layer 110a and the insulating layer 110b, there is no particular limitation on the structure of the insulating layer 110. FIG. 10B illustrates a structure example different from that in FIG. 10A. For example, the insulating layer 110c may be provided as illustrated in FIG. 10B. Providing the insulating layer 110c between the substrate 102 and the insulating layer 110a can inhibit impurities contained in the substrate 102 from diffusing into the region 108C through the insulating layer 110c and the insulating layer 110a. Similarly, oxygen contained in the insulating layer 110a can be inhibited from diffusing into the substrate side through the insulating layer 110c.

Note that the structure of the insulating layer 109 described in Structure example 1-4 can also be applied to other structure examples.

### Structure Example 1-5

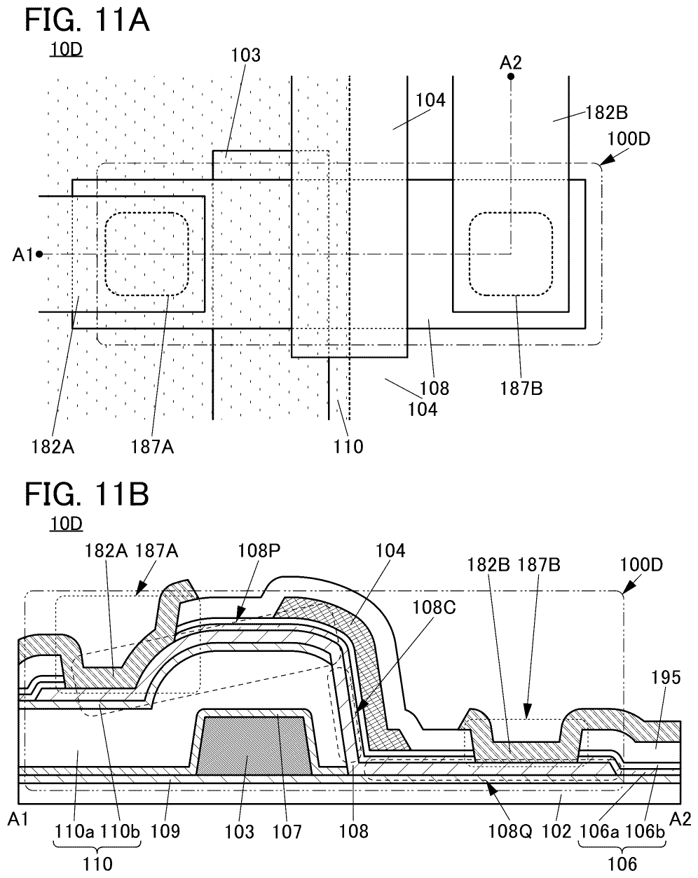

FIG. 11A shows a top view of a semiconductor device 10D of one embodiment of the present invention. FIG. 11B shows a cross-sectional view of a cut plane along the dashed-dotted line A1-A2 in FIG. 11A.

The semiconductor device 10D includes a transistor 100D, the insulating layer 109, and the insulating layer 110. The transistor 100C is different from the transistor 100 illustrated in FIG. 1B and the like mainly in including a conductive layer 103 and an insulating layer 107.

The transistor 100C includes the conductive layer 103 and the insulating layer 107 between the insulating layer 109 and the insulating layer 110.

The conductive layer 103 is positioned over the insulating layer 109. The insulating layer 107 is provided to cover a top surface and a side surface of the conductive layer 103. The insulating layer 107 is in contact with the top surface and the side surface of the conductive layer 103 and the top surface of the insulating layer 109. The insulating layer 110 is provided over the insulating layer 107.

The layer 108 of the transistor 100C includes a region that overlaps with the conductive layer 104 with the insulating layer 106 between the region and the conductive layer 104 and that overlaps with the conductive layer 103 with part (specifically, the insulating layer 110a) of the insulating layer 110 and the insulating layer 107 between the region and the conductive layer 103. In other words, the layer 108 includes the region interposed between the conductive layer 104 and the conductive layer 103, with the insulating layer 106 between the region and the conductive layer 104 and with the part (specifically, the insulating layer 110a) of the insulating layer 110 and the insulating layer 107 between the region and the conductive layer 103.

The conductive layer 103 functions as a back gate electrode (also referred to as a second gate electrode) of the transistor 100D. Part of the insulating layer 110 and the insulating layer 107 function as a back gate insulating layer (also referred to as a second gate insulating layer) of the transistor 100D. For the conductive layer 103, a material that can be used for the conductive layer 104 can be used. Note that the conductive layer 103 is not necessarily provided.

Provision of the back gate electrode for the transistor 100D enables the potential on the back gate electrode side (also referred to as the back channel side) of the layer 108 to be fixed, so that the saturation of the Id-Vd characteristics can be improved.

In this specification and the like, the state where the change in current is small in the saturation region of the Id-Vd characteristics of a transistor is sometimes described using the expression “favorable saturation”.

Since the transistor 100D includes the back gate electrode, the potential on the back channel side of the layer 108 can be fixed and a shift of the threshold voltage can be inhibited. Here, a shift of the threshold voltage of the transistor might increase the drain current flowing at a gate voltage of 0 V (hereinafter also referred to as cut-off current). When a shift of the threshold voltage is inhibited, the cut-off current can be reduced in the transistor. Accordingly, a semiconductor device with low power consumption can be provided.

For the insulating layer 107, a material that can be used for the insulating layer 110 can be used. The insulating layer 107 in contact with the conductive layer 103 is preferably less likely to transmit impurities contained in the conductive layer 103. In this case, the impurities contained in the conductive layer 103 can be inhibited from diffusing into the channel formation region through the insulating layer 107 and the insulating layer 110. For the insulating layer 107, a material that can be used for the insulating layer 110c and the insulating layer 110d can be suitably used. For example, silicon nitride or aluminum oxide can be suitably used for the insulating layer 107. Although the insulating layer 107 has a single-layer structure in this embodiment, one embodiment of the present invention is not limited thereto. The insulating layer 107 may have a stacked-layer structure of two or more layers.

The conductive layer 103 functioning as the back gate electrode may be electrically connected to the region 108P functioning as one of the source electrode and the drain electrode. For example, an opening reaching the conductive layer 103 is provided in the insulating layer 110 and the insulating layer 107 and the conductive layer 182A is provided to cover the opening, whereby the conductive layer 182A is in contact with the conductive layer 103. Thus, the conductive layer 103 and the region 108P can be electrically connected to each other through the conductive layer 182A. When the region 108P functioning as the source electrode or the drain electrode and the conductive layer 103 functioning as the back gate electrode are electrically connected to each other, the source electrode or the drain electrode can have the same potential as the back gate electrode. For example, in the case where the region 108P functions as the source electrode, a shift in the threshold voltage of the transistor 100D can be inhibited. In addition, the reliability of the transistor 100D can be improved. Alternatively, the conductive layer 103 may be electrically connected to the region 108Q functioning as the other of the source electrode and the drain electrode.

The conductive layer 103 functioning as the back gate electrode may be electrically connected to the conductive layer 104 functioning as the gate electrode. For example, an opening reaching the conductive layer 103 is provided in the insulating layer 106, the insulating layer 110, and the insulating layer 107 and the conductive layer 104 is provided to cover the opening, whereby the conductive layer 104 is in contact with the conductive layer 103. When the conductive layer 104 functioning as the gate electrode and the conductive layer 103 functioning as the back gate electrode are electrically connected to each other, the back gate electrode and the gate electrode can have the same potential, so that the on-state current of the transistor 100D can be increased.

The thickness of the conductive layer 103 may be larger than the thickness of the insulating layer 110. In this case, the potential on the back channel side of the layer 108 can be fixed in a wide range between the region 108P and the region 108Q of the layer 108.

The transistor 100D includes a region where the conductive layer 103, the insulating layer 107, the insulating layer 110, the layer 108, the insulating layer 106, and the conductive layer 104 are stacked in this order in one direction with no any other layer provided between these layers. The one direction can be a direction perpendicular to the channel length direction. When the above region is wide, the potential on the back channel side of the layer 108 can be controlled more reliably.

The thickness of the conductive layer 103 can be larger than the sum of the thickness of the region 108Q in contact with the insulating layer 109 and the thickness of the insulating layer 106 in contact with the region 108Q.

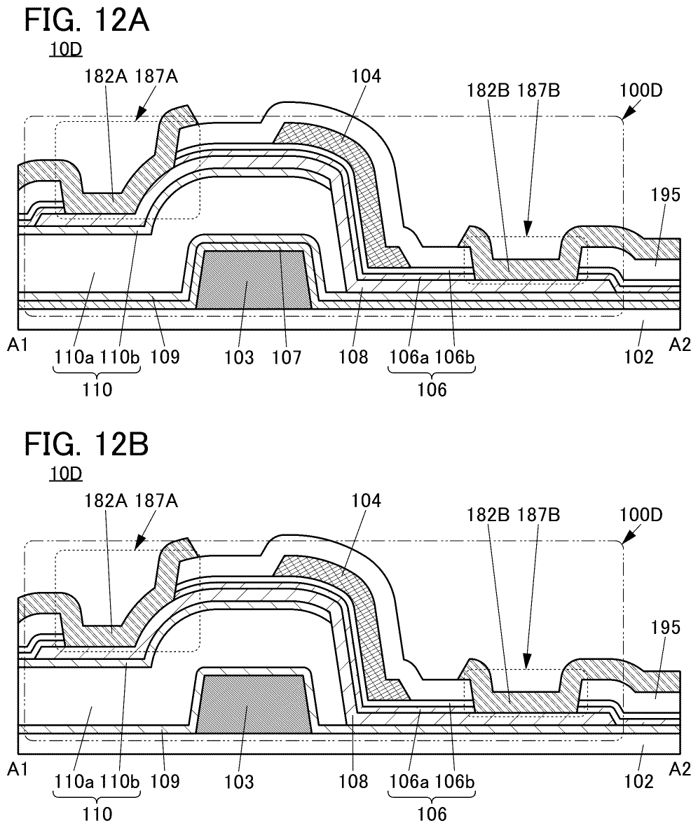

FIG. 12A and FIG. 12B illustrate an example of a structure different from the structure illustrated in FIG. 11B. As illustrated in FIG. 12A, the conductive layer 103 and the insulating layer 107 may be provided between the substrate 102 and the insulating layer 109. As illustrated in FIG. 12B, the insulating layer 107 may be omitted and the conductive layer 103 may be provided between the substrate 102 and the insulating layer 110.

The structure of the conductive layer 103 and the insulating layer 107 described in Structure example 1-5 can also be applied to other structure examples.

### Structure Example 1-6

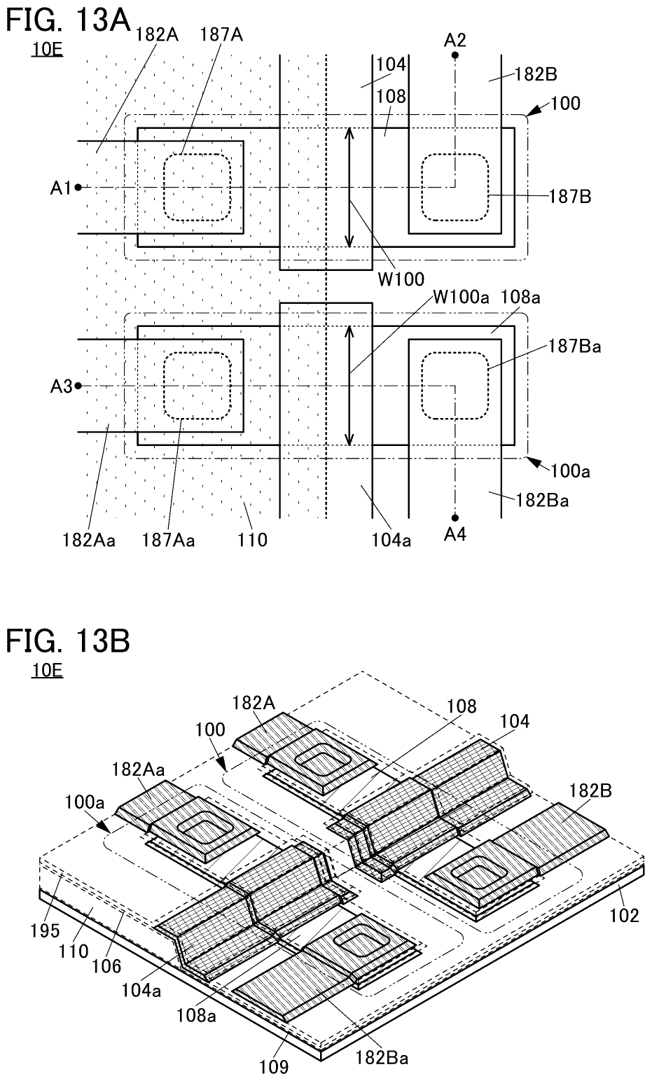

FIG. 13A is a top view of a semiconductor device 10E of one embodiment of the present invention. FIG. 1B can be referred to for cross-sectional views of cross sections taken along the dashed-dotted line A1-A2 and the dashed-dotted line A3-A4 illustrated in FIG. 13A. FIG. 13B is a perspective view of the semiconductor device 10E.

The semiconductor device 10E is different from the semiconductor device 10 illustrated in FIG. 1A and the like mainly in including a plurality of transistors.

The semiconductor device 10E includes the transistor 100, the transistor 100a, the capacitor 109, and the insulating layer 110. The transistor 100a has a structure similar to that of the transistor 100. The transistor 100a can be formed in the same step as the transistor 100.

The above description can be referred to for the transistor 100; thus, the detailed description thereof is omitted.

The transistor 100a includes a conductive layer 104a, the insulating layer 106, and a layer 108a.

The layer 108a includes a region in contact with the top surface and the side surface of the insulating layer 110 and the top surface of the conductive layer 109. It can also be said that the layer 108a includes a region overlapping with the insulating layer 110 and a region not overlapping with the insulating layer 110. A region of the layer 108a that is in contact with the insulating layer 110b functions as a channel formation region of the transistor 100a. For the region, the above description of the region 108C can be referred to. A region of the layer 108a that is in contact with the insulating layer 109 functions as one of a source electrode and a drain electrode of the transistor 100a, and a region of the layer 108a that is in contact with the insulating layer 110b functions as the other of the source electrode and the drain electrode. For these regions, the above description of the region 108P and the region 108Q can be referred to. Like the layer 108, the layer 108a includes the region functioning as the channel formation region, the region functioning as the source electrode, and the region functioning as the drain electrode.

The layer 108a contains a semiconductor material, and a material that can be used for the layer 108 can be used. The layer 108a can be formed in the same step as the layer 108. For example, a film to be the layer 108 and the layer 108a is formed and the film is processed, whereby the layer 108 and the layer 108a can be formed.

One part of the insulating layer 106 functions as the gate insulating layer of the transistor 100 and another part of the insulating layer 106 functions as the gate insulating layer of the transistor 100a. The insulating layer 106 is provided over the layer 108, the layer 108a, the insulating layer 109, and the insulating layer 110. The insulating layer 106 includes a region in contact with the top surface and the side surface of the layer 108, a top surface and a side surface of the layer 108a, and the top surface of the insulating layer 109 and the top surface and the side surface of the layer 110.

The conductive layer 104a functions as a gate electrode of the transistor 100a. The conductive layer 104a is provided over the insulating layer 106 and includes a region in contact with the top surface of the insulating layer 106. The conductive layer 104a includes a portion overlapping with a region of the layer 108a, which is in contact with the side surface of the insulating layer 110, with the insulating layer 106 therebetween. For the conductive layer 104a, a material that can be used for the conductive layer 104 can be used. The conductive layer 104a can be formed in the same step as the conductive layer 104. For example, a film to be the conductive layer 104 and the conductive layer 104a is formed and the film is processed, whereby the conductive layer 104 and the conductive layer 104a can be formed.

The insulating layer 195 is provided over the conductive layer 104 and the conductive layer 104a. The insulating layer 195 functions as a protective layer of the transistor 100 and the transistor 100a. The insulating layer 195 includes an opening 187Aa reaching a region functioning as one of the source electrode and the drain electrode of the transistor 100a and an opening 187Ba reaching a region functioning as the other thereof. A conductive layer 182Aa is provided to cover the opening 187Aa, and, in the opening 187Aa, the conductive layer 182Aa is electrically connected to one of the source electrode and the drain electrode. A conductive layer 182Ba is provided to cover the opening 187Ba, and, in the opening 187Ba, the conductive layer 182Ba is electrically connected to the other of the source electrode and the drain electrode. The conductive layer 182Aa and the conductive layer 182Ba each function as a wiring.

The channel length of the transistor 100a corresponds to the length of the side surface of the region of the insulating layer 110a that is in contact with the layer 108a in the cross-sectional view. Thus, the channel length of the transistor 100a is the same as or substantially the same as the channel length L100 of the transistor 100 (see FIG. 4A and FIG. 4B). The channel width of the transistor 100a is the width of the region where the layer 108a and the conductive layer 104a overlap with each other in the direction orthogonal to the channel length direction. In FIG. 13A, a channel length W100a of the transistor 100a is indicated by a dashed double-headed arrow.

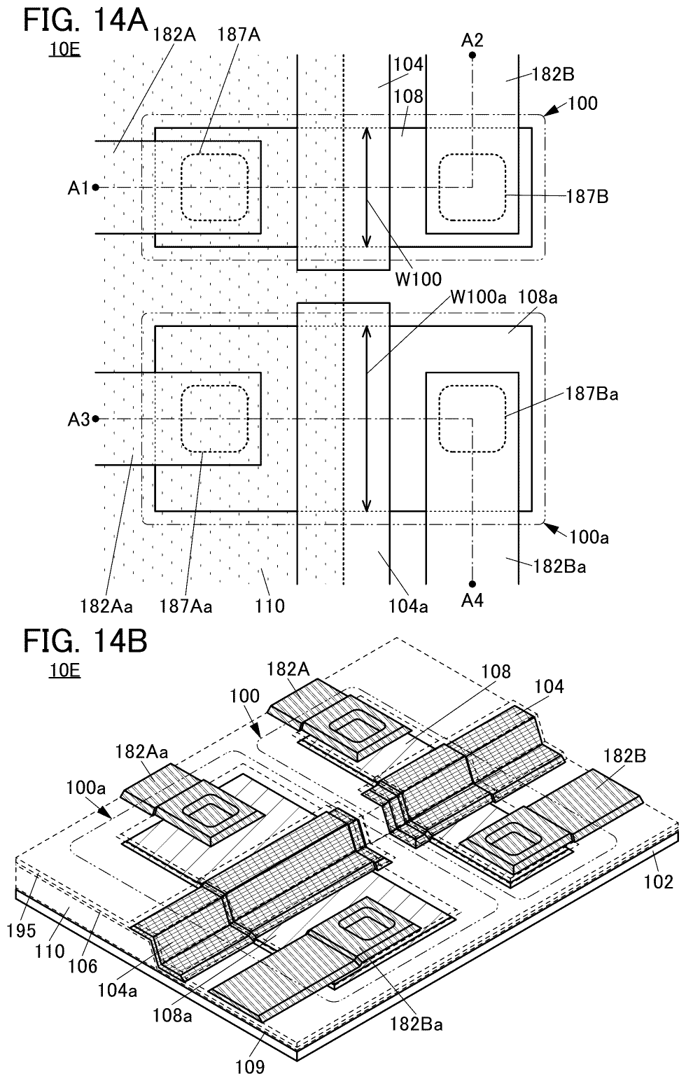

Although the channel width W100a of the transistor 100a has the same structure as the channel width W100 of the transistor 100 in FIG. 13A and FIG. 13B, one embodiment of the present invention is not limited thereto. As illustrated in FIG. 14A and FIG. 14B, the channel width W100a of the transistor 100a may be different from the channel width W100 of the transistor 100.

FIG. 14A and FIG. 14B show a structure in which the channel width W100a of the transistor 100a is larger than the channel width W100 of the transistor 100. A larger channel width can increase the on-state current of the transistor. The channel width may be varied depending on required electrical characteristics of the transistor.

Note that the structure of the transistor described in Structure example 1-6 can also be applied to other structure examples.

### Structure Example 1-7

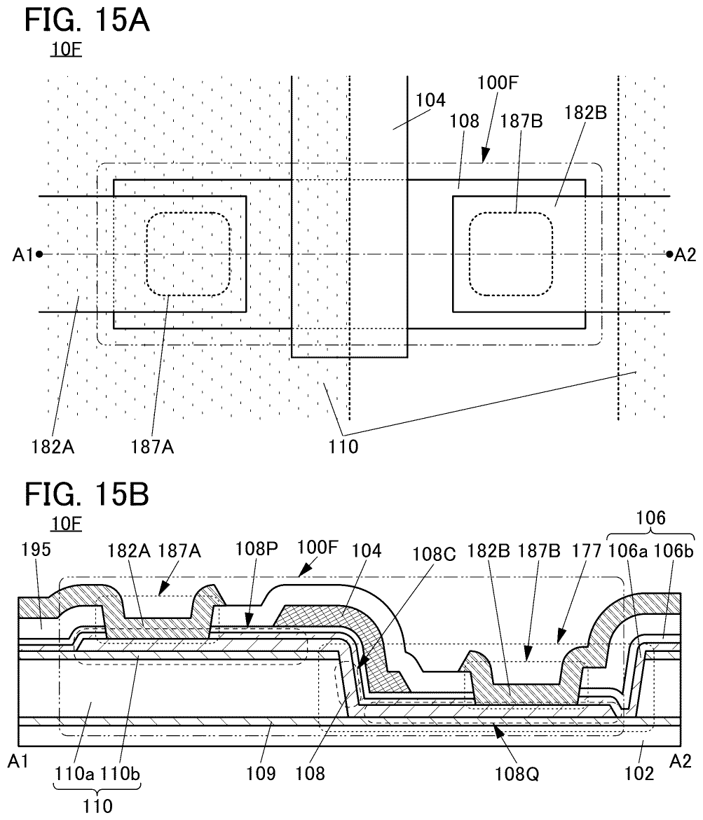

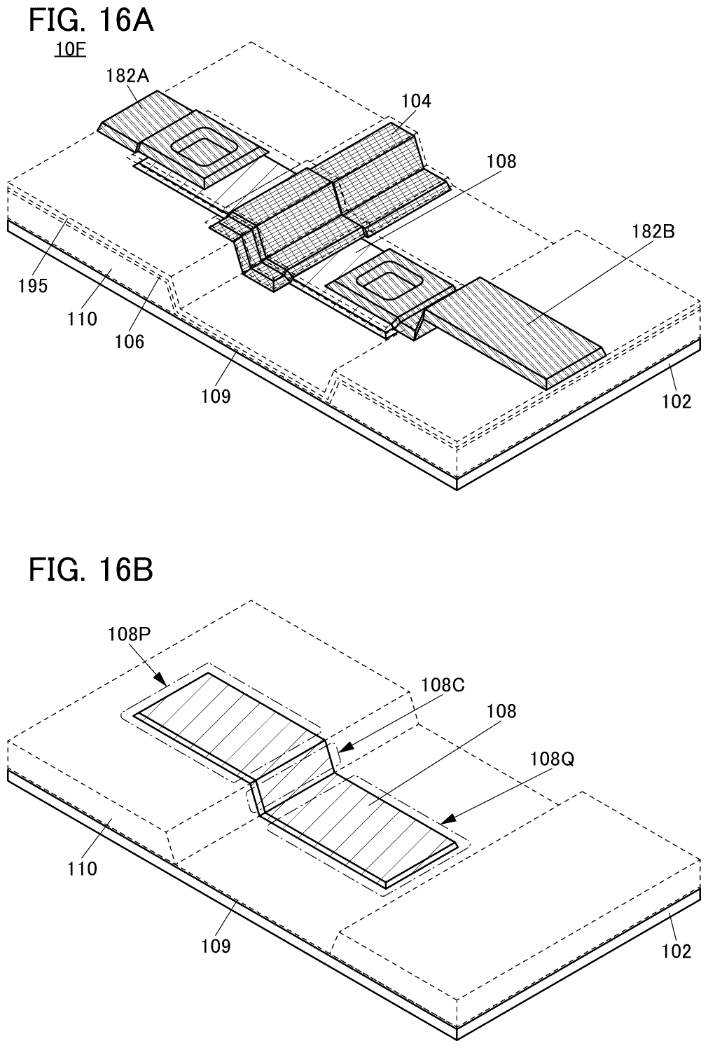

FIG. 15A is a top view of a semiconductor device 10F of one embodiment of the present invention. FIG. 15B shows a cross-sectional view of a cut plane along the dashed-dotted line A1-A2 in FIG. 15A. FIG. 16A is a perspective view of the semiconductor device 10F. FIG. 16B is a perspective view selectively illustrating the substrate 102, the insulating layer 109, the insulating layer 110, and the layer 108.

The semiconductor device 10F includes a transistor 100F, the insulating layer 109, and the insulating layer 110. The insulating layer 109 is provided over the substrate 102, and the insulating layer 110 is provided over the insulating layer 109. The insulating layer 110 includes a groove 177 reaching the insulating layer 109.

For the transistor 100F, the above description of the transistor 100 can be referred to.

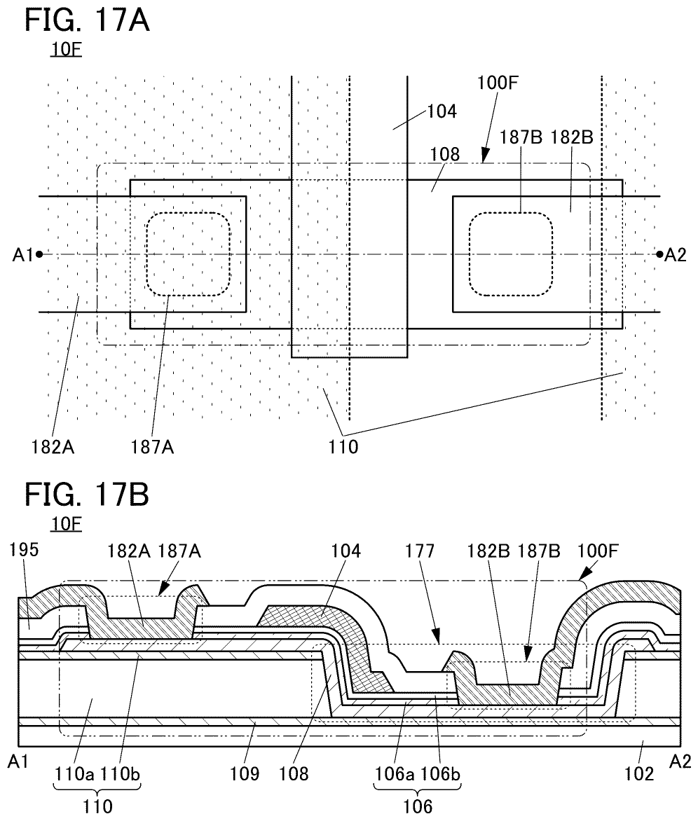

In the groove 177, the layer 108 is provided to cover the side surface of the insulating layer 110. As illustrated in FIG. 15B and FIG. 16B, the layer 108 includes the region 108C in contact with the insulating layer 110a, the region 108P in contact with the insulating layer 110b, and the region 108Q in contact with the insulating layer 109. Note that as illustrated in FIG. 17A and FIG. 17B, the layer 108 may be in contact with the side surfaces of the insulating layer 110, which face each other in the groove 177.

There is no particular limitation on the shape of the end portion of the insulating layer 110 though the shape is shown as a straight line in the top view in FIG. 17A and the like. The shape of the end portion of the insulating layer 110 may include a curve or a corner in the top view, for example. In the case where the top surface shape of the groove 177 includes a curve, the layer 108 may be provided in the portion of the curve; in the case where the shape includes a corner, the layer 108 may be provided in the portion of the corner.

In this specification and the like, the top surface shape of the groove 177 refers to the shape of an end portion of the top surface of the insulating layer 110 on the groove 177 side.

Note that the structure of the insulating layer 110 described in Structure example 1-7 can also be applied to other structure examples.

### Structure Example 1-8

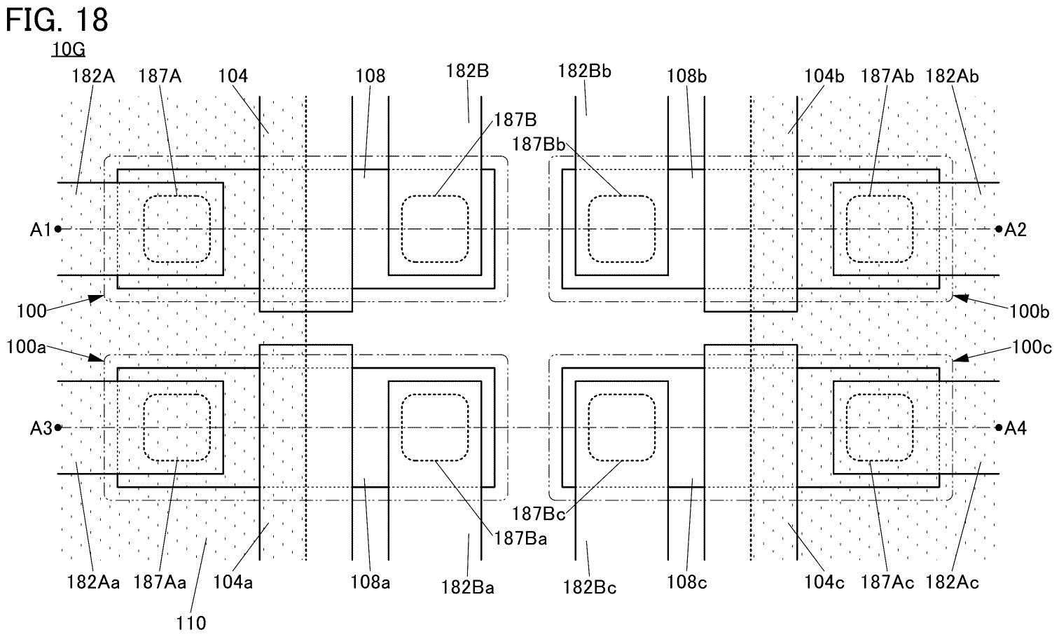

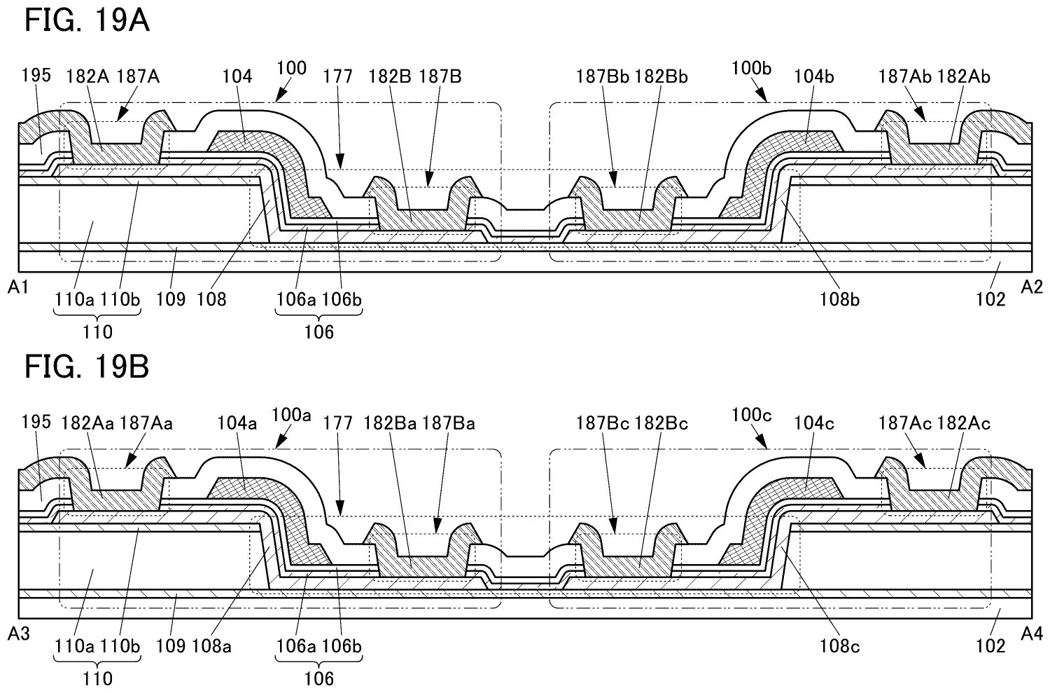

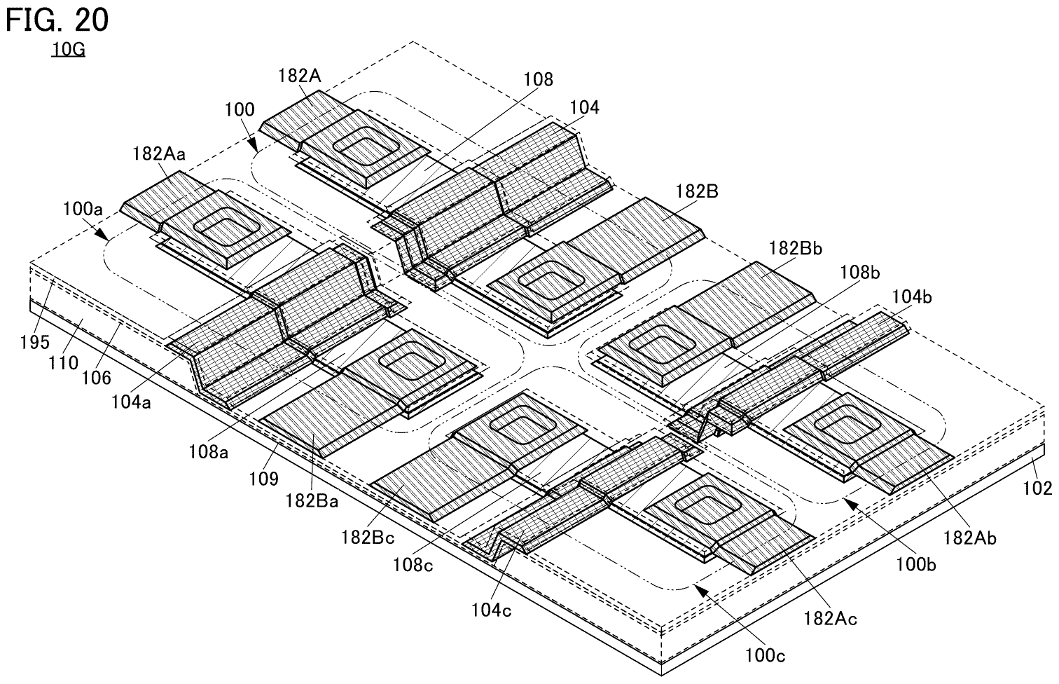

FIG. 18 shows a top view of a semiconductor device 10G of one embodiment of the present invention. FIG. 19A shows a cross-sectional view of a cross section along the dashed-dotted line A1-A2 in FIG. 18, and FIG. 19B shows a cross-sectional view of a cross section along the dashed-dotted line A3-A4. FIG. 20 is a perspective view of the semiconductor device 10G.

The semiconductor device 10G is different from the semiconductor device 10F illustrated in FIG. 15A and the like mainly in including a plurality of transistors.

The semiconductor device 10G includes the transistor 100, the transistor 100a, a transistor 100b, the transistor 100c, the insulating layer 109, and the insulating layer 110. Each of the transistor 100a to the transistor 100c has a structure similar to that of the transistor 100, and is provided across the region where the insulating layer 110 is provided and the region where the insulating layer 110 is not provided. Each of the transistor 100a to the transistor 100c can be formed in the same step as the transistor 100.

The above description can be referred to for the transistor 100; thus, the detailed description thereof is omitted.

The transistor 100a includes the layer 108a, the insulating layer 106 functioning as the gate insulating layer, and the conductive layer 104a functioning as the gate electrode.

The transistor 100b includes the layer 108b, the insulating layer 106 functioning as a gate insulating layer, and a conductive layer 104b functioning as a gate electrode.

The transistor 100c includes a layer 108c, the insulating layer 106 functioning as a gate insulating layer, and a conductive layer 104c functioning as a gate electrode.

For each of the layer 108a, the layer 108b, and the layer 108c, the material that can be used for the layer 108 can be used. The layer 108a, the layer 108b, and the layer 108c can be formed in the same step as the layer 108.

The layer 108, the layer 108a, the layer 108b, and the layer 108c each include a region in contact with the top surface and the side surface of the insulating layer 110 and a region in contact with the top surface of the insulating layer 109. It can also be said that the layer 108, the layer 108a, the layer 108b, and the layer 108c each include a region overlapping with the insulating layer 110 and a region not overlapping with the insulating layer 110. In each of the layer 108, the layer 108a, the layer 108b, and the layer 108c, a region in contact with the uppermost layer (here, the insulating layer 110b) of the insulating layer 110 functions as one of the source electrode and the drain electrode of each transistor, and a region in contact with the insulating layer 109 functions as the other.

Although the semiconductor device 10G includes four transistors here, one embodiment of the present invention is not limited thereto. There is no particular limitation on the number of the transistors in the semiconductor device. Although FIG. 18 and the like illustrate a structure in which one of the side surfaces of the insulating layer 110, which face each other in the groove 177, is provided with the layer 108 or the layer 108a and the other of the side surfaces is provided with the layer 108b or the layer 108c, one embodiment of the present invention is not limited thereto. There is no particular limitation on the number of layers 108 provided on each of the one and the other of the side surfaces of the insulating layer 110. In addition, there are no particular limitations on the number of the grooves 177 provided in the insulating layer 110, the number of the transistors provided in one groove 177, and the arrangement of the transistors in the groove 177.

FIG. 18 and the like illustrate the conductive layer 182A, the conductive layer 182B, the conductive layer 182Aa, the conductive layer 182Ba, the conductive layer 182Ab, the conductive layer 182Bb, the conductive layer 182Ac, and the conductive layer 182Bc that function as wirings. The conductive layer 182A and the conductive layer 182B respectively in the opening 187A and the opening 187B are electrically connected to the source electrode and the drain electrode of the transistor 100. The conductive layer 182Aa and the conductive layer 182Ba respectively in the opening 187Aa and the opening 187Ba are electrically connected to the source electrode and the drain electrode of the transistor 100a. The conductive layer 182Ab and the conductive layer 182Bb respectively in the opening 187Ab and the opening 187Bb are electrically connected to the source electrode and the drain electrode of the transistor 100b. The conductive layer 182Ac and the conductive layer 182Bc respectively in the opening 187Ac and the opening 187Bc are electrically connected to the source electrode and the drain electrode of the transistor 100c.

Note that the structure of the transistor described in Structure example 1-8 can also be applied to other structure examples.

### Structure Example 1-9

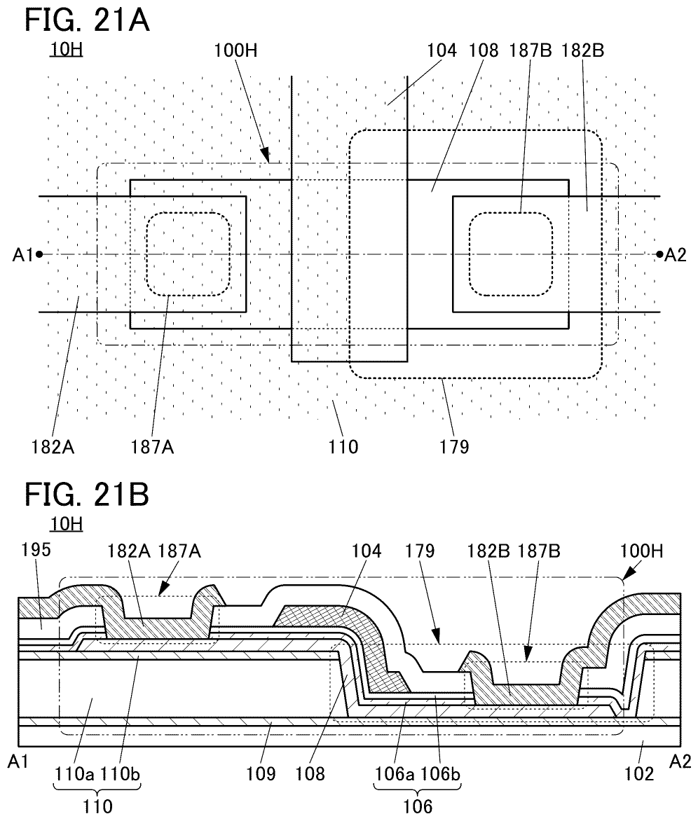

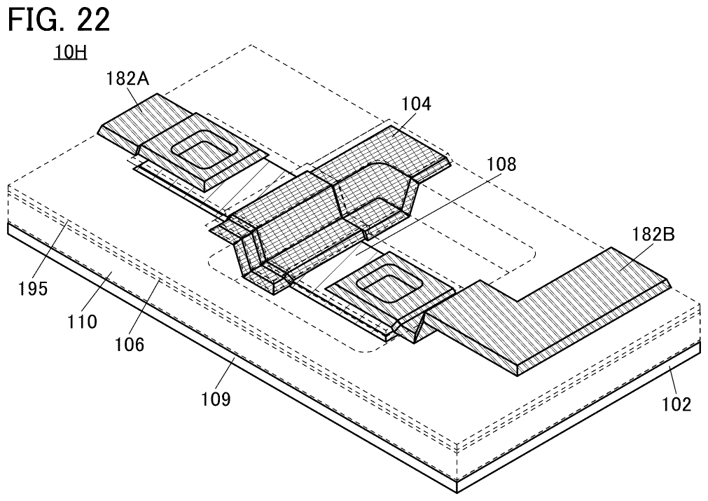

FIG. 21A shows a top view of a semiconductor device 10H of one embodiment of the present invention. FIG. 21B shows a cross-sectional view of a cut plane along the dashed-dotted line A1-A2 in FIG. 21A. FIG. 22A is a perspective view of the semiconductor device 10H.

The semiconductor device 10H includes a transistor 100H, the insulating layer 109, and the insulating layer 110. The insulating layer 109 is provided over the substrate 102, and the insulating layer 110 is provided over the insulating layer 109. The insulating layer 110 includes an opening 179 reaching the insulating layer 109.

For the transistor 100H, the above description of the transistor 100 can be referred to.

In the opening 179, the layer 108 is provided to cover the side surface of the insulating layer 110.

There is no limitation on the top surface shape of the opening 179, and the shape can be a circular shape; an elliptical shape; a polygonal shape such as a triangular shape, a tetragonal shape (including a rectangular shape, a rhombic shape, and a square shape), or a pentagonal shape; or any of these polygonal shapes whose corners are rounded, for example. Note that the polygonal shape can be either a concave polygonal shape (a polygonal shape at least one of the interior angles of which is greater than) 180° or a convex polygonal shape (a polygonal shape all the interior angles of which are less than or equal to) 180°. In this specification and the like, a circular shape is not necessarily a perfect circular shape. In the case where the top surface shape of the opening 179 includes a curve, the layer 108 may be provided in the portion of the curve; in the case where the shape includes a corner, the layer 108 may be provided in the portion of the corner.

In this specification and the like, the top surface shape of the opening 179 refers to the shape of an end portion of the top surface of the insulating layer 110 on the opening 179 side.

Although FIG. 21A and the like illustrate a structure in which the layer 108 is provided in a portion of the opening 179 whose top surface shape is linear in the top view, one embodiment of the present invention is not limited thereto. In the case where the top surface shape of the opening 179 includes a curve, the layer 108 may be provided in the portion of the curve; in the case where the top surface shape of the opening 179 includes a corner, the layer 108 may be provided in the portion of the corner.

Note that the structure of the insulating layer 110 described in Structure example 1-9 can also be applied to other structure examples.

### Structure Example 1-10

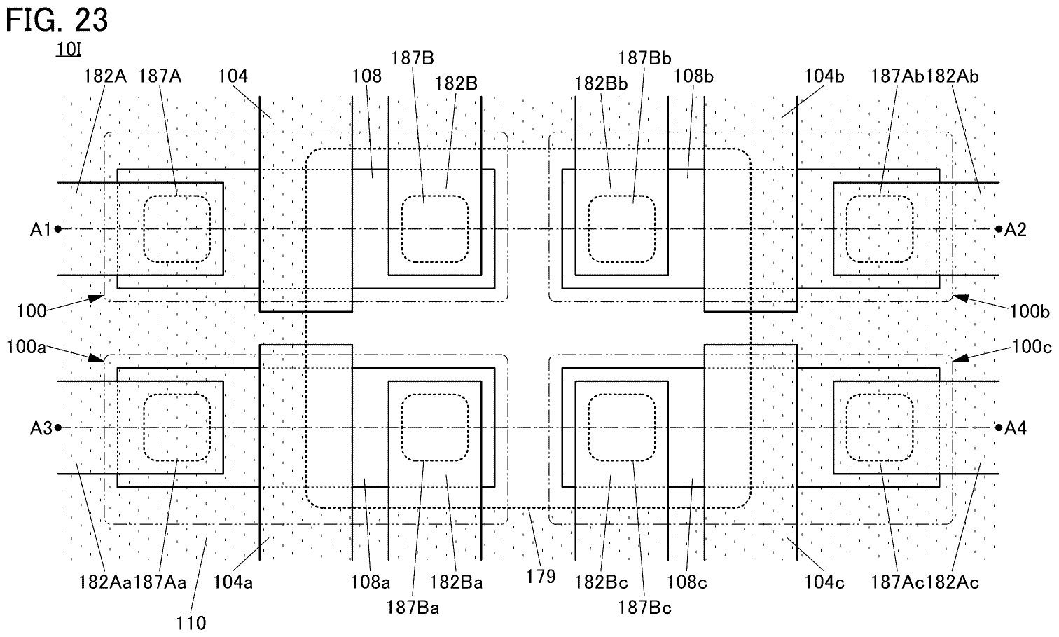

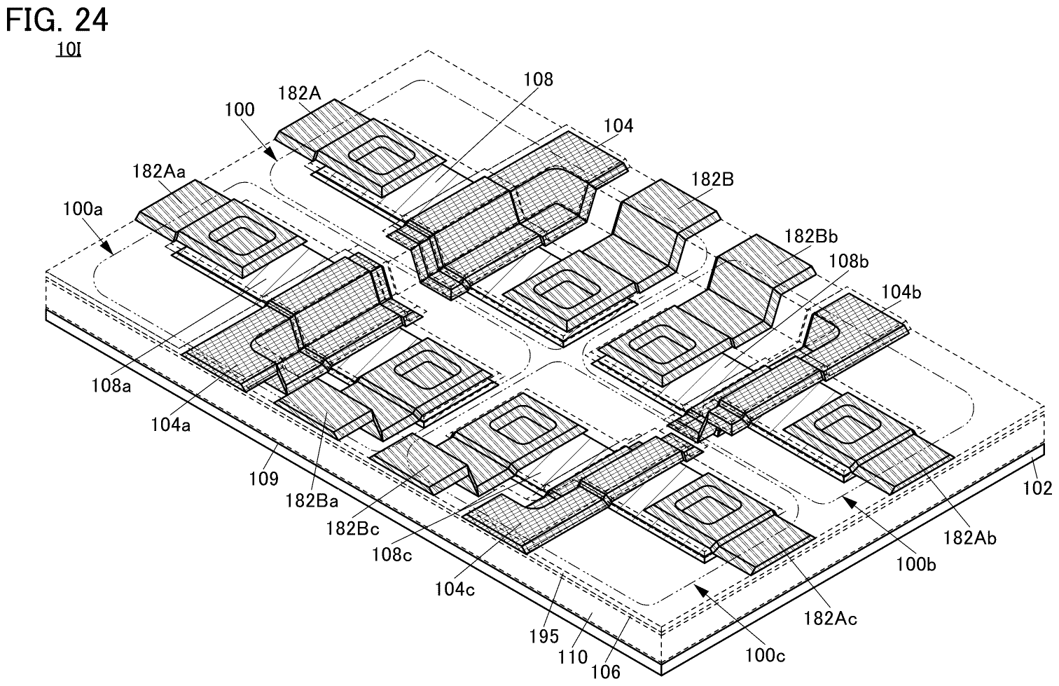

FIG. 23 shows a top view of the semiconductor device 10I of one embodiment of the present invention. FIG. 19A and FIG. 19A can be referred to for cross-sectional views of cross sections taken along the dashed-dotted line A1-A2 and the dashed-dotted line A3-A4 illustrated in FIG. 23. FIG. 24 is a perspective view of the semiconductor device 10I.

The semiconductor device 10I is different from the semiconductor device 10H illustrated in FIG. 21A and the like mainly in including a plurality of transistors.

The semiconductor device 10I includes the transistor 100, the transistor 100a, the transistor 100b, the transistor 100c, the insulating layer 109, and the insulating layer 110. The transistor 100a to the transistor 100c each have a structure similar to that of the transistor 100, and are provided across the region where the insulating layer 110 is provided and the region where the insulating layer 110 is not provided. Each of the transistor 100a to the transistor 100c can be formed in the same step as the transistor 100.

The above description can be referred to for the transistor 100 and the transistor 100a to the transistor 100c; thus, the detailed description thereof is omitted.

Although FIG. 23 and the like illustrate a structure in which the layer 108 and the layer 108a to the layer 108c are each provided in a portion of the opening 179 whose top surface shape is linear in the top view, one embodiment of the present invention is not limited thereto. One or more of the layer 108 and the layer 108a to the layer 108c may be provided in a curved portion or may be provided to cover a corner of the opening 179.

Although the semiconductor device 10I includes four transistors here, one embodiment of the present invention is not limited thereto. There is no particular limitation on the number of the transistors in the semiconductor device. In addition, there are no particular limitations on the number of the openings 179 provided in the insulating layer 110, the number of the transistors provided in one opening 179, and the arrangement of the transistors in the opening 179.

Note that the structure of the transistor described in Structure example 1-10 can also be applied to other structure examples.

### Structure Example 2

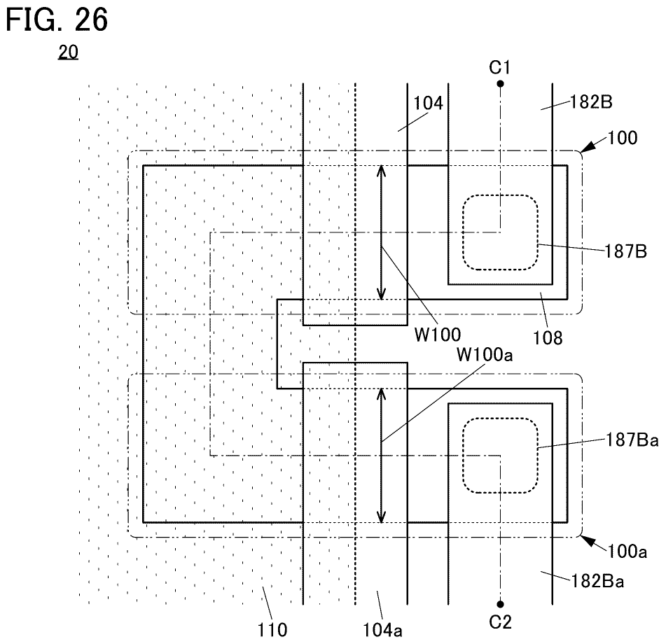

FIG. 26 to FIG. 44 are circuit diagrams of the semiconductor device of one embodiment of the present invention. illustrate top views, cross-sectional views, and perspective views of a semiconductor device of embodiments of the present invention. In the following description, the transistor 100 is mainly used as an example of the transistor included in the semiconductor device of one embodiment of the present invention. Without limitation to this, the semiconductor device of one embodiment of the present invention may include any one or more of the transistor 100 to the transistor 100H described above.

The semiconductor device of one embodiment of the present invention includes at least two transistors, and any of a gate, a source, and a drain of one transistor is electrically connected to any of a gate, a source, and a drain of another transistor. Alternatively, the semiconductor device of one embodiment of the present invention includes a transistor and a capacitor, and any of a gate, a source, and a drain of the transistor is electrically connected to one terminal of the capacitor.

The semiconductor device of one embodiment of the present invention can be used for a display device. The display device includes a transistor and a display element. A source or a drain of the transistor is electrically connected to a pixel electrode of the display element.

### Structure Example 2-1

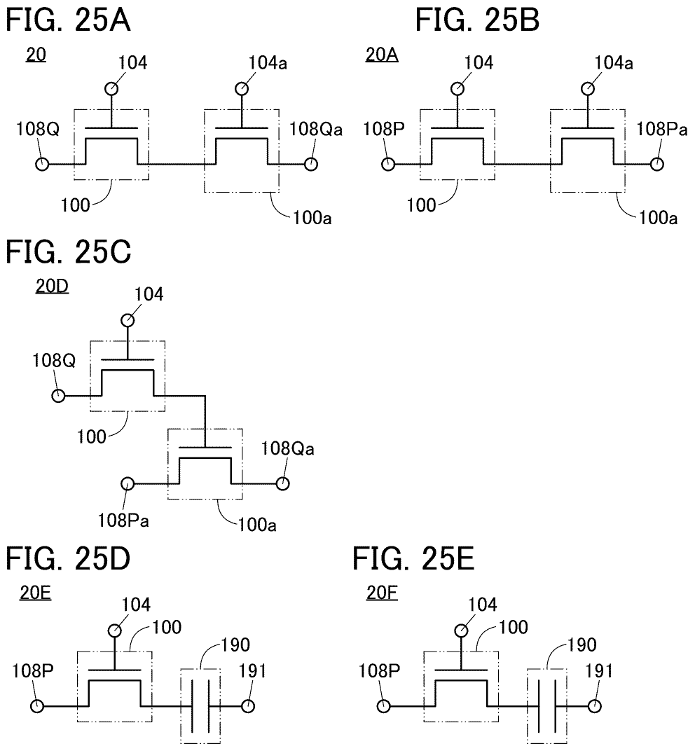

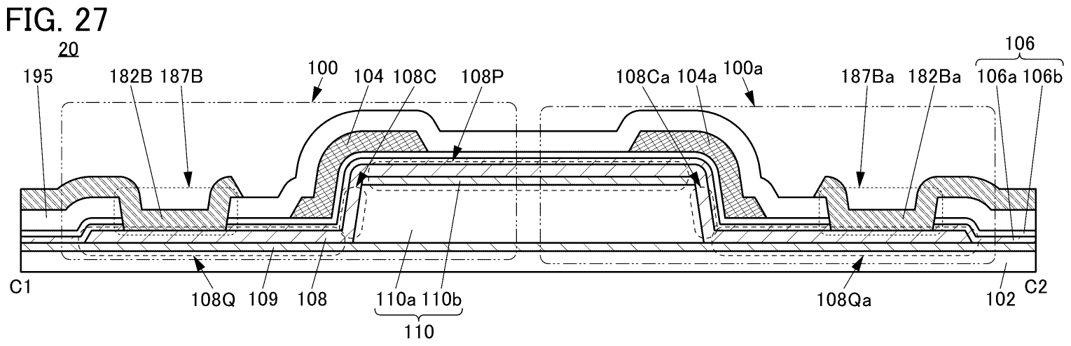

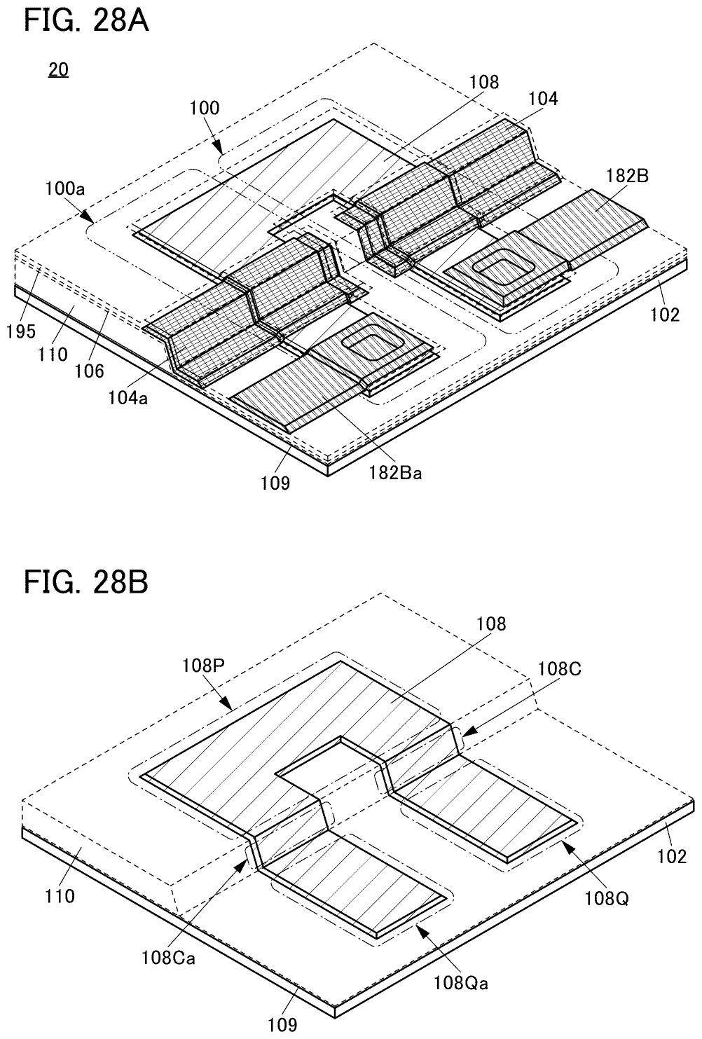

FIG. 25A shows an equivalent circuit diagram of a semiconductor device 20 of one embodiment of the present invention. FIG. 26 shows a top view of the semiconductor device 20. FIG. 27 shows a cross-sectional view of a cross section along the dashed-dotted line C1-C2 in FIG. 26. FIG. 28A shows a perspective view of the semiconductor device 20. FIG. 28B is a perspective view selectively illustrating the substrate 102, the insulating layer 109, the insulating layer 110, and the layer 108.

The semiconductor device 20 includes the transistor 100, the transistor 100a, the insulating layer 109, and the insulating layer 110. One of the source and the drain of the transistor 100 is electrically connected to one of the source and the drain of the transistor 100a.

The transistor 100 includes the layer 108, the insulating layer 106 functioning as a gate insulating layer, and the conductive layer 104 functioning as a gate electrode. The transistor 100a includes the layer 108, the insulating layer 106 functioning as a gate insulating layer, and the conductive layer 104a functioning as a gate electrode. The transistor 100a has a structure similar to that of the transistor 100. The transistor 100a and the transistor 100 can be formed in the same step.

The transistor 100 and the transistor 100a share the layer 108. The layer 108 includes the region 108P in contact with the insulating layer 110b, the region 108Q and a region 108Qa which are in contact with the insulating layer 109, and the region 108C and a region 108Ca which are in contact with the insulating layer 110a. A portion where the region 108Qa is in contact with the insulating layer 109 is different from a portion where the region 108Q is in contact with the insulating layer 109. A portion where the region 108Ca is in contact with the insulating layer 110a is different from a portion where the region 108C is in contact with the insulating layer 110a.

The region 108P functions as one of the source electrode and the drain electrode of the transistor 100 and also functions as one of the source electrode and the drain electrode of the transistor 100a. The region 108Q functions as the other of the source electrode and the drain electrode of the transistor 100, and the region 108Qa functions as the other of the source electrode and the drain electrode of the transistor 100a. The region 108C functions as the channel formation region of the transistor 100, and the region 108Ca functions as the channel formation region of the transistor 100a.

When the transistor 100 and the transistor 100a share the layer 108, the area occupied by the semiconductor device can be reduced.

In the semiconductor device 20, the region 108P can be regarded as functioning as a wiring that electrically connects the transistor 100 and the transistor 100a.

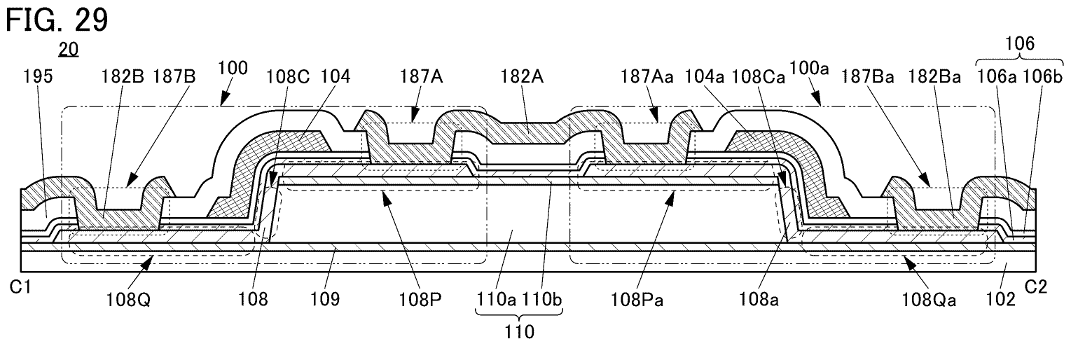

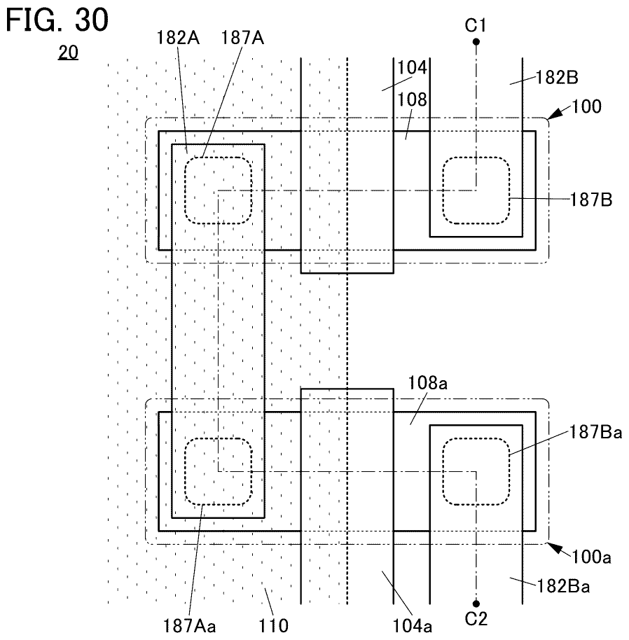

Here, in the case of using an oxide conductor (OC) for a wiring, the electric resistance of the wiring may be higher than in the case of using a metal or an alloy. In the case where the distance between the transistor 100 and the transistor 100a is long and the wiring electrically connecting the transistor 100 and the transistor 100a requires relatively low wiring resistance, a metal or an alloy can be suitably used for the wiring. For example, as illustrated in FIG. 29 and FIG. 30, a structure may be employed in which the transistor 100 and the transistor 100a do not share the layer 108 and the region 108P included in the layer 108a is electrically connected to the region 108Pa included in the layer 108a through the conductive layer 182A. A metal or an alloy can be suitably used for the conductive layer 182A.

In the case where the distance between the transistor 100 and the transistor 100a is short and the wiring electrically connecting the transistor 100 and the transistor 100a requires relatively high wiring resistance, as illustrated in FIG. 26 and the like, the region 108P included in the layer 108 is shared by the transistor 100 and the transistor 100a and the region 108P functions as the wiring, whereby one of the source and the drain of the transistor 100 may be electrically connected to one of the source and the drain of the transistor 100a. Thus, the area occupied by the semiconductor device can be reduced.

The method for electrically connecting the transistor 100 and the transistor 100a is determined in accordance with the material used for the layer 108 and the wiring resistance required for the wiring electrically connecting the transistor 100 and the transistor 100a.

Note that the structure of the layer 108 described in Structure example 2-1 can also be applied to other structure examples.

A structure example which is partly different from that of Structure example 2-1 shown above will be described below. Note that description of the same portions as those in Structure example 2-1 shown above is omitted below in some cases. Furthermore, in drawings that are referred to later, the same hatching pattern is applied to portions having functions similar to those in Structure example 2-1 shown above, and the portions are not denoted by reference numerals in some cases.

### Structure Example 2-2

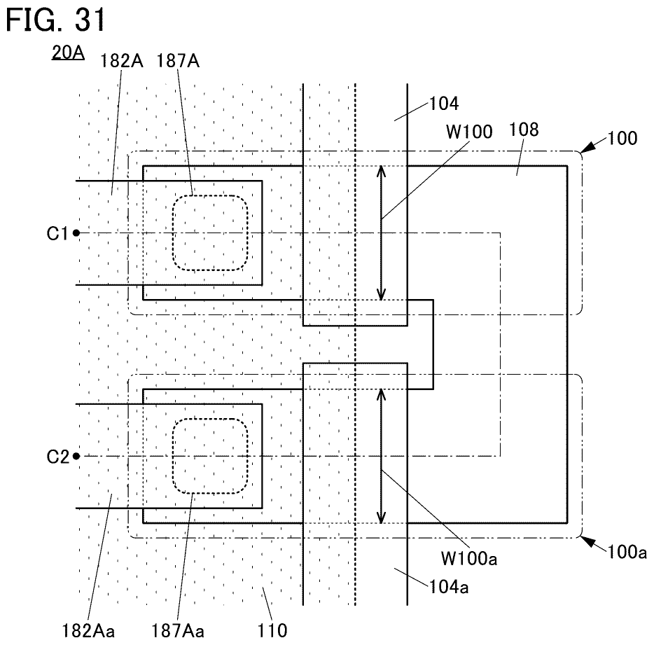

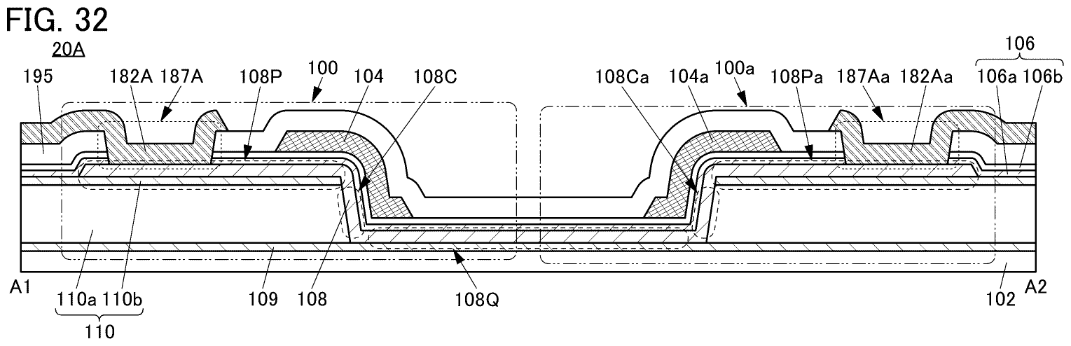

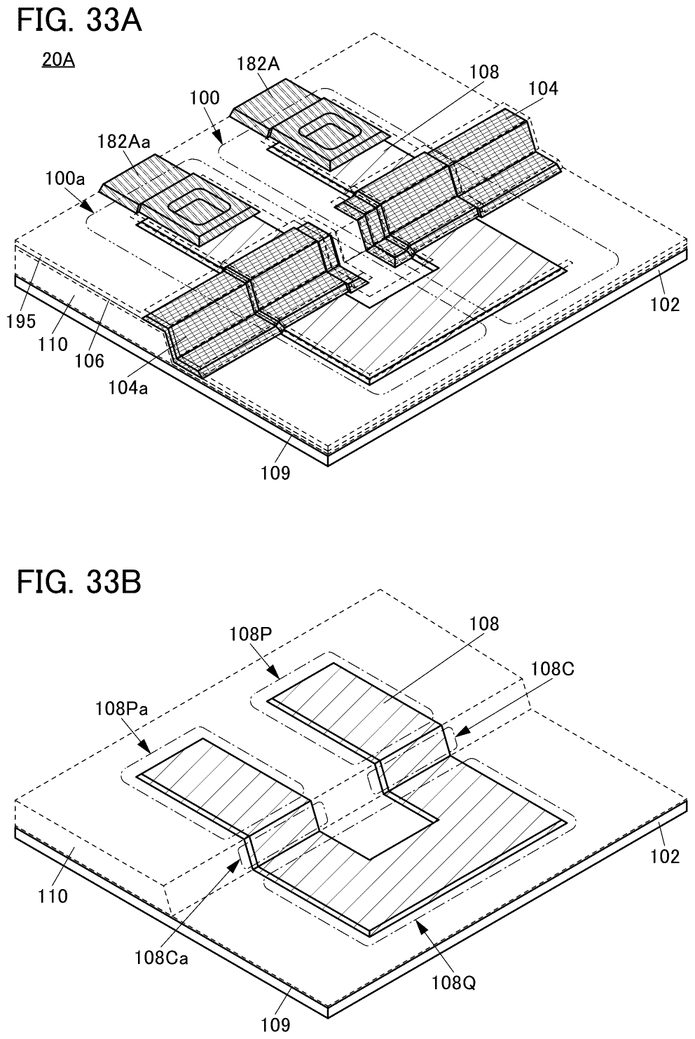

FIG. 25B shows an equivalent circuit diagram of the semiconductor device 20A of one embodiment of the present invention. FIG. 31 shows a top view of the semiconductor device 20A. FIG. 32 shows a cross-sectional view of a cross section along the dashed-dotted line C1-C2 in FIG. 31. FIG. 33A is a perspective view of the semiconductor device 20A. FIG. 33B is a perspective view selectively illustrating the substrate 102, the insulating layer 109, the insulating layer 110, and the layer 108.

The semiconductor device 20A includes the transistor 100, the transistor 100a, the insulating layer 109, and the insulating layer 110. The other of the source and the drain of the transistor 100 is electrically connected to the other of the source and the drain of the transistor 100a. The semiconductor device 20A is different from the semiconductor device 20 illustrated in FIG. 26 and the like mainly in the structure of the layer 108.

The layer 108 includes the region 108P and the region 108Pa that are in contact with the insulating layer 110b, the region 108Q that is in contact with the insulating layer 109, and the region 108C and the region 108Ca that are in contact with the insulating layer 110a. A portion where the region 108Pa is in contact with the insulating layer 110b is different from a portion where the region 108P is in contact with the insulating layer 110b.

The region 108Q functions as the other of the source electrode and the drain electrode of the transistor 100 and also functions as the other of the source electrode and the drain electrode of the transistor 100a. The region 108P functions as one of the source electrode and the drain electrode of the transistor 100, and the region 108Pa functions as one of the source electrode and the drain electrode of the transistor 100a.

Note that the structure of the layer 108 described in Structure example 2-2 can also be applied to other structure examples.

### Structure Example 2-3

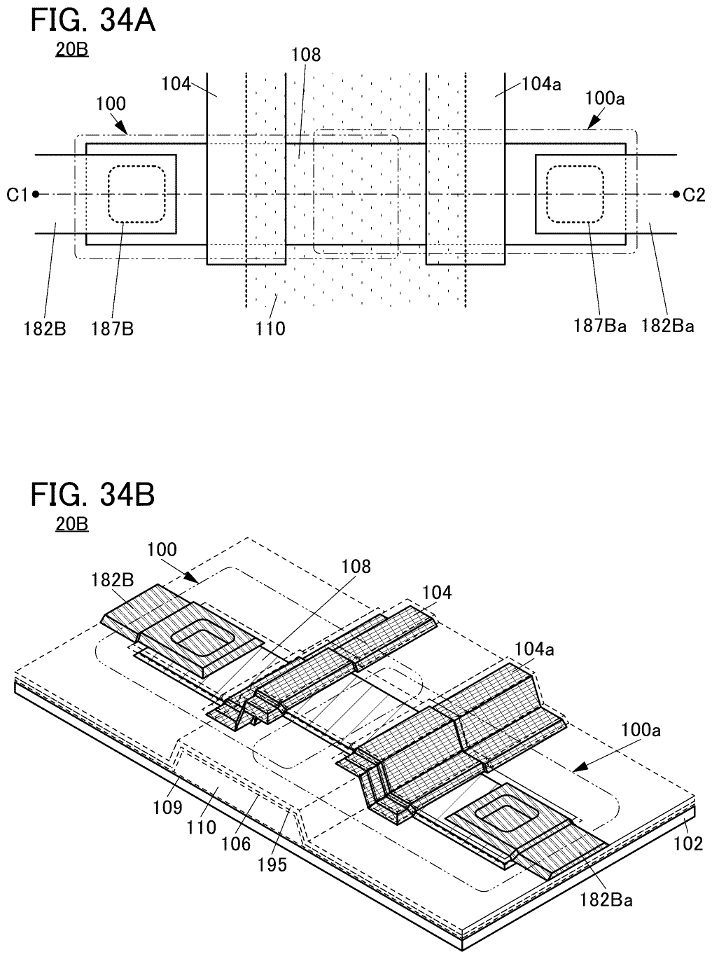

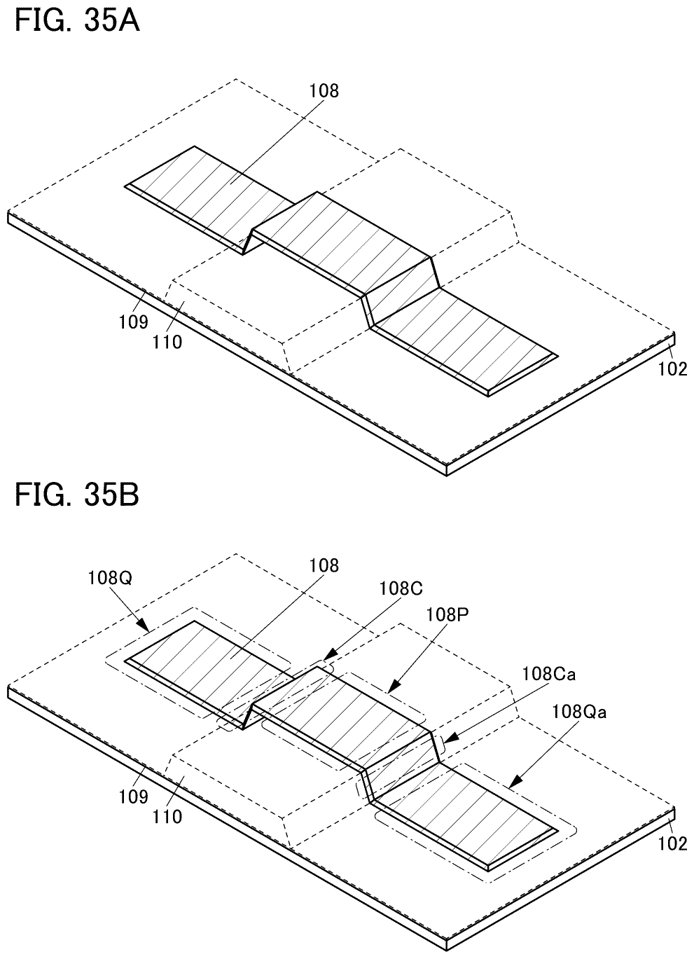

FIG. 34A is a top view of a semiconductor device 20B of one embodiment of the present invention. FIG. 27 can be referred to for a cross-sectional view of a cross section along the dashed-dotted line C1-C2 in FIG. 34A. FIG. 34B is a perspective view of the semiconductor device 20B. FIG. 35A and FIG. 35B are perspective views selectively illustrating the substrate 102, the insulating layer 109, the insulating layer 110, and the layer 108. FIG. 25A can be referred to for an equivalent circuit diagram of the semiconductor device 20B.

The semiconductor device 20B includes the transistor 100, the transistor 100a, the insulating layer 109, and the insulating layer 110. One of the source and the drain of the transistor 100 is electrically connected to one of the source and the drain of the transistor 100a.

The transistor 100 includes the layer 108, the insulating layer 106 functioning as a gate insulating layer, and the conductive layer 104 functioning as a gate electrode. The transistor 100a includes the layer 108, the insulating layer 106 functioning as a gate insulating layer, and the conductive layer 104a functioning as a gate electrode.

The transistor 100 and the transistor 100a share the layer 108. The layer 108 includes the region 108P in contact with the insulating layer 110b, the region 108Q and the region 108Qa which are in contact with the insulating layer 109, and the region 108C and a region 108Ca which are in contact with the insulating layer 110a. The semiconductor device 20B is different from the semiconductor device 20 illustrated in FIG. 26 and the like mainly in that the side surface of the insulating layer 110a in contact with the region 108Ca is different from the side surface of the insulating layer 110a in contact with the region 108C.

Note that the structure of the layer 108 described in Structure example 2-3 can also be applied to other structure examples.

### Structure Example 2-4

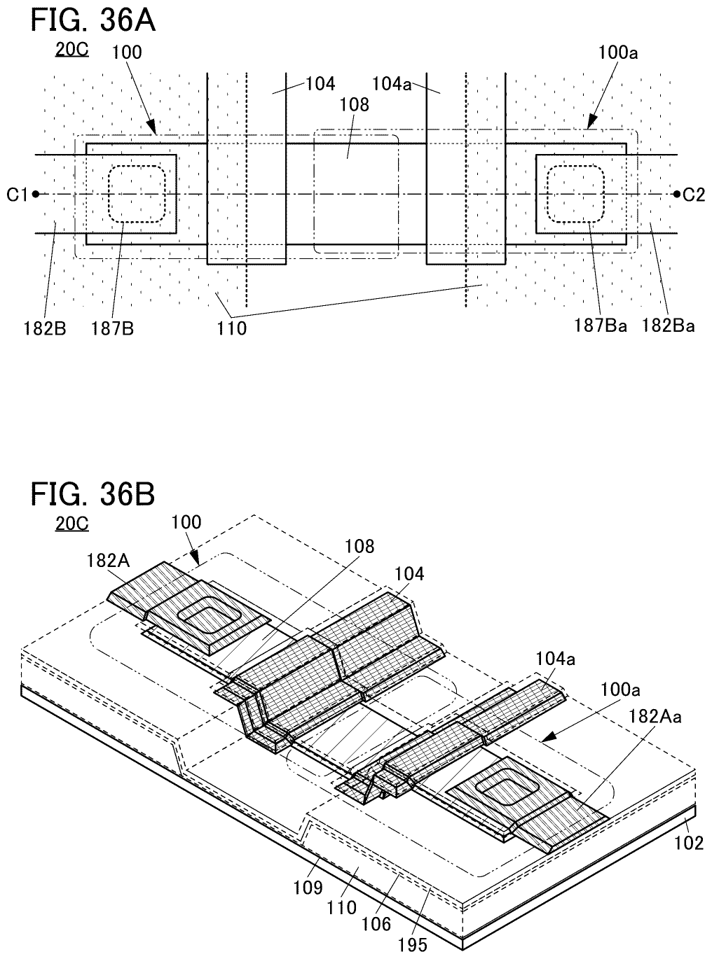

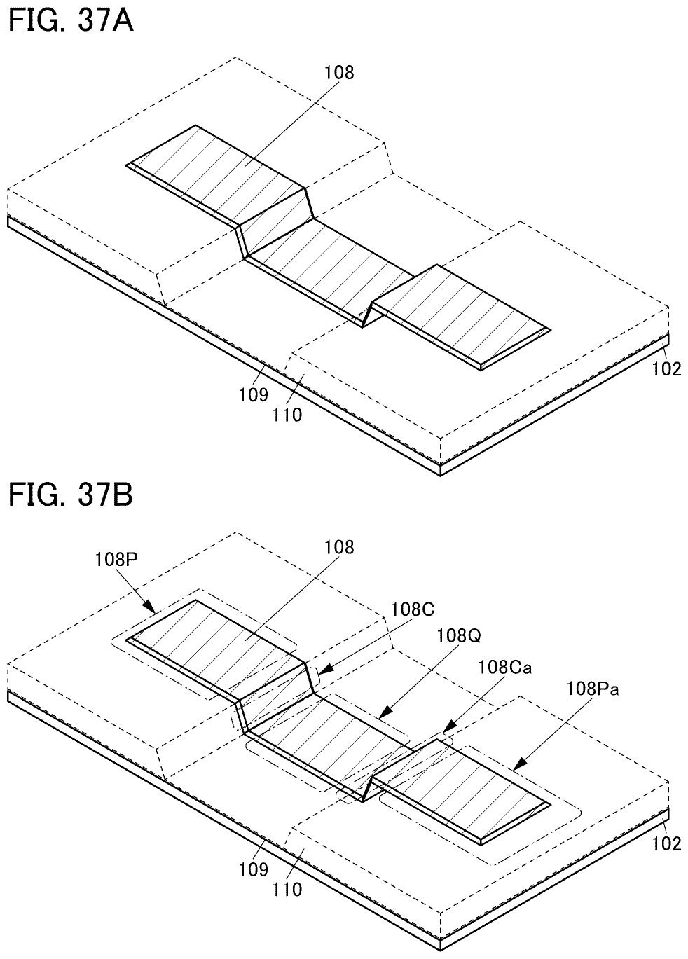

FIG. 36A is a top view of a semiconductor device 20C of one embodiment of the present invention. FIG. 32 can be referred to for a cross-sectional view of a cross section along the dashed-dotted line C1-C2 in FIG. 36A. FIG. 36B is a perspective view of the semiconductor device 20C. FIG. 37A and FIG. 37B are perspective views selectively illustrating the substrate 102, the insulating layer 109, the insulating layer 110, and the layer 108. FIG. 25B can be referred to for an equivalent circuit diagram of the semiconductor device 20C.

The semiconductor device 20C includes the transistor 100, the transistor 100a, the insulating layer 109, and the insulating layer 110. The other of the source and the drain of the transistor 100 is electrically connected to the other of the source and the drain of the transistor 100a.

The transistor 100 includes the layer 108, the insulating layer 106 functioning as a gate insulating layer, and the conductive layer 104 functioning as a gate electrode. The transistor 100a includes the layer 108, the insulating layer 106 functioning as a gate insulating layer, and the conductive layer 104a functioning as a gate electrode.

The transistor 100 and the transistor 100a share the layer 108. The layer 108 includes the region 108P and the region 108Pa that are in contact with the insulating layer 110b, the region 108Q that is in contact with the insulating layer 109, and the region 108C and the region 108Ca that are in contact with the insulating layer 110a. The semiconductor device 20C is different from the semiconductor device 20A illustrated in FIG. 31 and the like mainly in that the side surface of the insulating layer 110a in contact with the region 108Ca is different from the side surface of the insulating layer 110a in contact with the region 108C.

Note that the structure of the layer 108 described in Structure example 2-4 can also be applied to other structure examples.

### Structure Example 2-5

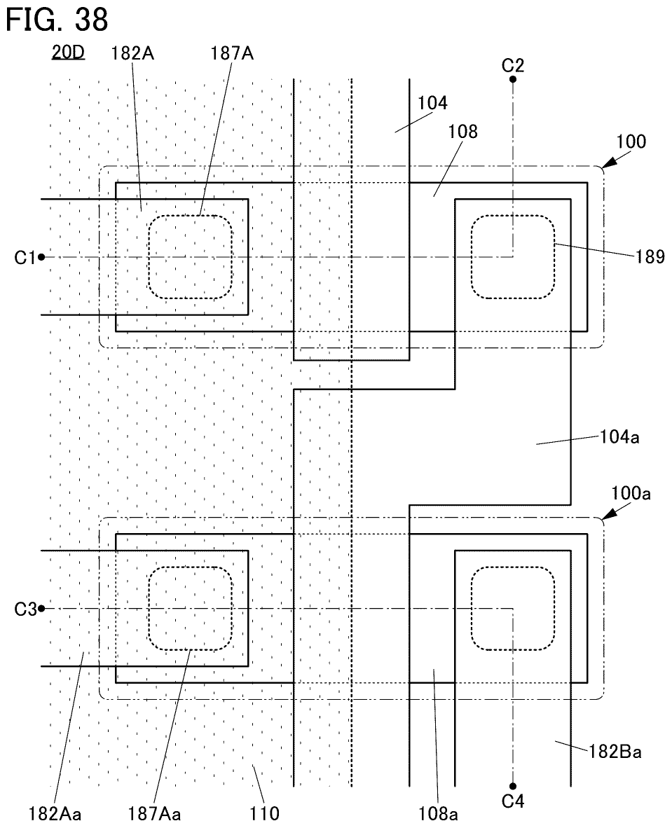

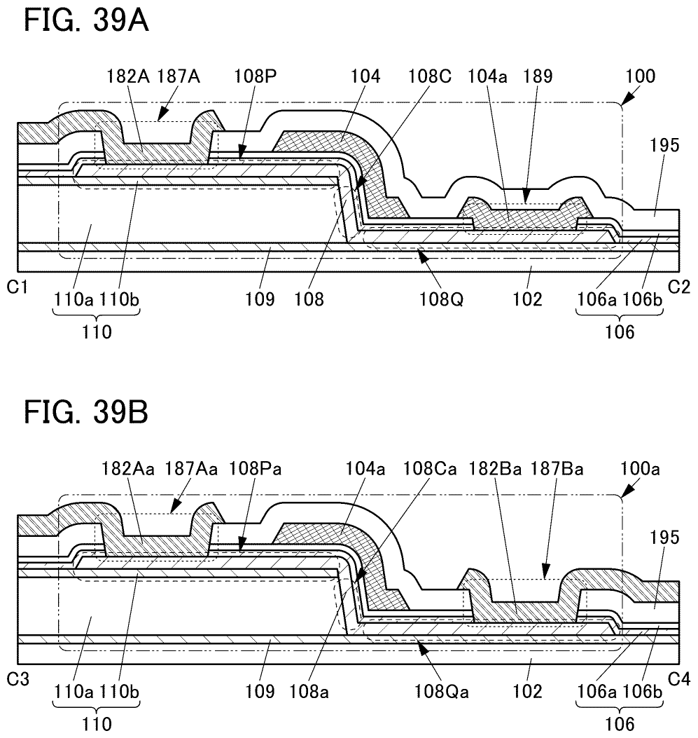

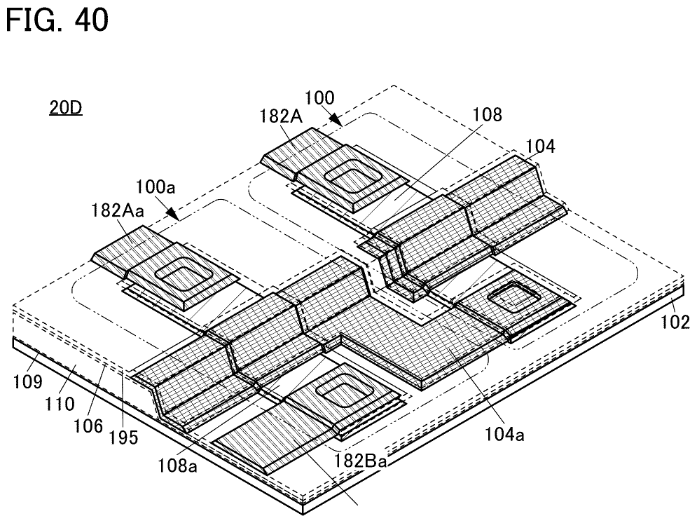

FIG. 25C shows an equivalent circuit diagram of the semiconductor device 20D of one embodiment of the present invention. FIG. 38 is a top view of the semiconductor device 20D. FIG. 39A is a cross-sectional view of a cross section along the dashed-dotted line C1-C2 in FIG. 38, and FIG. 39B is a cross-sectional view of a cross section along the dashed-dotted line C3-C4 in FIG. 38. FIG. 40 is a perspective view of the semiconductor device 20D.

The semiconductor device 20D includes the transistor 100, the transistor 100a, the insulating layer 109, and the insulating layer 110. The other of the source and the drain of the transistor 100 is electrically connected to a gate of the transistor 100a.

The transistor 100 includes the layer 108, the insulating layer 106, and the conductive layer 104. The transistor 100a includes the layer 108a, the insulating layer 106, and the conductive layer 104a. An opening 189 reaching the region 108Q is provided in the insulating layer 106, and the conductive layer 104a is provided to cover the opening 189. The conductive layer 104a functioning as the gate electrode of the transistor 100a is in contact with the region 108Q functioning as the other of the source electrode and the drain electrode of the transistor 100 in the opening 189.

Note that the structure of the conductive layer 104a described in Structure example 2-5 can also be applied to other structure examples.

### Structure Example 2-6

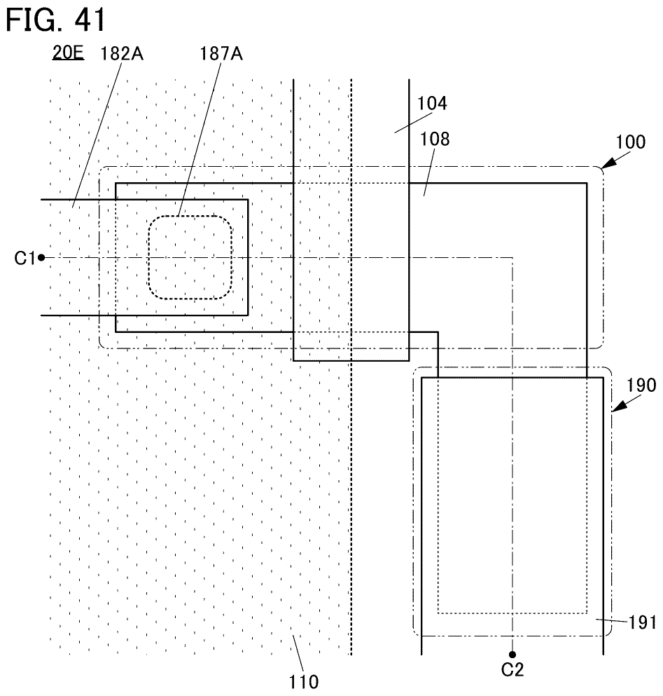

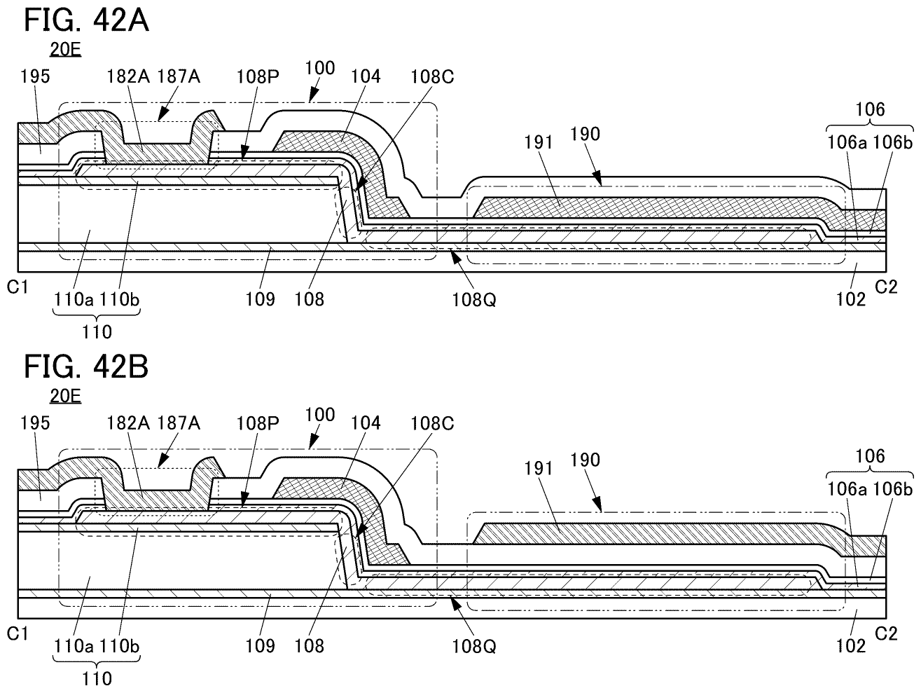

FIG. 25D shows an equivalent circuit diagram of a semiconductor device 20E of one embodiment of the present invention. FIG. 41 is a top view of the semiconductor device 20E. FIG. 42A shows a cross-sectional view of a cross section along the dashed-dotted line C1-C2 in FIG. 41.

The semiconductor device 20E includes the transistor 100, the capacitor 190, the insulating layer 109, and the insulating layer 110. The capacitor 190 includes a pair of electrodes and a dielectric interposed between the pair of electrodes. The source or the drain of the transistor 100 is electrically connected to one of the pair of electrodes of the capacitor 190.

The region 108Q included in the layer 108 functions as the other of the source electrode and the drain electrode of the transistor 100 and also functions as one of the pair of electrodes of the capacitor 190. The conductive layer 191 functioning as the other of the pair of electrodes of the capacitor 190 is provided over the insulating layer 106. The conductive layer 191 can be formed in, for example, the same step as the conductive layer 104 included in the transistor 100. The insulating layer 106 in a region interposed between the region 108Q and the conductive layer 191 functions as the dielectric of the capacitor 190.

Although the region 108Q and the conductive layer 191 function as the pair of electrodes of the capacitor 190 and the insulating layer 106 interposed between these electrodes functions as a dielectric here, one embodiment of the present invention is not limited thereto. There is no particular limitation on the structure of the capacitor 190.

As illustrated in FIG. 42B, the conductive layer 191 may be provided over the insulating layer 195. The conductive layer 191 can be formed in the same step as, for example, the conductive layer 182A included in the transistor 100. The insulating layer 106 and the insulating layer 195 in a region interposed between the region 108Q and the conductive layer 191 function as the dielectric of the capacitor 190.

Since the transistor 100 and the capacitor 190 share the region 108Q, it is not necessary to provide one of the pair of electrodes of the capacitor 190 separately from the layer 108, which simplifies the manufacturing process of the semiconductor device and thus the manufacturing cost can be reduced. Moreover, the yield of the semiconductor device can be increased.

Although the region 108Q and the conductive layer 191 function as the pair of electrodes of the capacitor 190 and the insulating layer 106 and the insulating layer 195 interposed between these electrodes function as a dielectric here, one embodiment of the present invention is not limited thereto. There is no particular limitation on the structure of the capacitor 190.

Note that the structure of the capacitor 190 described in Structure example 2-6 can also be applied to other structure examples.

### Structure Example 2-7

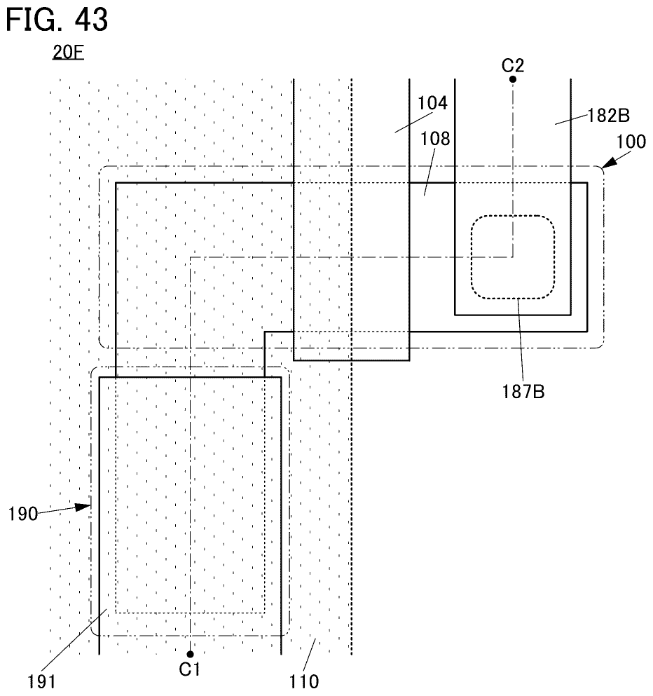

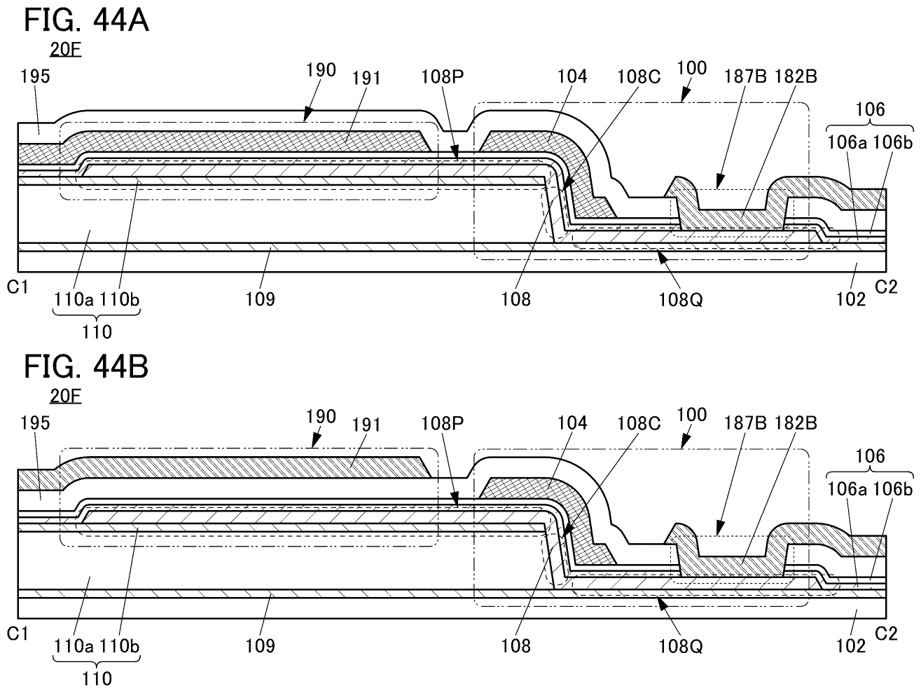

FIG. 25E shows an equivalent circuit diagram of the semiconductor device 20F of one embodiment of the present invention. FIG. 43 shows a top view of the semiconductor device 20F. FIG. 44A is a cross-sectional view of a cross section along the dashed-dotted line C1-C2 in FIG. 43.

The semiconductor device 20F includes the transistor 100, the capacitor 190, the insulating layer 109, and the insulating layer 110. The capacitor 190 includes a pair of electrodes and a dielectric interposed between the pair of electrodes. The source or the drain of the transistor 100 is electrically connected to one of the pair of electrodes of the capacitor 190.

The region 108P included in the layer 108 functions as one of the source electrode and the drain electrode of the transistor 100 and also functions as one of the pair of electrodes of the capacitor 190. The conductive layer 191 functioning as the other of the pair of electrodes of the capacitor 190 is provided over the insulating layer 106. The conductive layer 191 can be formed in, for example, the same step as the conductive layer 104 included in the transistor 100. The insulating layer 106 in a region interposed between the region 108P and the conductive layer 191 functions as the dielectric of the capacitor 190.

Although the region 108P and the conductive layer 191 function as the pair of electrodes of the capacitor 190 and the insulating layer 106 interposed between these electrodes functions as a dielectric here, one embodiment of the present invention is not limited thereto. There is no particular limitation on the structure of the capacitor 190.

As illustrated in FIG. 44B, the conductive layer 191 may be provided over the insulating layer 195. The conductive layer 191 can be formed in the same step as, for example, the conductive layer 182B included in the transistor 100. The insulating layer 106 and the insulating layer 195 in a region interposed between the region 108P and the conductive layer 191 function as the dielectric of the capacitor 190.

Since the transistor 100 and the capacitor 190 share the region 108P, it is not necessary to provide one of the pair of electrodes of the capacitor 190 separately from the layer 108, which simplifies the manufacturing process of the semiconductor device and thus the manufacturing cost can be reduced. Moreover, the yield of the semiconductor device can be increased.

Although the region 108P and the conductive layer 191 function as the pair of electrodes of the capacitor 190 and the insulating layer 106 and the insulating layer 195 interposed between these electrodes function as a dielectric here, one embodiment of the present invention is not limited thereto. There is no particular limitation on the structure of the capacitor 190.

Note that the structure of the capacitor 190 described in Structure example 2-7 can also be applied to other structure examples.

### Structure Example 2-8

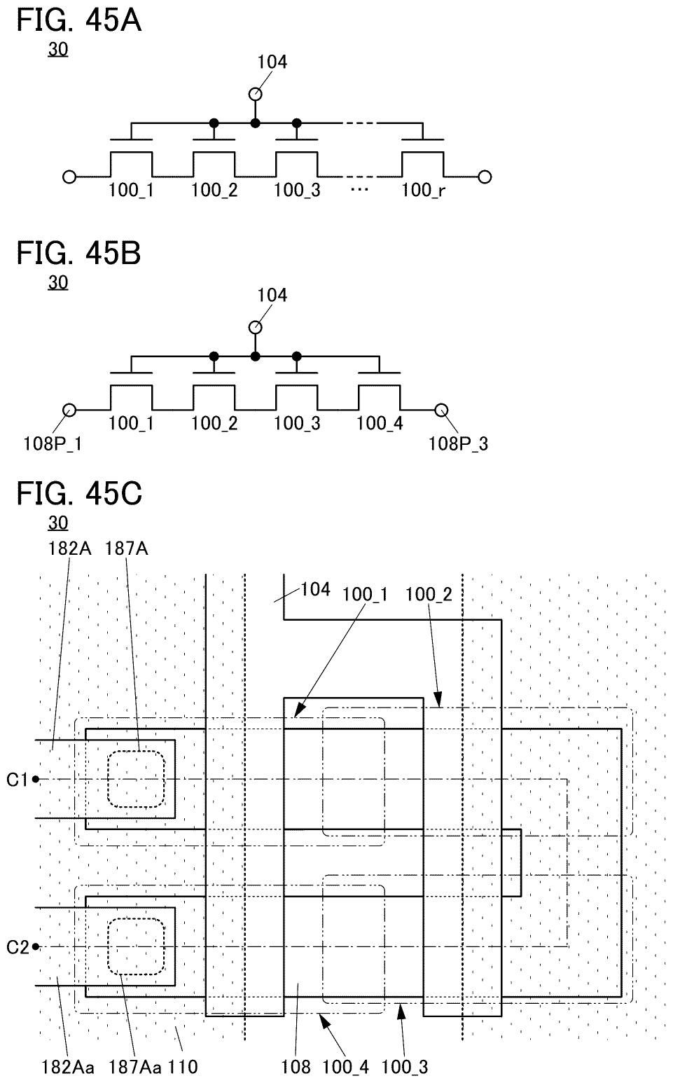

FIG. 45A is an equivalent circuit diagram of a semiconductor device 30 of one embodiment of the present invention. The semiconductor device 30 includes a transistor 100_1 to a transistor 100_r (r is an integer greater than or equal to 2), the insulating layer 109, and the insulating layer 110. The semiconductor device 30 can be regarded as one transistor, in which the transistor 100_1 to the transistor 100_r are connected in series.

Although the transistor 100_1 to the transistor 100_r are shown as n-channel transistors in FIG. 45A, one embodiment of the present invention is not limited thereto. The transistor 100_1 to the transistor 100_r may be p-channel transistors.

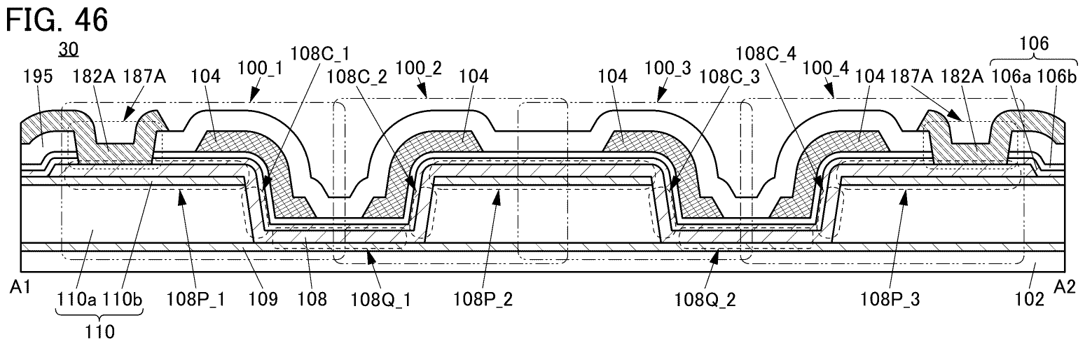

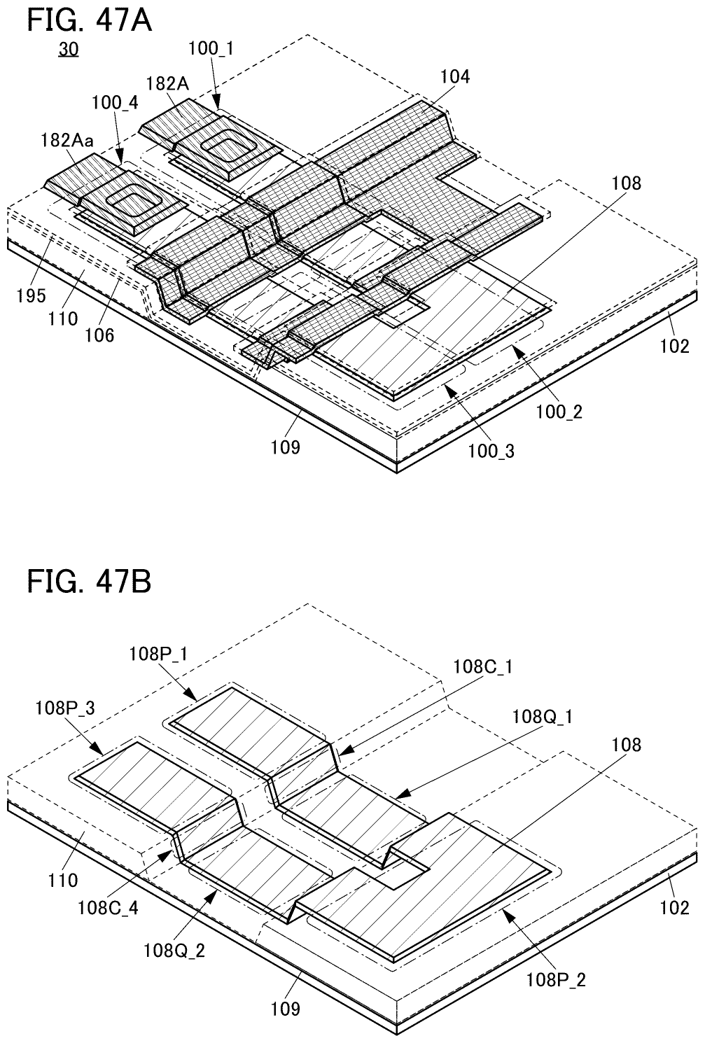

The case where r is 4 is specifically described as an example. FIG. 45B is an equivalent circuit diagram of the semiconductor device 30 of one embodiment of the present invention. FIG. 45C is a top view of the semiconductor device 30. FIG. 46 is a cross-sectional view of a cross section along the dashed-dotted line C1-C2 in FIG. 45C. FIG. 47 is a perspective view of the semiconductor device 30.

The semiconductor device 30 includes a transistor 100_1, a transistor 100_2, a transistor 100_3, a transistor 100_4, the insulating layer 109, and the insulating layer 110. The transistor 100_1 to the transistor 100_4 can each employ the above-described structure of the transistor 100. Although the transistor 100 is described as an example here, one embodiment of the present invention is not limited thereto. As the transistor 100_1 to the transistor 100_4, any of the transistor 100 to the transistor 100H can be used.

Although FIG. 45C and the like illustrate a structure in which the transistor 100_1 to the transistor 100_4 are arranged in two rows and two columns, there is no limitation on the transistor arrangement. For example, the transistor 100_1 to the transistor 100_4 may be arranged in one row and four columns.

The transistor 100_1 to the transistor 100_4 each include the conductive layer 104, the insulating layer 106, and the layer 108. In other words, the conductive layer 104, the insulating layer 106, and the layer 108 are shared by the transistor 100_1 to the transistor 100_4.

The layer 108 includes a region 108P_1, a region 108P_2, and a region 108P_3, which are in contact with the insulating layer 110b, a region 108Q_1 and a region 108Q_2, which are in contact with the insulating layer 109, and a region 108C_1, a region 108C_2, a region 108C_3, and a region 108C_4, which are in contact with the insulating layer 110a. A portion where the region 108P_1 is in contact with the insulating layer 110b, a portion where the region 108P_2 is in contact with the insulating layer 110b, and a portion where the region 108P_3 is in contact with the insulating layer 110b are different from each other. A portion where the region 108Q_1 is in contact with the insulating layer 109 and a portion where the region 108Q_2 is in contact with the insulating layer 109 are different from each other. A portion where the region 108C_1 is in contact with the insulating layer 110a, a portion where the region 108C_2 is in contact with the insulating layer 110a, a portion where the region 108C_3 is in contact with the insulating layer 110a, and a portion where the region 108C_4 is in contact with the insulating layer 110a are different from each other.

The region 108P_1 included in the layer 108 functions as one of a source electrode and a drain electrode of the transistor 100_1, and the region 108Q_1 included in the layer 108 functions as the other.

The region 108P_2 included in the layer 108 functions as one of a source electrode and a drain electrode of the transistor 100_2, and the region 108Q_1 functions as the other. The region 108Q_1 is shared by the transistor 100_1 and the transistor 100_2. The region 108Q_1 functions as the other of the source electrode and the drain electrode of the transistor 100_2 and also functions as the other of the source electrode and the drain electrode of the transistor 100_1. That is, the other of the source electrode and the drain electrode of the transistor 100_2 is electrically connected to the other of the source electrode and the drain electrode of the transistor 100_1.

The region 108P_2 included in the layer 108 functions as one of a source electrode and a drain electrode of the transistor 100_3, and the region 108Q_2 functions as the other. The region 108Q_2 is shared by the transistor 100_2 and the transistor 100_3. The region 108P_2 functions as one of the source electrode and the drain electrode of the transistor 100_3 and also functions as one of the source electrode and the drain electrode of the transistor 100_2. That is, one of the source electrode and the drain electrode of the transistor 100_3 is electrically connected to one of the source electrode and the drain electrode of the transistor 100_2.

The region 108P_3 included in the layer 108 functions as one of a source electrode and a drain electrode of the transistor 100_4, and the region 108Q_2 functions as the other. The region 108Q_2 is shared by the transistor 100_3 and the transistor 100_4. The region 108Q_2 functions as the other of the source electrode and the drain electrode of the transistor 100_4 and also functions as the other of the source electrode and the drain electrode of the transistor 100_3. That is, the other of the source electrode and the drain electrode of the transistor 100_4 is electrically connected to the other of the source electrode and the drain electrode of the transistor 100_3.

The insulating layer 106 is provided over the layer 108 and functions as a gate insulating layer of each of the transistor 100_1 to the transistor 100_4. The conductive layer 104 is provided over the insulating layer 106 and functions as a gate electrode of each of the transistor 100_1 to the transistor 100_4. The conductive layer 104 includes regions overlapping with the region 108C_1 to the region 108C_4 with the insulating layer 106 therebetween.

In the case where the semiconductor device 30 is regarded as one transistor, the channel length of the transistor is the sum of the channel lengths of the transistor 100_1 to the transistor 100_4. For example, in the case where the channel length L100 corresponds to the channel length of each of the transistor 100_1 to the transistor 100_4, the semiconductor device 30 can be regarded as a transistor having a channel length of “L100×4” (see FIG. 4B and FIG. 5B). The semiconductor device 30 composed of r transistors can be regarded as a transistor having a channel length of “L100×r”. Note that the semiconductor device 30 can be regarded as a transistor having the channel width W100 (see FIG. 4A, FIG. 5A, and FIG. 5B). A plurality of transistors connected in series enable a larger channel length and favorable saturation. By adjusting the number (r) of transistors connected in series, the channel length can be changed. The number (r) of transistors connected in series is determined so that desired saturation is obtained.

Note that the structure of the semiconductor device 30 described in Structure example 2-8 can also be applied to other structure examples. For example, the semiconductor device 30 may be used as one or more transistors included in the above-described semiconductor devices.

Although the structures of the semiconductor device including a plurality of transistors and the semiconductor device including a transistor and a capacitor are described here, one embodiment of the present invention is not limited thereto. The semiconductor device of one embodiment of the present invention can be suitably used for a display device. The display device of one embodiment of the present invention can have a structure in which the region 108P or the region 108Q included in the transistor is in contact with a pixel electrode included in the display element. A structure of the display device will be described in detail in Embodiment 3.

This embodiment can be combined with the other embodiments as appropriate. In this specification, in the case where a plurality of structure examples are shown in one embodiment, the structure examples can be combined as appropriate.

### Embodiment 2

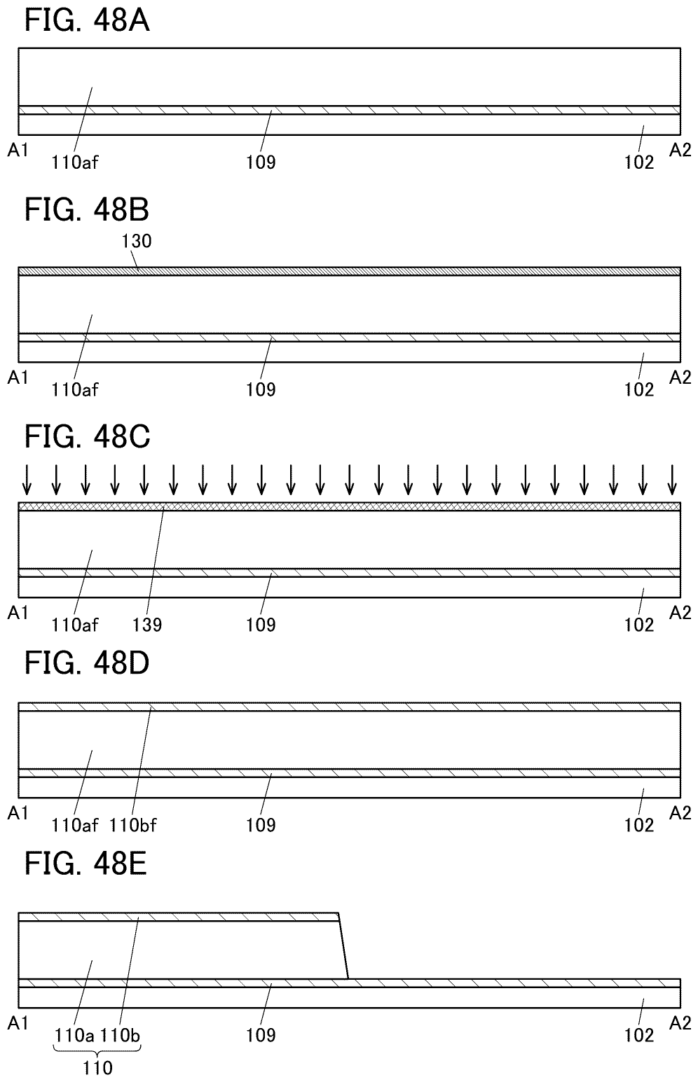

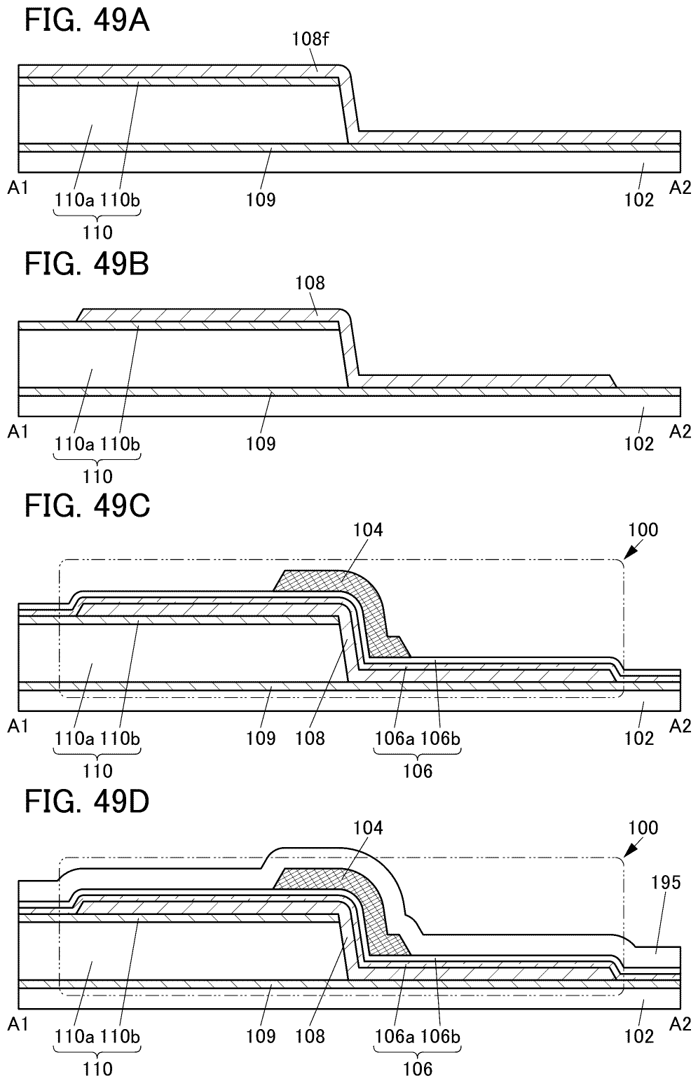

In this embodiment, a method for manufacturing a semiconductor device of one embodiment of the present invention will be described with reference to FIG. 48A to FIG. 49D. Note that as for a material and a formation method of each component, portions similar to the portions described in Embodiment 1 are not described in some cases.

FIG. 48A to FIG. 49D are cross-sectional views taken along the dashed-dotted line A1-A2 in FIG. 1A.

Thin films (e.g., insulating films, semiconductor films, and conductive films) included in the semiconductor device can be formed by a sputtering method, a chemical vapor deposition (CVD) method, a vacuum evaporation method, a pulsed laser deposition (PLD) method, an ALD method, a molecular beam epitaxy (MBE) method or the like. Examples of the CVD method include a PECVD method and a thermal CVD method. As an example of the thermal CVD method, a metal organic chemical vapor deposition (MOCVD: Metal Organic CVD) method is given.

The thin films included in the semiconductor device (e.g., insulating films, semiconductor films, and conductive films) can be formed by a wet film formation method such as spin coating, dipping, spray coating, inkjetting, dispensing, screen printing, offset printing, a doctor knife method, slit coating, roll coating, curtain coating, or knife coating.

When the thin films included in the semiconductor device are processed, a photolithography method or the like can be used. Alternatively, the thin films may be processed by a nanoimprinting method, a sandblasting method, a lift-off method, or the like. Alternatively, island-shaped thin films may be directly formed by a film formation method using a shielding mask such as a metal mask.

There are the following two typical examples of a photolithography method. In one of the methods, a resist mask is formed over a thin film to be processed, the thin film is processed by etching or the like, and then the resist mask is removed. In the other method, after a photosensitive thin film is formed, light exposure and development are performed, so that the thin film is processed into a desired shape.

As light for light exposure in a photolithography method, it is possible to use the i-line (wavelength: 365 nm), the g-line (wavelength: 436 nm), the h-line (wavelength: 405 nm), or light in which the i-line, the g-line, and the h-line are mixed. Alternatively, ultraviolet light, KrF laser light, ArF laser light, or the like can be used. The light exposure may be performed by liquid immersion exposure technique. As the light used for the light exposure, extreme ultraviolet (EUV) light or X-rays may be used. Instead of the light used for the light exposure, an electron beam can be used. Extreme ultraviolet light, X-rays, or an electron beam is preferably used, in which case extremely minute processing can be performed. Note that a photomask is not needed when the light exposure is performed by scanning with a beam such as an electron beam.

For etching of thin films, one or more of a dry etching method, a wet etching method, and a sandblast method can be used.

First, the insulating layer 109 is formed over the substrate 102, and an insulating film 110af to be the insulating layer 110a is formed over the insulating layer 109 (FIG. 48A).

A sputtering method or a PECVD method can be suitably used for the formation of the insulating layer 109 and the insulating film 110af. The insulating film 110af is preferably formed successively in a vacuum without exposure of the surface of the insulating layer 109 to the air after the formation of the insulating layer 109. The insulating layer 109 and the insulating film 110af are successively formed, whereby impurities derived from the air can be inhibited from being attached to the surface of the insulating layer 109. Examples of the impurities include water and organic substances.

The substrate temperature at the time of forming the insulating layer 109 and the insulating film 110af is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. When the substrate temperature at the time of the formation is in the above range, the amount of impurities (e.g., water and hydrogen) released from the insulating layer 109 and the insulating film 110af can be reduced. In particular, impurities from the insulating layer 110a can be inhibited from diffusing into the region 108C. Thus, the transistor can have favorable electrical characteristics and high reliability.

Note that since the insulating layer 109 and the insulating film 110af are formed earlier than the layer 108, there is no need to consider the probability of oxygen release from the layer 108 due to heat applied thereto at the time of forming the insulating layer 109 and the insulating film 110af.

After the insulating film 110af is formed, oxygen may be supplied to the insulating film 110af. As a method for supplying oxygen, an ion implantation method, an ion doping method, a plasma immersion ion implantation method, or plasma treatment can be used, for example. For the plasma treatment, an apparatus in which an oxygen gas is brought into a plasma state by high-frequency power can be suitably used. Examples of the apparatus in which a gas is brought into a plasma state by high-frequency power include a PECVD apparatus, a plasma etching apparatus, and a plasma ashing apparatus. The plasma treatment is preferably performed in an atmosphere containing oxygen. For example, the plasma treatment is preferably performed in an atmosphere containing one or more of oxygen, dinitrogen monoxide (N₂O), nitrogen dioxide (NO₂), carbon monoxide, and carbon dioxide.

Note that the plasma treatment may be successively performed in a vacuum without exposure of the surface of the insulating film 110af to the air. For example, in the case where a PECVD apparatus is used to form the insulating film 110af, the plasma treatment is preferably performed with the PECVD apparatus. Accordingly, the productivity can be increased. Specifically, after the insulating film 110af is formed with the PECVD apparatus, N₂O plasma treatment can be successively performed in a vacuum.

Next, the metal oxide layer 130 is preferably formed over the insulating film 110af (FIG. 48B). The formation of the metal oxide layer 130 enables oxygen supply to the insulating film 110af.

There is no limitation on the conductivity of the metal oxide layer 130. As the metal oxide layer 130, at least one of an insulating film, a semiconductor film, and a conductive film can be used. For the metal oxide layer 130, aluminum oxide, hafnium oxide, hafnium aluminate, indium oxide, indium tin oxide (ITO), or indium tin oxide containing silicon (ITSO) can be used, for example.

For the metal oxide layer 130, an oxide material containing one or more elements that are the same as those of the layer 108 is preferably used. It is particularly preferable to use a metal oxide material that can be used for the layer 108.

At the time of forming the metal oxide layer 130, the amount of oxygen supplied into the insulating film 110af can be increased with a higher oxygen flow rate ratio of the film formation gas introduced into a processing chamber of a film formation apparatus or with a higher oxygen partial pressure in the processing chamber. The oxygen flow rate ratio or oxygen partial pressure is, for example, set to higher than or equal to 50% and lower than or equal to 100%, preferably higher than or equal to 65% and lower than or equal to 100%, further preferably higher than or equal to 80% and lower than or equal to 100%, still further preferably higher than or equal to 90% and lower than or equal to 100%. It is particularly preferable that the oxygen flow rate ratio be 100% and the oxygen partial pressure be as close to 100% as possible.

When the metal oxide layer 130 is formed by a sputtering method in an atmosphere containing oxygen in the above manner, oxygen can be supplied to the insulating film 110af and release of oxygen from the insulating film 110af can be prevented at the time of the formation of the metal oxide layer 130. As a result, a large amount of oxygen can be enclosed in the insulating film 110af. Then, a large amount of oxygen can be supplied to the region 108C of the layer 108 by heat treatment performed later. As a result, oxygen vacancies and V_{O}H in the region 108C can be reduced, so that a highly reliable transistor exhibiting favorable electrical characteristics can be obtained.

After the metal oxide layer 130 is formed, heat treatment may be performed. By performing the heat treatment after the metal oxide layer 130 is formed, oxygen can be effectively supplied from the metal oxide layer 130 to the insulating film 110af.

The heat treatment temperature is preferably higher than or equal to 150° C. and lower than the strain point of the substrate, further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. The heat treatment can be performed in an atmosphere containing one or more of a noble gas, nitrogen, and oxygen. As an atmosphere containing nitrogen or an atmosphere containing oxygen, clean dry air (CDA) may be used. Note that the content of hydrogen, water, or the like in the atmosphere is preferably as low as possible. As the atmosphere, a high-purity gas with a dew point of −60° C. or lower, preferably −100° C. or lower is preferably used. With the use of an atmosphere where the content of hydrogen, water, or the like is as low as possible, entry of hydrogen, water, or the like into the insulating layer 109 and the insulating film 110af can be prevented as much as possible. An oven, a rapid thermal annealing (RTA) apparatus, or the like can be used for the heat treatment. The use of the RTA apparatus can shorten the heat treatment time.

After the formation of the metal oxide layer 130 or after the above-described heat treatment, oxygen may be further supplied to the insulating film 110af through the metal oxide layer 130. As a method for supplying oxygen, an ion implantation method, an ion doping method, a plasma immersion ion implantation method, or plasma treatment can be used, for example. The above description can be referred to for the plasma treatment; thus, the detailed description thereof is omitted.

Then, the metal oxide layer 130 is removed. There is no particular limitation on a method for removing the metal oxide layer 130, and a wet etching method can be suitably used. With use of a wet etching method, the insulating film 110af can be inhibited from being etched during the removal of the metal oxide layer 130. This can inhibit a reduction in the thickness of the insulating film 110af and the thickness of the insulating layer 110a can be uniform.

After the metal oxide layer 130 is removed, oxygen may be further supplied to the insulating film 110af. The above description can be referred to for a method for supplying oxygen. For example, as illustrated in FIG. 48C, a film 139 may be formed over the insulating film 110af, and treatment supplying oxygen to the insulating film 110af may be performed through the film 139. As the treatment, plasma treatment in an atmosphere containing oxygen can be performed. FIG. 48C schematically illustrates a state where oxygen is supplied to the insulating film 110af, which is indicated by arrows.

As the film 139, a conductive film or a semiconductor film is preferably used. As the film 139, a metal oxide film, a metal film, or an alloy film can be used. When the film 139 is formed using a metal oxide in an atmosphere containing oxygen by a sputtering method or the like, oxygen can be supplied to the insulating film 110af also at the time of forming the film 139, which is preferable.

The thickness of the film 139 is preferably small, and is preferably greater than or equal to 1 nm and less than or equal to 20 nm, further preferably greater than or equal to 2 nm and less than or equal to 20 nm, still further preferably greater than or equal to 2 nm and less than or equal to 15 nm, yet still further preferably greater than or equal to 3 nm and less than or equal to 15 nm, yet still further preferably greater than or equal to 3 nm and less than or equal to 10 nm, and can be typically approximately 5 nm.

The substrate temperature at the time of forming the film 139 is preferably lower than or equal to 350° C., further preferably lower than or equal to 340° C., still further preferably lower than or equal to 330° C., yet still further preferably lower than or equal to 300° C. Thus, a large amount of oxygen can be supplied to the insulating film 110af.

With the film 139, when a bias voltage is applied between the pair of electrodes in oxygen supply, ionized oxygen is easily drawn. Accordingly, a large amount of oxygen can be supplied to the insulating film 110af.

As a treatment apparatus used for oxygen supply, a dry etching apparatus, an ashing apparatus, or a PECVD apparatus can be suitably used. In particular, an ashing apparatus is preferably used. When a bias voltage is applied between a pair of electrodes included in the treatment apparatus, the bias voltage is set to higher than or equal to 10 V and lower than or equal to 1 kV, for example. Alternatively, the power density of the bias is set to higher than or equal to 1 W/cm² and lower than or equal to 5 W/cm², for example.

Next, the film 139 is removed. There is no particular limitation on a method for removing the film 139, and a wet etching method can be suitably used.

The treatment of supplying oxygen to the insulating film 110af is not limited to the above-described method. An oxygen radical, an oxygen atom, an oxygen atomic ion, or an oxygen molecular ion is supplied to the insulating film 110af by an ion doping method, an ion implantation method, or plasma treatment, for example. Alternatively, a film that inhibits oxygen release may be formed over the insulating film 110af, and then oxygen may be supplied to the insulating film 110af through the film. It is preferable to remove the film after supply of oxygen. As the above film that inhibits oxygen release, a conductive film or a semiconductor film containing one or more of indium, zinc, gallium, tin, aluminum, chromium, tantalum, titanium, molybdenum, nickel, iron, cobalt, and tungsten can be used.

Next, an insulating film 110bf to be the insulating layer 110b is formed over the insulating film 110af (FIG. 48D). For the formation of the insulating film 110bf, the description of the formation of the insulating layer 109 and the insulating film 110af can be referred to; thus, the detailed description thereof is omitted.

Next, the insulating film 110af and the insulating film 110bf are partly removed to form the insulating layer 110 (FIG. 48E). By the formation of the insulating layer 110, the top surface of part of the insulating layer 109 is exposed. For the formation of the insulating layer 110, a dry etching method can be suitably used. At this time, a region of the insulating layer 109 that does not overlap with the insulating layer 110 may be partly removed to be thinned (see FIG. 7A and FIG. 7B).

Next, a metal oxide film 108f to be the layer 108 is formed over the insulating layer 110 and the insulating layer 109 (FIG. 49A). At this time, the metal oxide film 108f is provided along the step due to the region where the insulating layer 110 is provided and the region where the insulating layer 110 is not provided. The metal oxide film 108f is provided to be in contact with the top surface and the side surface of the insulating layer 110 and the top surface of the insulating layer 109.

The metal oxide film 108f is preferably formed by a sputtering method using a metal oxide target. Alternatively, the metal oxide film 108f is preferably formed by an ALD method. An ALD method offers high coverage and thus can be suitably used to form the metal oxide film 108f provided along the side surface of the insulating layer 110. With use of an ALD method, a metal oxide film can be formed also on the side surface of the insulating layer 110 with high coverage. In an ALD method, the film formation rate can be easily controlled, so that a thin film can be formed with high yield.

The metal oxide film 108f is preferably a dense film with as few defects as possible. The metal oxide film 108f is preferably a highly purified film in which impurities containing hydrogen elements are reduced as much as possible. It is particularly preferable to use a metal oxide film having crystallinity as the metal oxide film 108f.

In forming the metal oxide film 108f, an oxygen gas is preferably used. With use of an oxygen gas, oxygen can be suitably supplied into the insulating layer 110. For example, in the case where an oxide or an oxynitride is used for the insulating layer 110a, oxygen can be favorably supplied to the insulating layer 110a.

By the supply of oxygen to the insulating layer 110a, oxygen is supplied to the channel formation region in the layer 108 in a later step, so that oxygen vacancies and V_{O}H in the channel formation region can be reduced.

In forming the metal oxide film 108f, an oxygen gas and an inert gas (e.g., a helium gas, an argon gas, or a xenon gas) may be mixed. As the oxygen flow rate ratio of the film formation gas or the oxygen partial pressure is higher in forming the metal oxide film, the metal oxide film can have higher crystallinity, and a transistor with higher reliability can be obtained. On the other hand, as the oxygen flow rate ratio or the oxygen partial pressure is lower, the metal oxide film can have lower crystallinity and higher electrical conductivity, and a transistor with a higher on-state current can be obtained.

Here, when the oxygen flow rate ratio or the oxygen partial pressure is high, the metal oxide film may have a polycrystalline structure. In the case where the metal oxide film has a polycrystalline structure, the crystal grain boundary becomes a recombination center and captures carriers and thus decreases the on-state current of the transistor, in some cases. Therefore, the oxygen flow rate ratio or the oxygen partial pressure is preferably adjusted so that the metal oxide film 108f does not have a polycrystalline structure. Since the ease of forming a polycrystalline structure depends on the composition of the metal oxide film, the oxygen flow rate ratio or the oxygen partial pressure is adjusted in accordance with the composition of the metal oxide film 108f.

As the substrate temperature in forming the metal oxide film is higher, a denser metal oxide film having higher crystallinity can be formed. On the other hand, as the substrate temperature is lower, a metal oxide film having lower crystallinity and higher electrical conductivity can be formed.

The substrate temperature at the time of forming the metal oxide film 108f is preferably higher than or equal to room temperature and lower than or equal to 250° C., further preferably higher than or equal to room temperature and lower than or equal to 200° C., still further preferably higher than or equal to room temperature and lower than or equal to 140° C. For example, when the substrate temperature is higher than or equal to room temperature and lower than or equal to 140° C., high productivity is achieved, which is preferable. Furthermore, when the metal oxide film 108f is formed with the substrate temperature set at room temperature or without heating the substrate, the crystallinity can be made low.

When the substrate temperature is high, the metal oxide film may have a polycrystalline structure. The substrate temperature is preferably adjusted so that the metal oxide film 108f does not have a polycrystalline structure. The substrate temperature is adjusted in accordance with the composition applied to the metal oxide film 108f.

In the case of using an ALD method, a film formation method such as a thermal ALD method or PEALD (Plasma Enhanced ALD) is preferably used. The thermal ALD method is preferable because of its capability of offering extremely high coverage. The PEALD method is preferable because of its capability of forming a film at low temperatures, in addition to its capability of offering high coverage.

For example, the metal oxide film can be formed by an ALD method using a precursor containing a constituent metal element and an oxidizer.

For example, in the case where In—Ga—Zn oxide is formed, three precursors of a precursor containing indium, a precursor containing gallium, and a precursor containing zinc can be used. Alternatively, two precursors of a precursor containing indium and a precursor containing gallium and zinc may be used.

Examples of the precursor containing indium include triethylindium, tris(2,2,6,6-tetramethyl-3,5-heptanedionato) indium, cyclopentadienylindium, indium (III) chloride, and (3-(dimethylamino) propyl)dimethylindium.

Examples of the precursor containing gallium include trimethylgallium, triethylgallium, gallium trichloride, tris(dimethylamido) gallium (III), gallium (III) acetylacetonate, tris(2,2,6,6-tetramethyl-3,5-heptanedionato) gallium, dimethylchlorogallium, and diethylchlorogallium.

Examples of the precursor containing zinc include dimethylzinc, diethylzinc, bis(2,2,6,6-tetramethyl-3,5-heptanedionato) zinc, and zinc chloride.

Examples of the oxidizer include ozone, oxygen, and water.

As a method for controlling the composition of a film to be obtained, adjusting one or more of the kinds of source gases, the flow rate ratio of source gases, the flowing time of the source gases, and the order in which the source gases flow is given. By adjusting these, the composition of the metal oxide film 108f can be controlled. Moreover, by adjusting these, a film whose composition is continuously changed can be formed. The composition of the metal oxide film 108f may be continuously changed.

It is preferable to perform at least one of treatment for desorbing water, hydrogen, an organic substance, and the like adsorbed onto the surface of the insulating layer 110 and treatment for supplying oxygen into the insulating layer 110 before the formation of the metal oxide film 108f. For example, heat treatment can be performed at a temperature higher than or equal to 70° C. and lower than or equal to 200° C. in a reduced-pressure atmosphere. Alternatively, plasma treatment may be performed in an atmosphere containing oxygen. Alternatively, oxygen may be supplied to the insulating layer 110 by plasma treatment in an atmosphere containing an oxidizing gas such as dinitrogen monoxide (N₂O). Performing plasma treatment including a dinitrogen monoxide gas can supply oxygen while suitably removing an organic substance on the surface of the insulating layer 110. It is preferable that the metal oxide film 108f be formed successively after such treatment, without exposure of the surface of the insulating layer 110 to the air.

Note that in the case where the layer 108 has a stacked-layer structure, an upper metal oxide film is preferably formed successively after the formation of a lower metal oxide film without exposure of a surface of the lower metal oxide film to the air.

In the case where the layer 108 has a stacked-layer structure, all the layers included in the layer 108 may be formed by the same film formation method (e.g., a sputtering method or an ALD method), or a film formation method to be used may be different between the layers. For example, the first metal oxide layer may be formed by a sputtering method, and the second metal oxide layer may be formed by an ALD method.

Next, the metal oxide film 108f is processed into an island shape to form the layer 108 (FIG. 49B). The layer 108 is provided across the region where the insulating layer 110 is provided and the region where the insulating layer 110 is not provided, and the layer 108 is in contact with the top surface and the side surface of the insulating layer 110 and the top surface of the insulating layer 109.

For the formation of the layer 108, a wet etching method can be suitably used. In this case, parts of the insulating layers 110 and 109 that overlap with the layer 108 may be etched and thinned. Note that a material having high selectivity is preferably used for the insulating layers 110b and 109 in etching of the metal oxide film 108f, in which case reductions in the thicknesses of the insulating layers 110b and 109 can be inhibited.

It is preferable that heat treatment be performed after the metal oxide film 108f is formed or the metal oxide film 108f is processed into the layer 108. By the heat treatment, hydrogen or water included in the metal oxide film 108f or the layer 108 or adsorbed on a surface thereof can be removed. Furthermore, the film quality of the metal oxide film 108f or the layer 108 is improved (e.g., defects are reduced or crystallinity is increased) by the heat treatment in some cases.

Impurities can be supplied from the insulating layer 110b to the metal oxide film 108f or the region of the layer 108 that is in contact with the insulating layer 110b by the heat treatment. Accordingly, the region 108P is formed. Similarly, impurities can be supplied from the insulating layer 109 to the metal oxide film 108f or the region of the layer 108 that is in contact with the insulating layer 109. Accordingly, the region 108Q is formed. In addition, oxygen can be supplied from the insulating layer 110a to the metal oxide film 108f or the layer 108 by the heat treatment. Thus, oxygen vacancies (V_{O}) in the region 108C functioning as the channel formation region can be reduced. In this case, it is further preferable that the heat treatment be performed before processing into the layer 108. The above description can be referred to for the heat treatment; thus, the detailed description thereof is omitted. Note that supply of impurities to the region 108P and the region 108Q and supply of oxygen to the region 108C functioning as the channel formation region may be performed not only through the heat treatment but also in a heat application step in and after the formation of the metal oxide film 108f (e.g., the step of forming the insulating layer 106).

Note that the heat treatment is not necessarily performed. The heat treatment in this step may be omitted, and heat treatment performed in a later step may also function as the heat treatment in this step. In some cases, heat application treatment in a later step (e.g., a film formation step) or the like can serve as the heat treatment in this step.

Then, the insulating layer 106 is formed to cover the layer 108 and the insulating layer 110. For the formation of the insulating layer 106, for example, a PECVD method, s sputtering method, or an ALD method can be suitably used.

In the case where the insulating layer 106 has a stacked-layer structure, these layers are further preferably formed successively in a vacuum. For example, in the case where the insulating layer 106 has a stacked-layer structure of the insulating layer 106a and the insulating layer 106b over the insulating layer 106a, the insulating layer 106b is preferably formed successively in a vacuum without exposure of the surface of the insulating layer 106a to the air after the formation of the insulating layer 106a. The insulating layer 106a and the insulating layer 106b are successively formed in a vacuum, whereby impurities derived from the air can be inhibited from being attached to the surface of the insulating layer 106a. Examples of the impurities include water and organic substances.

By increasing the temperature at the time of forming the insulating layer 106 functioning as the gate insulating layer, the insulating layer including few defects can be obtained. However, the high temperature at the time of forming the insulating layer 106 sometimes allows release of oxygen from the layer 108, which increases oxygen vacancies and V_{O}H in the layer 108 in some cases. The substrate temperature at the time of forming the insulating layer 106 is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C. When the substrate temperature at the time of forming the insulating layer 106 is in the above range, release of oxygen from the layer 108 can be inhibited while the defects in the insulating layer 106 can be reduced. Consequently, the transistor can have favorable electrical characteristics and high reliability.

Before the formation of the insulating layer 106, the surface of the layer 108 may be subjected to plasma treatment. By the plasma treatment, an impurity adsorbed onto the surface of the layer 108, such as water, can be reduced. Thus, impurities at the interface between the layer 108 and the insulating layer 106 can be reduced, achieving a highly reliable transistor. The plasma treatment is particularly suitable in the case where the surface of the layer 108 is exposed to the air after the formation of the layer 108 and before the formation of the insulating layer 106. For example, the plasma treatment can be performed in an atmosphere containing oxygen, ozone, nitrogen, dinitrogen monoxide, argon, or the like. The plasma treatment and the formation of the insulating layer 106 are preferably performed successively without exposure to the air.

Then, film to be the conductive layer 104 is formed over the insulating layer 106 and the film is processed, so that the conductive layer 104 is formed (FIG. 49C). For the formation of the film, a sputtering method, a thermal CVD method (including an MOCVD method), or an ALD method can be suitably used, for example.

Through the above steps, the transistor 100 can be manufactured.

Subsequently, the insulating layer 195 is formed to cover the conductive layer 104 and the insulating layer 106 (FIG. 49D). For the formation of the insulating layer 195, a PECVD method can be suitably used.

Heat treatment may be performed after the formation of the insulating layer 195.

Next, the insulating layer 106 and the insulating layer 195 are partly removed to form the opening 187A reaching the region 108P and the opening 187B reaching the region 108Q.

Next, a film to be the conductive layer 182A and the conductive layer 182B is formed to cover the opening 187A and the opening 187B and the film is processed, whereby the conductive layer 182A and the conductive layer 182B functioning as wirings are formed (FIG. 1B).

Through the above steps, the semiconductor device of one embodiment of the present invention can be manufactured.

This embodiment can be combined with the other embodiments as appropriate.

### Embodiment 3

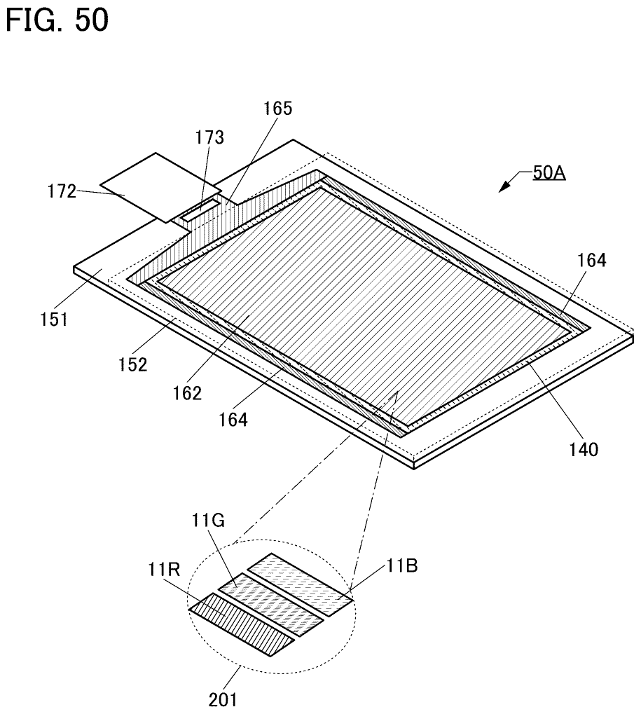

In this embodiment, display devices of one embodiment of the present invention will be described with reference to FIG. 50 to FIG. 60.

The display device of this embodiment can be a high-resolution display device or a large-sized display device. Accordingly, for example, the display device of this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or laptop computer, a monitor of a computer or the like, digital signage, and a large game machine such as a pachinko machine.

The display device of this embodiment can be a high-definition display device. Accordingly, the display device of this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The semiconductor device of one embodiment of the present invention can be used for a display device or a module including the display device. Examples of the module including the display device are a module in which a connector such as a flexible printed circuit board (hereinafter referred to as an FPC) or a TCP (Tape Carrier Package) is attached to the display device and a module in which the display device is mounted with an integrated circuit (IC) by a COG (Chip On Glass) method, a COF (Chip On Film) method, or the like.

The display device of this embodiment may have a function of a touch panel. The display device can employ any of a variety of sensor elements that can sense proximity or touch of a sensing target such as a finger, for example.

Examples of the sensor type include a capacitive type, a resistive type, a surface acoustic wave type, an infrared type, an optical type, and a pressure-sensitive type.

Examples of the capacitive type include a surface capacitive type and a projected capacitive type. Examples of the projected capacitive type include a self-capacitive type and a mutual capacitive type. The use of the mutual capacitive type is preferable because multiple points can be sensed simultaneously.

Examples of a touch panel include an out-cell type, an on-cell type, and an in-cell type. Note that an in-cell touch panel has a structure in which an electrode included in a sensor element is provided on one or both of a substrate supporting a display element and a counter substrate.

### [Display Device 50A]

FIG. 50 shows a perspective view of a display device 50A.

The display device 50A has a structure in which a substrate 152 and a substrate 151 are attached to each other. In FIG. 50, the substrate 152 is indicated by a dashed line.

The display device 50A includes a display portion 162, a connection portion 140, a circuit portion 164, a conductive layer 165, and the like. FIG. 50 shows an example in which an IC 173 and an FPC 172 are mounted on the display device 50A. Thus, the structure illustrated in FIG. 50 can be regarded as a display module including the display device 50A, the IC, and the FPC.

The connection portion 140 is provided outside the display portion 162. The connection portion 140 can be provided along one or more sides of the display portion 162. The number of connection portions 140 may be one or more. FIG. 50 shows an example in which the connection portion 140 is provided to surround the four sides of the display portion. In the connection portion 140, a common electrode of a display element is electrically connected to a conductive layer so that a potential can be supplied to the common electrode.

The circuit portion 164 includes a scan line driver circuit (also referred to as a gate driver), for example. The circuit portion 164 may include both a scan line driver circuit and a signal line driver circuit (also referred to as a source driver).

The conductive layer 165 has a function of supplying a signal and electric power to the display portion 162 and the circuit portion 164. The signal and electric power are input to the conductive layer 165 from the outside through the FPC 172 or input to the conductive layer 165 from the IC 173.

FIG. 50 shows an example in which the IC 173 is provided on the substrate 151 by a COG method, a COF method, or the like. An IC including one or both of a scan line driver circuit and a signal line driver circuit can be used as the IC 173, for example. Note that the display device 50A and the display module may be configured not to include an IC. The IC may be mounted on the FPC by a COF method or the like.

The semiconductor device of one embodiment of the present invention includes a vertical transistor (VFET) having a submicron-sized channel length and a high on-state current. The semiconductor device of one embodiment of the present invention can be used for one or both of the display portion 162 and the circuit portion 164 of the display device 50A, for example. An oxide semiconductor (OS) can be suitably used for a channel formation region of a transistor included in the display device. By using an OS transistor, a display device can have low power consumption. The semiconductor device of one embodiment of the present invention can be used for both the display portion 162 and the circuit portion 164, that is, all the transistors included in the display device can be OS transistors. When all the transistors included in the display device are OS transistors in this manner, an effect of reducing the manufacturing cost can be obtained.

When the semiconductor device of one embodiment of the present invention is used for a pixel circuit of a display device, the area occupied by the pixel circuit can be reduced and a high-definition display device can be provided, for example. When the semiconductor device of one embodiment of the present invention is used for a driver circuit (e.g., one or both of a gate line driver circuit and a source line driver circuit) of a display device, the area occupied by the driver circuit can be reduced and the display device can have a narrow bezel. Since the semiconductor device of one embodiment of the present invention has favorable electrical characteristics, the display device can have increased reliability by using the semiconductor device.

The display portion 162 of the display device 50A is a region where an image is to be displayed, and includes a plurality of pixels 201 that are periodically arranged. An enlarged view of one pixel 201 is shown in FIG. 50.

There is no particular limitation on the arrangement of the pixels in the display device of this embodiment, and a variety of methods can be used. Examples of the arrangement of the pixels include stripe arrangement, S-stripe arrangement, matrix arrangement, delta arrangement, Bayer arrangement, and PenTile arrangement.

The pixel 201 illustrated in FIG. 50 includes a subpixel 11R that emits red light, a subpixel 11G that emits green light, and a subpixel 11B that emits blue light.

The subpixels 11R, 11G, and 11B each include a display element and a circuit for controlling the driving of the display element.

A variety of elements can be used as the display element, and a liquid crystal element or a light-emitting element can be used, for example. Alternatively, it is also possible to use, for example, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like. Alternatively, a QLED (Quantum-dot LED) employing a light source and color conversion technology using quantum dot materials may be used.

Examples of a display device using a liquid crystal element include a transmissive liquid crystal display device, a reflective liquid crystal display device, and a transflective liquid crystal display device.

Examples of a mode that can be employed for a display device including a liquid crystal element include a vertical alignment (VA) mode, an FFS (Fringe Field Switching) mode, an IPS (In-Plane-Switching) mode, a TN (Twisted Nematic) mode, an ASM (Axially Symmetric aligned Micro-cell) mode, an OCB (Optically Compensated Birefringence) mode, an FLC (Ferroelectric Liquid Crystal) mode, an AFLC (AntiFerroelectric Liquid Crystal) mode, an ECB (Electrically Controlled Birefringence) mode, and a guest-host mode. Examples of the VA mode include an MVA (Multi-Domain Vertical Alignment) mode, a PVA (Patterned Vertical Alignment) mode, and an ASV (Advanced Super View) mode.

Examples of a liquid crystal material that can be used for the liquid crystal element include a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, and an anti-ferroelectric liquid crystal. These liquid crystal materials exhibit a cholesteric phase, a smectic phase, a cubic phase, a chiral nematic phase, an isotropic phase, a blue phase, or the like depending on conditions. As the liquid crystal material, either a positive liquid crystal or a negative liquid crystal may be used, and the selection can be made in accordance with the mode or design that is used.

Examples of the light-emitting element include a self-luminous light-emitting element such as an LED (Light Emitting Diode), an OLED (Organic LED), and a semiconductor laser. As the LED, for example, a mini LED or a micro LED can be used.

Examples of a light-emitting substance contained in the light-emitting element include a substance that emits fluorescent light (a fluorescent material), a substance that emits phosphorescent light (a phosphorescent material), a substance that exhibits thermally activated delayed fluorescence (a thermally activated delayed fluorescence (TADF) material), and an inorganic compound (a quantum dot material or the like).

The emission color of the light-emitting element can be infrared, red, green, blue, cyan, magenta, yellow, white, or the like. When the light-emitting element has a microcavity structure, the color purity can be increased.

One electrode of a pair of electrodes included in the light-emitting element functions as an anode, and the other electrode functions as a cathode.

The display device of one embodiment of the present invention can have any of the following structures: a top-emission structure in which light is emitted in a direction opposite to the substrate where the light-emitting element is formed, a bottom-emission structure in which light is emitted to the substrate side where the light-emitting element is formed, and a dual-emission structure in which light is emitted to both surfaces.

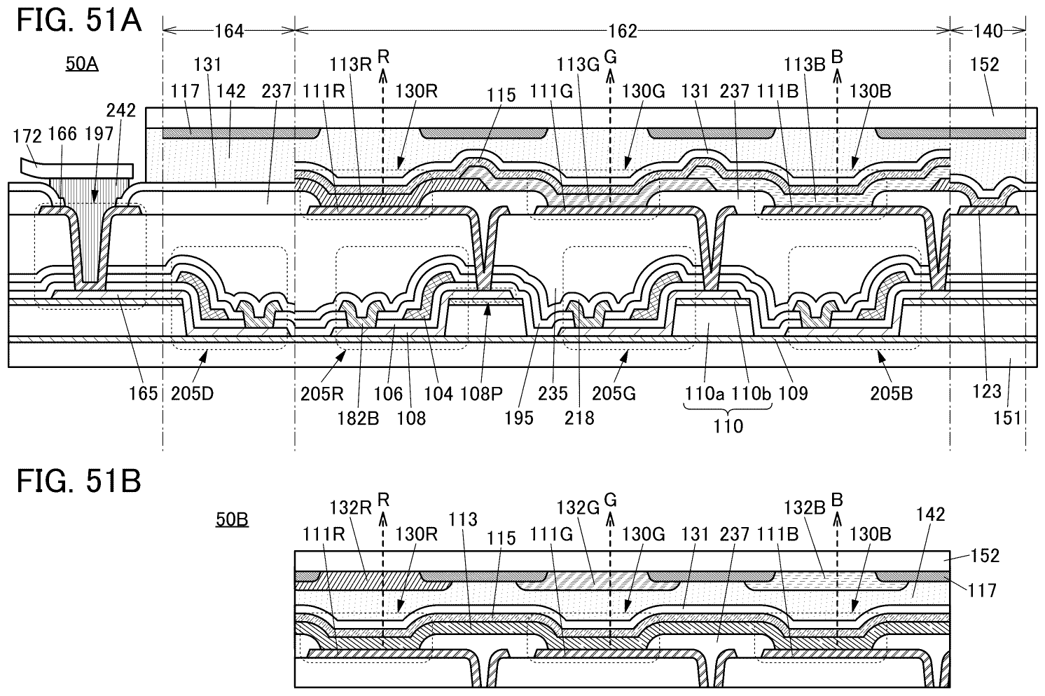

FIG. 51A shows an example of cross sections of part of a region including the FPC 172, part of the circuit portion 164, part of the display portion 162, part of the connection portion 140, and part of a region including an end portion of the display device 50A. Here, a plurality of layers obtained by processing the same conductive film are shown with the same hatching pattern.

The display device 50A illustrated in FIG. 51A includes transistors 205D, 205R, 205G, and 205B, a light-emitting element 130R, a light-emitting element 130G, a light-emitting element 130B, and the like between the substrate 151 and the substrate 152. The light-emitting element 130R is a display element included in the subpixel 11R that emits red light, the light-emitting element 130G is a display element included in the subpixel 11G that emits green light, and the light-emitting element 130B is a display element included in the subpixel 11B that emits blue light.

The display device 50A employs an SBS structure. The SBS structure can optimize materials and structures of light-emitting elements and thus can increase the degree of freedom in selecting materials and structures, so that the luminance and the reliability can be easily improved.

The display device 50A has a top-emission structure. The aperture ratio of pixels in a top-emission structure can be higher than that of pixels in a bottom-emission structure because a transistor and the like can be provided so as to overlap with a light-emitting region of a light-emitting element in the top-emission structure.

The transistors 205D, 205R, 205G, and 205B are each formed over the substrate 151. These transistors can be formed using the same material in the same step.

This embodiment describes an example in which OS transistors are used as the transistors 205D, 205R, 205G, and 205B. The transistor of one embodiment of the present invention can be used as the transistors 205D, 205R, 205G, and 205B. In other words, the display device 50A includes the transistor of one embodiment of the present invention in both the display portion 162 and the circuit portion 164. When the transistor of one embodiment of the present invention is used in the display portion 162, the pixel size can be reduced and high definition can be achieved. When the transistor of one embodiment of the present invention is used in the circuit portion 164, the area occupied by the circuit portion 164 can be reduced and a narrower bezel can be achieved. The description in the above embodiment can be referred to for the transistor of one embodiment of the present invention.

Specifically, the transistors 205D, 205R, 205G, and 205B each include the conductive layer 104 functioning as a gate, the insulating layer 106 functioning as a gate insulating layer, and the layer 108 containing a metal oxide. The layer 108 includes the region 108P (not illustrated) in a region in contact with the insulating layer 109, and the region 108P functions as one of a source and a drain. The layer 108 includes the region 108Q (not illustrated) in a region in contact with the insulating layer 110b, and the region 108Q functions as the other of the source and the drain.

Note that the transistor included in the display device of this embodiment is not limited to the transistor of one embodiment of the present invention. For example, the display device of this embodiment may include the transistor of one embodiment of the present invention and a transistor having another structure in combination.

The display device of this embodiment may include any one or more of a planar transistor, a staggered transistor, and an inverted staggered transistor. A transistor included in the display device of this embodiment may have either a top-gate structure or a bottom-gate structure. Alternatively, gates may be provided above and below the layer where a channel is formed.

A Si transistor may be included in the display device of this embodiment.

To increase the emission luminance of the light-emitting element included in the pixel circuit, the amount of current flowing through the light-emitting element needs to be increased. To increase the amount of current, the source-drain voltage of a driving transistor included in the pixel circuit needs to be increased. Since an OS transistor has a higher breakdown voltage between the source and the drain than a Si transistor, a high voltage can be applied between the source and the drain of the OS transistor. Accordingly, when an OS transistor is used as the driving transistor included in the pixel circuit, the amount of current flowing through the light-emitting element can be increased, so that the emission luminance of the light-emitting element can be increased.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, the amount of current flowing between the source and the drain can be set minutely by a change in gate-source voltage; hence, the amount of current flowing through the light-emitting element can be controlled. Accordingly, the number of gray levels in the pixel circuit can be increased.

Regarding saturation characteristics of current flowing when a transistor operates in a saturation region, even in the case where the source-drain voltage of an OS transistor increases gradually, more stable current (saturation current) can be made to flow through an OS transistor than through a Si transistor. Thus, by using an OS transistor as the driving transistor, a stable current can be made to flow through a light-emitting element even when the current-voltage characteristics of the light-emitting element vary, for example. In other words, when the OS transistor operates in the saturation region, the source-drain current hardly changes with a change in the source-drain voltage; hence, the emission luminance of the light-emitting element can be stable.

The transistors included in the circuit portion 164 and the transistors included in the display portion 162 may have the same structure or different structures. A plurality of transistors included in the circuit portion 164 may have the same structure or two or more kinds of structures. Similarly, a plurality of transistors included in the display portion 162 may have the same structure or two or more kinds of structures.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display device can have low power consumption and high drive capability. A structure in which an LTPS transistor and an OS transistor are used in combination is referred to as LTPO in some cases. As a more suitable example, a structure in which the OS transistor is used as a transistor or the like functioning as a switch for controlling conduction or non-conduction between wirings, and the LTPS transistor is used as a transistor or the like for controlling current, is given.

For example, one of the transistors included in the display portion 162 functions as a transistor for controlling a current flowing through the light-emitting element and can also be referred to as a driving transistor. One of a source and a drain of the driving transistor is electrically connected to a pixel electrode of the light-emitting element. An LTPS transistor is preferably used as the driving transistor. In that case, the amount of current flowing through the light-emitting element can be increased in the pixel circuit.

By contrast, another transistor included in the display portion 162 functions as a switch for controlling selection or non-selection of a pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., lower than or equal to 1 fps); thus, power consumption can be reduced by stopping the driver in displaying a still image.

An insulating layer 218 is provided to cover the transistors 205D, 205R, 205G, and 205B and an insulating layer 235 is provided over the insulating layer 218.

The insulating layer 218 preferably functions as a protective layer of the transistors. For the insulating layer 218, a material that does not easily allow diffusion of impurities such as water and hydrogen is preferably used. Accordingly, the insulating layer 218 can function as a barrier film. This structure can effectively inhibit diffusion of impurities into the transistors from the outside and improve the reliability of the display device.

The insulating layer 218 preferably includes one or more inorganic insulating films. Examples of a material that can be used for the inorganic insulating film include an oxide, a nitride, an oxynitride, and a nitride oxide. Specific examples of a material that can be used for the inorganic insulating film are as described above.

The insulating layer 235 preferably has a function of a planarization layer, and an organic insulating film is suitably used. Examples of a material that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 235 may have a stacked-layer structure of an organic insulating film and an inorganic insulating film. The outermost layer of the insulating layer 235 preferably functions as an etching protective layer. Accordingly, a depressed portion can be inhibited from being formed in the insulating layer 235 in processing pixel electrodes 111R, 111G, and 111B, for example. Alternatively, a depressed portion may be formed in the insulating layer 235 in processing the pixel electrodes 111R, 111G, and 111B, for example.

The light-emitting elements 130R, 130G, and 130B are provided over the insulating layer 235.

The light-emitting element 130R includes the pixel electrode 111R over the insulating layer 235, an EL layer 113R over the pixel electrode 111R, and a common electrode 115 over the EL layer 113R. The light-emitting element 130R illustrated in FIG. 51A emits red light (R). The EL layer 113R includes a light-emitting layer that emits red light.

The light-emitting element 130G includes the pixel electrode 111G over the insulating layer 235, an EL layer 113G over the pixel electrode 111G, and the common electrode 115 over the EL layer 113G. The light-emitting element 130G illustrated in FIG. 51A emits green light (G). The EL layer 113G includes a light-emitting layer that emits green light.

The light-emitting element 130B includes the pixel electrode 111B over the insulating layer 235, an EL layer 113B over the pixel electrode 111B, and the common electrode 115 over the EL layer 113B. The light-emitting element 130B illustrated in FIG. 51A emits blue light (B). The EL layer 113B includes a light-emitting layer that emits blue light.

Although the EL layers 113R, 113G, and 113B have the same thickness in FIG. 51A, the present invention is not limited thereto. The EL layers 113R, 113G, and 113B may have different thicknesses. For example, the thicknesses of the EL layers 113R, 113G, and 113B are preferably set in accordance with an optical path length that intensifies light emitted from each EL layer. Accordingly, a microcavity structure is achieved, and the color purity of light emitted from each light-emitting element can be improved.

The pixel electrode 111R is electrically connected to the region 108P included in the transistor 205R through an opening provided in the insulating layer 106, the insulating layer 195, the insulating layer 218, and the insulating layer 235. In a similar manner, the pixel electrode 111G is electrically connected to the region 108P included in the transistor 205G, and the pixel electrode 111B is electrically connected to the region 108P included in the transistor 205B.

End portions of the pixel electrodes 111R, 111G, and 111B are covered with an insulating layer 237. The insulating layer 237 functions as a partition wall. The insulating layer 237 can be provided to have a single-layer structure or a stacked-layer structure using one or both of an inorganic insulating material and an organic insulating material. A material that can be used for the insulating layer 218 and a material that can be used for the insulating layer 235 can be used for the insulating layer 237, for example. With the insulating layer 237, the pixel electrode and the common electrode can be electrically insulated from each other. Furthermore, with the insulating layer 237, adjacent light-emitting elements can be electrically insulated from each other.

The insulating layer 237 is provided in at least the display portion 162. The insulating layer 237 may be provided in not only the display portion 162 but also the connection portion 140 and the circuit portion 164. The insulating layer 237 may be provided to extend to the end portion of the display device 50A.

The common electrode 115 is a continuous film shared by the light-emitting elements 130R, 130G, and 130B. The common electrode 115 shared by the plurality of light-emitting elements is electrically connected to a conductive layer 123 provided in the connection portion 140. For the conductive layer 123, a conductive layer formed using the same material in the same step as the pixel electrodes 111R, 111G, and 111B is preferably used.

In the display device of one embodiment of the present invention, a conductive film transmitting visible light is used for the electrode through which light is extracted, which is either the pixel electrode or the common electrode. A conductive film reflecting visible light is preferably used for the electrode through which light is not extracted.

A conductive film transmitting visible light may be used also for the electrode through which light is not extracted. In that case, this electrode is preferably provided between a reflective layer and the EL layer. In other words, light emitted by the EL layer may be reflected by the reflective layer to be extracted from the display device.

As a material that forms the pair of electrodes of the light-emitting element, a metal, an alloy, a compound having electrical conductivity, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing appropriate combination of any of these metals. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element belonging to Group 1 or Group 2 of the periodic table that is not described above as an example (e.g., lithium, cesium, calcium, or strontium), a rare earth metal such as europium or ytterbium, an alloy containing an appropriate combination of any of these elements, and graphene.

The light-emitting element preferably employs a microcavity structure. Thus, one of the pair of electrodes of the light-emitting element is preferably an electrode having properties of transmitting and reflecting visible light (a transflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

A transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have an electrical resistivity lower than or equal to 1×10⁻² (2 cm.

The EL layers 113R, 113G, and 113B are each provided to have an island shape. In FIG. 51A, an end portion of the EL layer 113R and an end portion of the EL layer 113G that are adjacent to each other overlap with each other, an end portion of the EL layer 113G and an end portion of the EL layer 113B that are adjacent to each other overlap with each other, and an end portion of the EL layer 113R and an end portion of the EL layer 113B that are adjacent to each other overlap with each other. When island-shaped EL layers are formed using a fine metal mask, the end portions of the EL layers adjacent to each other may overlap with each other as illustrated in FIG. 51A; however, the present invention is not limited thereto. That is, it is also possible that the EL layers adjacent to each other do not overlap with each other and are apart from each other. Furthermore, both a portion where the EL layers adjacent to each other overlap with each other and a portion where the EL layers adjacent to each other do not overlap with each other and are apart from each other may exist in the display device.

Each of the EL layers 113R, 113G, and 113B includes at least a light-emitting layer. The light-emitting layer contains one or more kinds of light-emitting substances. As the light-emitting substance, a substance whose emission color is blue, violet, bluish violet, green, yellow green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

The light-emitting layer may contain one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the one or more kinds of organic compounds, a bipolar substance (a substance with a high electron-transport property and a high hole-transport property) or a TADF material may be used.

The light-emitting layer preferably contains a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In addition to the light-emitting layer, the EL layer can include one or more of a layer containing a substance having a high hole-injection property (a hole-injection layer), a layer containing a hole-transport material (a hole-transport layer), a layer containing a substance having a high electron-blocking property (an electron-blocking layer), a layer containing a substance having a high electron-injection property (an electron-injection layer), a layer containing an electron-transport material (an electron-transport layer), and a layer containing a substance having a high hole-blocking property (a hole-blocking layer). The EL layer may further include one or both of a bipolar substance and a TADF material.

Either a low molecular compound or a high molecular compound can be used for the light-emitting element, and an inorganic compound may also be contained. Each of the layers included in the light-emitting element can be formed by an evaporation method (including a vacuum evaporation method), a transfer method, a printing method, an inkjet method, a coating method, or the like.

For the light-emitting element, a single structure (a structure including only one light-emitting unit) or a tandem structure (a structure including a plurality of light-emitting units) may be employed. The light-emitting unit includes at least one light-emitting layer. The tandem structure is a structure in which a plurality of light-emitting units are connected in series with a charge-generation layer therebetween. The charge-generation layer has a function of injecting electrons into one of the two light-emitting units and injecting holes into the other when voltage is applied between the pair of electrodes. The tandem structure enables a light-emitting element capable of high-luminance light emission. Furthermore, the tandem structure allows the amount of current needed for obtaining the same luminance to be reduced as compared to the case of using a single structure, and thus can improve the reliability. The tandem structure may be referred to as a stack structure.

In the case of using a light-emitting element having a tandem structure in FIG. 51A, the EL layer 113R preferably includes a plurality of light-emitting units emitting red light, the EL layer 113G preferably includes a plurality of light-emitting units emitting green light, and the EL layer 113B preferably includes a plurality of light-emitting units emitting blue light.

A protective layer 131 is provided over the light-emitting elements 130R, 130G, and 130B. The protective layer 131 and the substrate 152 are attached to each other with an adhesive layer 142 therebetween. The substrate 152 is provided with a light-blocking layer 117. For example, a solid sealing structure or a hollow sealing structure can be employed to seal the light-emitting elements. In FIG. 51A, a solid sealing structure is employed, in which a space between the substrate 152 and the substrate 151 is filled with the adhesive layer 142. Alternatively, a hollow sealing structure may be employed, in which the space is filled with an inert gas (e.g., nitrogen or argon). Here, the adhesive layer 142 may be provided not to overlap with the light-emitting element. The space may be filled with a resin different from that of the frame-like adhesive layer 142.

The protective layer 131 is provided at least in the display portion 162, and preferably provided to cover the entire display portion 162. The protective layer 131 is preferably provided to cover not only the display portion 162 but also the connection portion 140 and the circuit portion 164. It is also preferable that the protective layer 131 be provided to extend to the end portion of the display device 50A. Meanwhile, a connection portion 197 has a portion not provided with the protective layer 131 so that the FPC 172 and a conductive layer 166 are electrically connected to each other.

By providing the protective layer 131 over the light-emitting elements 130R, 130G, and 130B, the reliability of the light-emitting elements can be improved.

The protective layer 131 may have a single-layer structure or a stacked-layer structure of two or more layers. There is no limitation on the conductivity of the protective layer 131. As the protective layer 131, at least one type of insulating films, semiconductor films, and conductive films can be used.

The protective layer 131 including an inorganic film can inhibit deterioration of the light-emitting elements by preventing oxidation of the common electrode 115 and inhibiting entry of impurities (e.g., moisture and oxygen) into the light-emitting elements, for example; thus, the reliability of the display device can be improved.

As the protective layer 131, an inorganic insulating film containing one or more of an oxide, a nitride, an oxynitride, and a nitride oxide can be used, for example. Specific examples of a material that can be used for the inorganic insulating film are as described above. In particular, the protective layer 131 preferably contains a nitride or a nitride oxide, and further preferably contains a nitride.

An inorganic film containing ITO, In—Zn oxide, Ga—Zn oxide, Al—Zn oxide, IGZO, or the like can also be used as the protective layer 131. The inorganic film preferably has high resistance, specifically, higher resistance than the common electrode 115. The inorganic film may further contain nitrogen.

When light emitted from the light-emitting element is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can have, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) into the EL layer.

Furthermore, the protective layer 131 may include an organic film. For example, the protective layer 131 may include both an organic film and an inorganic film. Examples of an organic film that can be used for the protective layer 131 include organic insulating films that can be used for the insulating layer 235.

The connection portion 197 is provided in a region of the substrate 151 not overlapping with the substrate 152. In the connection portion 197, the conductive layer 165 is electrically connected to the FPC 172 through the conductive layer 166 and a connection layer 242. FIG. 51 shows an example in which the conductive layer 165 has the same structure as the region 108P included in the layer 108. For example, a film to be the layer 108 and the conductive layer 165 is formed, and the film is processed. In a region of the layer 108 that is in contact with the uppermost layer of the insulating layer 110 (here, the insulating layer 110b), the conductive layer 165 is formed together with the region 108P. An example in which the conductive layer 166 is a single conductive layer obtained by processing the same conductive film as the pixel electrodes 111R, 111G, and 111B is shown. On the top surface of the connection portion 197, the conductive layer 166 is exposed. Thus, the connection portion 197 and the FPC 172 can be electrically connected to each other through the connection layer 242.

The display device 50A has a top-emission structure. Light emitted from the light-emitting element is emitted to the substrate 152 side. For the substrate 152, a material having a high visible-light-transmitting property is preferably used. The pixel electrodes 111R, 111G, and 111B contain a material that reflects visible light, and the counter electrode (the common electrode 115) contains a material that transmits visible light.

The light-blocking layer 117 is preferably provided on the surface of the substrate 152 that faces the substrate 151. The light-blocking layer 117 can be provided between adjacent light-emitting elements, in the connection portion 140, and in the circuit portion 164, for example.

A coloring layer such as a color filter may be provided on the surface of the substrate 152 that faces the substrate 151 or over the protective layer 131. When the color filter is provided so as to overlap with the light-emitting element, the color purity of light emitted from the pixel can be increased.

The coloring layer is a colored layer that selectively transmits light in a specific wavelength range and absorbs light in the other wavelength ranges. For example, a red (R) color filter for transmitting light in the red wavelength range, a green (G) color filter for transmitting light in the green wavelength range, a blue (B) color filter for transmitting light in the blue wavelength range, or the like can be used. For each coloring layer, one or more of a metal material, a resin material, a pigment, and a dye can be used. Each coloring layer is formed in a desired position by a printing method, an inkjet method, an etching method using a photolithography method, or the like.

A variety of optical members can be provided on the outer side of the substrate 152 (the surface opposite to the substrate 151). Examples of the optical members include a polarizing plate, a retardation plate, a light diffusion layer (e.g., a diffusion film), an anti-reflective layer, and a light-condensing film. Furthermore, a surface protective layer such as an antistatic film inhibiting the attachment of dust, a water repellent film inhibiting the attachment of stain, a hard coat film inhibiting generation of a scratch caused by the use, or an impact-absorbing layer may be provided on the outer side of the substrate 152. For example, it is preferable to provide, as the surface protective layer, a glass layer or a silica layer (SiOₓ layer) because the surface contamination and generation of damage can be inhibited. For the surface protective layer, DLC (diamond-like carbon), aluminum oxide (AlOₓ), a polyester-based material, a polycarbonate-based material, or the like may be used. For the surface protective layer, a material having a high visible-light transmittance is preferably used. For the surface protective layer, a material with high hardness is preferably used.

For each of the substrate 151 and the substrate 152, glass, quartz, ceramics, sapphire, a resin, a metal, an alloy, a semiconductor, or the like can be used. For the substrate on the side from which light from the light-emitting element is extracted, a material that transmits the light is used. When a flexible material is used for each of the substrate 151 and the substrate 152, the flexibility of the display device can be increased and a flexible display can be achieved. Furthermore, a polarizing plate may be used as at least one of the substrate 151 and the substrate 152.

For each of the substrate 151 and the substrate 152, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example. Glass that is thin enough to have flexibility may be used as at least one of the substrate 151 and the substrate 152.

In the case where a circularly polarizing plate overlaps with the display device, a highly optically isotropic substrate is preferably used as the substrate included in the display device. A highly optically isotropic substrate has a low birefringence (i.e., a small amount of birefringence). Examples of a highly optically isotropic film include a triacetyl cellulose (TAC, also referred to as cellulose triacetate) film, a cycloolefin polymer (COP) film, a cycloolefin copolymer (COC) film, and an acrylic film.

As the adhesive layer 142, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-liquid-mixture-type resin may be used. An adhesive sheet or the like may be used.

As the connection layer 242, an anisotropic conductive film (ACF), an anisotropic conductive paste (ACP), or the like can be used.

### [Display Device 50B]

FIG. 51B shows an example of a cross section of the display portion 162 of a display device 50B. The display device 50B is different from the display device 50A mainly in that an EL layer 113 shared between the light-emitting elements and coloring layers (color filters or the like) are used for the subpixels of different colors. The structure illustrated in FIG. 51B can be combined with the structure of the region including the FPC 172, the circuit portion 164, the stacked-layer structure from the substrate 151 to the insulating layer 235 in the display portion 162, the connection portion 140, and an end portion, which is illustrated in FIG. 51A. As for the description of the display device below, description of portions similar to those of the above-described display device is omitted in some cases.

The display device 50B illustrated in FIG. 51B includes the light-emitting elements 130R, 130G, and 130B, a coloring layer 132R transmitting red light, a coloring layer 132G transmitting green light, a coloring layer 132B transmitting blue light, and the like.

The light-emitting element 130R includes the pixel electrode 111R, the EL layer 113 over the pixel electrode 111R, and the common electrode 115 over the EL layer 113. Light emitted from the light-emitting element 130R is extracted as red light to the outside of the display device 50B through the coloring layer 132R.

The light-emitting element 130G includes the pixel electrode 111G, the EL layer 113 over the pixel electrode 111G, and the common electrode 115 over the EL layer 113. Light emitted from the light-emitting element 130G is extracted as green light to the outside of the display device 50B through the coloring layer 132G.

The light-emitting element 130B includes the pixel electrode 111B, the EL layer 113 over the pixel electrode 111B, and the common electrode 115 over the EL layer 113. Light emitted from the light-emitting element 130B is extracted as blue light to the outside of the display device 50B through the coloring layer 132B.

The EL layer 113 and the common electrode 115 are shared between the light-emitting elements 130R, 130G, and 130B. The number of manufacturing steps can be smaller in the structure in which the EL layer 113 is provided to be shared between the subpixels of different colors than in the structure in which the subpixels of different colors are provided with different EL layers.

The light-emitting elements 130R, 130G, and 130B illustrated in FIG. 51B emit white light, for example. When white light emitted from the light-emitting elements 130R, 130G, and 130B passes through the coloring layers 132R, 132G, and 132B, light of desired colors can be obtained.

The light-emitting element that emits white light preferably includes two or more light-emitting layers. When white light emission is obtained using two light-emitting layers, the two light-emitting layers are selected such that emission colors of the light-emitting layers are complementary colors. For example, when an emission color of a first light-emitting layer and an emission color of a second light-emitting layer are complementary colors, the light-emitting element can be configured to emit white light as a whole. When white light emission is obtained using three or more light-emitting layers, the light-emitting element is configured to emit white light as a whole by combining emission colors of the three or more light-emitting layers.

The EL layer 113 preferably includes a light-emitting layer containing a light-emitting substance that emits blue light and a light-emitting layer containing a light-emitting substance that emits visible light having a longer wavelength than blue light, for example. The EL layer 113 preferably includes a light-emitting layer that emits yellow light and a light-emitting layer that emits blue light, for example. Alternatively, the EL layer 113 preferably includes a light-emitting layer that emits red light, a light-emitting layer that emits green light, and a light-emitting layer that emits blue light, for example.

A light-emitting element that emits white light preferably has a tandem structure. Specifically, examples of applicable structures are as follows: a two-unit tandem structure including a light-emitting unit emitting yellow light and a light-emitting unit emitting blue light; a two-unit tandem structure including a light-emitting unit emitting red light and green light and a light-emitting unit emitting blue light; a three-unit tandem structure in which a light-emitting unit emitting blue light, a light-emitting unit emitting yellow, yellow-green, or green light, and a light-emitting unit emitting blue light are stacked in this order; and a three-unit tandem structure in which a light-emitting unit emitting blue light, a light-emitting unit emitting yellow, yellow-green, or green light and red light, and a light-emitting unit emitting blue light are stacked in this order. Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from the anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Note that in the case where the light-emitting element emitting white light has a microcavity structure, light with a specific wavelength such as red, green, or blue is sometimes intensified to be emitted.

Alternatively, the light-emitting elements 130R, 130G, and 130B illustrated in FIG. 51B emit blue light, for example. In this case, the EL layer 113 includes one or more light-emitting layers that emit blue light. In the subpixel 11B that emits blue light, blue light emitted from the light-emitting element 130B can be extracted. In each of the subpixel 11R that emits red light and the subpixel 11G that emits green light, a color conversion layer is provided between the light-emitting element 130R or the light-emitting element 130G and the substrate 152 so that blue light emitted from the light-emitting element 130R or the light-emitting element 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. In some cases, part of light emitted from the light-emitting element is transmitted through the color conversion layer without being converted. When light transmitted through the color conversion layer is extracted through the coloring layer, light other than light of the desired color can be absorbed by the coloring layer, and color purity of light exhibited by a subpixel can be improved.

### [Display Device 50C]

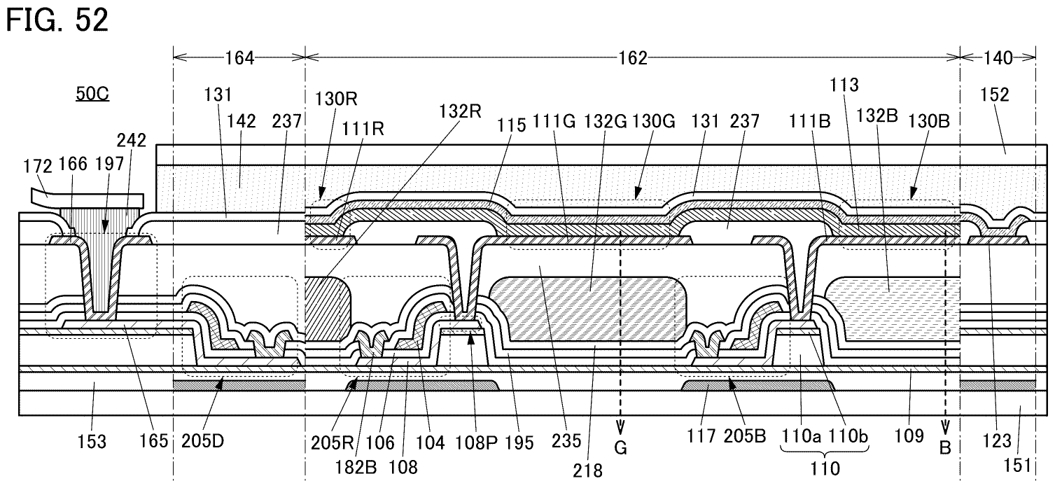

A display device 50C illustrated in FIG. 52 is different from the display device 50B mainly in having a bottom-emission structure.

Light emitted from the light-emitting element is emitted to the substrate 151 side. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor. FIG. 52 shows an example in which the light-blocking layers 117 are provided over the substrate 151, the insulating layer 153 is provided over the light-blocking layers 117, and the transistor 205D, the transistor 205R (not illustrated), the transistor 205G, and the transistor 205B and the like are provided over the insulating layer 153. In addition, the coloring layer 132R, the coloring layer 132G, and the coloring layer 132B are provided over the insulating layer 218, and the insulating layer 235 is provided over the coloring layer 132R, the coloring layer 132G, and the coloring layer 132B.

The light-emitting element 130R overlapping with the coloring layer 132R includes the pixel electrode 111R, the EL layer 113, and the common electrode 115.

The light-emitting element 130G overlapping with the coloring layer 132G includes the pixel electrode 111G, the EL layer 113, and the common electrode 115.

The light-emitting element 130B overlapping with the coloring layer 132B includes the pixel electrode 111B, the EL layer 113, and the common electrode 115.

A material having a high visible-light-transmitting property is used for each of the pixel electrodes 111R, 111G, and 111B. A material reflecting visible light is preferably used for the common electrode 115. In the display device having a bottom-emission structure, a metal or the like having low electrical resistivity can be used for the common electrode 115; thus, a voltage drop due to the electric resistance of the common electrode 115 can be inhibited and a high display quality can be achieved.

The transistor of one embodiment of the present invention can be miniaturized and the area occupied by the transistor can be reduced, so that the aperture ratio of the pixel can be increased or the pixel size can be reduced in the display device having a bottom-emission structure.

### [Display Device 50D]

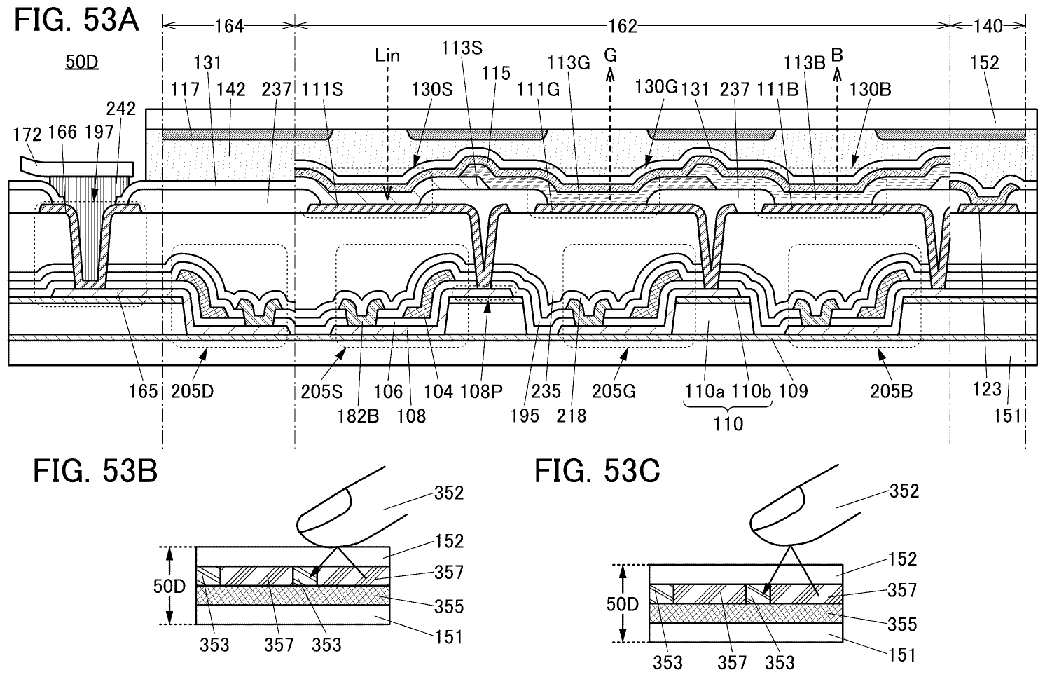

A display device 50D illustrated in FIG. 53A is different from the display device 50A mainly in including a light-receiving element 130S.

The display device 50D includes light-emitting elements and a light-receiving element in a pixel. In the display device 50D, organic EL elements are preferably used as the light-emitting elements and an organic photodiode is preferably used as the light-receiving element. The organic EL elements and the organic photodiode can be formed over the same substrate. Thus, the organic photodiode can be incorporated in the display device including the organic EL elements.

In the display device 50D including light-emitting elements and a light-receiving element in each pixel, the pixel has a light-receiving function; thus, the display device can detect a contact or approach of an object while displaying an image. Accordingly, the display portion 162 has one or both of an image capturing function and a sensing function in addition to a function of displaying an image. For example, all the subpixels included in the display device 50D can display an image; alternatively, some of the subpixels can emit light as a light source, some of the rest of the subpixels can detect light, and the other subpixels can display an image.

Accordingly, a light-receiving portion and a light source do not need to be provided separately from the display device 50D; hence, the number of components of an electronic device can be reduced. For example, it is unnecessary to separately provide a biometric authentication device provided in the electronic device, a capacitive touch panel for scroll operation, or the like. Thus, with the use of the display device 50D, the electronic device can be provided at lower manufacturing costs.

When the light-receiving element is used as an image sensor, the display device 50D can capture an image using the light-receiving element. For example, image capturing for personal authentication with the use of a fingerprint, a palm print, the iris, the shape of a blood vessel (including the shape of a vein and the shape of an artery), a face, or the like is possible by using the image sensor.

The light-receiving element can be used for a touch sensor (also referred to as a direct touch sensor), a contactless sensor (also referred to as a hover sensor, a hover touch sensor, or a touchless sensor), or the like. The touch sensor can detect an object (e.g., a finger, a hand, or a pen) when the display device and the object come in direct contact with each other. Furthermore, the contactless sensor can detect an object even when the object is not in contact with the display device.

The light-receiving element 130S includes a pixel electrode 111S over the insulating layer 235, a functional layer 113S over the pixel electrode 111S, and the common electrode 115 over the functional layer 113S. Light Lin enters the functional layer 113S from the outside of the display device 50D.

The pixel electrode 111S is electrically connected to the region 108P included in the layer 108 of a transistor 205S through an opening provided in the insulating layer 106, the insulating layer 195, the insulating layer 218, and the insulating layer 235.

An end portion of the pixel electrode 111S is covered with the insulating layer 237. The common electrode 115 is a continuous film provided to be shared by the light-receiving element 130S, the light-emitting element 130R (not illustrated), the light-emitting element 130G, and the light-emitting element 130B. The common electrode 115 shared by the light-emitting elements and the light-receiving element is electrically connected to the conductive layer 123 provided in the connection portion 140.

The functional layer 113S includes at least an active layer (also referred to as a photoelectric conversion layer). The active layer includes a semiconductor. Examples of the semiconductor include an inorganic semiconductor such as silicon and an organic semiconductor including an organic compound. This embodiment describes an example in which an organic semiconductor is used as the semiconductor included in the active layer. The use of an organic semiconductor is preferable because the light-emitting layer and the active layer can be formed by the same method (e.g., a vacuum evaporation method) and thus the same manufacturing apparatus can be used.

In addition to the active layer, the functional layer 113S may further include a layer containing a substance having a high hole-transport property, a substance having a high electron-transport property, a bipolar substance, or the like. Without limitation to the above, the functional layer 113S may further include a layer containing a substance having a high hole-injection property, a hole-blocking material, a substance having a high electron-injection property, an electron-blocking material, or the like. For the functional layer 113S, a material that can be used for the light-emitting element can be used, for example.

Either a low molecular compound or a high molecular compound can be used for the light-receiving element, and an inorganic compound may be included. Each of the layers included in the light-receiving element can be formed by an evaporation method (including a vacuum evaporation method), a transfer method, a printing method, an inkjet method, a coating method, or the like.

The display device 50D illustrated in FIG. 53B and FIG. 53C includes, between the substrate 151 and the substrate 152, a layer 353 including the light-receiving element, a circuit layer 355, and a layer 357 including the light-emitting elements.

The layer 353 includes the light-receiving element 130S, for example. The layer 357 includes the light-emitting elements 130R, 130G, and 130B, for example.

The functional layer 355 includes a circuit for driving the light-receiving element and a circuit for driving the light-emitting element. The circuit layer 355 includes the transistors 205R, 205G, and 205B, for example. In addition, one or more of a switch, a capacitor, a resistor, a wiring, a terminal, and the like can be provided in the circuit layer 355.

FIG. 53B shows an example in which the light-receiving element 130S is used as a touch sensor. Light emitted from the light-emitting element in the layer 357 is reflected by a finger 352 that touches the display device 50D as illustrated in FIG. 53B, and the light-receiving element in the layer 353 detects the reflected light. Thus, the touch of the finger 352 on the display device 50D can be detected.

FIG. 53C is an example in which the light-receiving element 130S is used as a contactless sensor. Light emitted from the light-emitting element in the layer 357 is reflected by the finger 352 that is approaching (i.e., that is not in contact with) the display device 50D as illustrated in FIG. 53C, and the light-receiving element in the layer 353 detects the reflected light.

### [Display Device 50E]

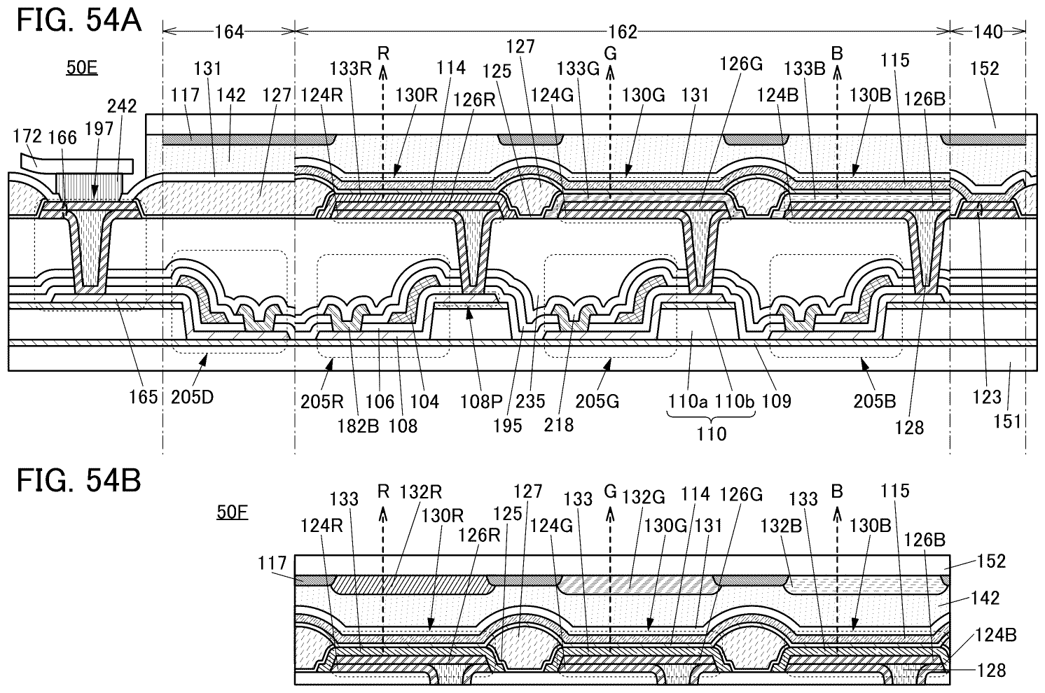

A display device 50E illustrated in FIG. 54A is an example of a display device having an MML (metal maskless) structure. In other words, the display device 50E includes a light-emitting element that is formed without using a fine metal mask. The stacked-layer structure from the substrate 151 to the insulating layer 235 and the stacked-layer structure from the protective layer 131 to the substrate 152 are similar to those in the display device 50A; thus, the description thereof is omitted.

In FIG. 54A, the light-emitting elements 130R, 130G, and 130B are provided over the insulating layer 235.

The light-emitting element 130R includes a conductive layer 124R over the insulating layer 235, a conductive layer 126R over the conductive layer 124R, a layer 133R over the conductive layer 126R, a common layer 114 over the layer 133R, and the common electrode 115 over the common layer 114. The light-emitting element 130R illustrated in FIG. 54A emits red light (R). The layer 133R includes a light-emitting layer that emits red light. In the light-emitting element 130R, the layer 133R and the common layer 114 can be collectively referred to as an EL layer. One or both of the conductive layer 124R and the conductive layer 126R can be referred to as a pixel electrode.

The light-emitting element 130G includes a conductive layer 124G over the insulating layer 235, a conductive layer 126G over the conductive layer 124G, a layer 133G over the conductive layer 126G, the common layer 114 over the layer 133G, and the common electrode 115 over the common layer 114. The light-emitting element 130G illustrated in FIG. 54A emits green light (G). The layer 133G includes a light-emitting layer that emits green light. In the light-emitting element 130G, the layer 133G and the common layer 114 can be collectively referred to as an EL layer. One or both of the conductive layer 124G and the conductive layer 126G can be referred to as a pixel electrode.

The light-emitting element 130B includes a conductive layer 124B over the insulating layer 235, a conductive layer 126B over the conductive layer 124B, a layer 133B over the conductive layer 126B, the common layer 114 over the layer 133B, and the common electrode 115 over the common layer 114. The light-emitting element 130B illustrated in FIG. 54A emits blue light (B). The layer 133B includes a light-emitting layer that emits blue light. In the light-emitting element 130B, the layer 133B and the common layer 114 can be collectively referred to as an EL layer. One or both of the conductive layer 124B and the conductive layer 126B can be referred to as a pixel electrode.

In this specification and the like, in the EL layers included in the light-emitting elements, the island-shaped layer provided in each light-emitting element is referred to as the layer 133B, the layer 133G, or the layer 133R, and the layer shared by the plurality of light-emitting elements is referred to as the common layer 114. Note that in this specification and the like, the layer 133R, the layer 133G, and the layer 133B are sometimes referred to as island-shaped EL layers, EL layers formed in an island shape, or the like, in which case the common layer 114 is not included. The layer 133R, the layer 133G, and the layer 133B are separated from one another.

When the EL layer is provided to have an island shape for each light-emitting element, a leakage current between adjacent light-emitting elements can be inhibited. This can prevent unintended light emission due to crosstalk, so that a display device with extremely high contrast can be obtained.

Although the layers 133R, 133G, and 133B have the same thickness in FIG. 54A, the present invention is not limited thereto. The layers 133R, 133G, and 133B may have different thicknesses.

The conductive layer 124R is electrically connected to the region 108P included in the layer 108 of the transistor 205R through an opening provided in the insulating layer 106, the insulating layer 195, the insulating layer 218, and the insulating layer 235. In a similar manner, the conductive layer 124G is electrically connected to the region 108P included in the layer 108 of the transistor 205G and the conductive layer 124B is electrically connected to the region 108P included in the layer 108 of the transistor 205B.

The conductive layers 124R, 124G, and 124B are formed to cover the openings provided in the insulating layer 235. A layer 128 is embedded in each of the depressed portions of the conductive layers 124R, 124G, and 124B.

The layer 128 has a planarization function for the depressed portions of the conductive layers 124R, 124G, and 124B. The conductive layers 126R, 126G, and 126B electrically connected to the conductive layers 124R, 124G, and 124B, respectively, are provided over the conductive layers 124R, 124G, and 124B and the layer 128. Thus, regions overlapping with the depressed portions of the conductive layers 124R, 124G, and 124B can also be used as the light-emitting regions, increasing the aperture ratio of the pixels. As each of the conductive layer 124R and the conductive layer 126R, a conductive layer functioning as a reflective electrode is preferably used.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the insulating layer 237 can be used, for example.

Although FIG. 54A shows an example in which the top surface of the layer 128 includes a flat portion, the shape of the layer 128 is not particularly limited. The top surface of the layer 128 may include at least one of a convex surface, a concave surface, and a flat surface.

The level of the top surface of the layer 128 and the level of the top surface of the conductive layer 124R may be the same or substantially the same, or may be different from each other. For example, the level of the top surface of the layer 128 may be either lower or higher than the level of the top surface of the conductive layer 124R.

An end portion of the conductive layer 126R may be aligned with an end portion of the conductive layer 124R or may cover the side surface of the end portion of the conductive layer 124R. The end portions of the conductive layer 124R and the conductive layer 126R each preferably have a tapered shape. Specifically, the end portions of the conductive layer 124R and the conductive layer 126R each preferably have a tapered shape with a taper angle greater than 0° and less than 90°. In the case where the end portion of the pixel electrode has a tapered shape, the layer 133R provided along the side surface of the pixel electrode has an inclined portion. When the side surface of the pixel electrode has a tapered shape, coverage with an EL layer provided along the side surface of the pixel electrode can be favorable.

Since the conductive layers 124G and 126G and the conductive layers 124B and 126B are similar to the conductive layers 124R and 126R, the detailed description thereof is omitted.

The top surface and the side surface of the conductive layer 126R are covered with the layer 133R. Similarly, the top surface and the side surface of the conductive layer 126G are covered with the layer 133G, and the top surface and the side surface of the conductive layer 126B are covered with the layer 133B. Accordingly, regions provided with the conductive layers 126R, 126G, and 126B can be entirely used as the light-emitting regions of the light-emitting elements 130R, 130G, and 130B, thereby increasing the aperture ratio of the pixels.

The side surface and part of the top surface of each of the layer 133R, the layer 133G, and the layer 133B are covered with the insulating layers 125 and 127. The common layer 114 is provided over the layer 133R, the layer 133G, the layer 133B, and the insulating layers 125 and 127, and the common electrode 115 is provided over the common layer 114. The common layer 114 and the common electrode 115 are each a continuous film shared by a plurality of light-emitting elements.

In FIG. 54A, the insulating layer 237 illustrated in FIG. 51A or the like is not provided between the conductive layer 126R and the layer 133R. That is, an insulating layer (also referred to as a partition wall, a bank, a spacer, or the like) in contact with the pixel electrode and covering an upper end portion of the pixel electrode is not provided in the display device 50E. Thus, the distance between adjacent light-emitting elements can be extremely narrowed. Accordingly, the display device can have high definition or high resolution. In addition, a mask (e.g., a photomask) for forming the insulating layer is not needed, which leads to a reduction in manufacturing cost of the display device.

As described above, the layer 133R, the layer 133G, and the layer 133B each include the light-emitting layer. The layer 133R, the layer 133G, and the layer 133B each preferably include the light-emitting layer and a carrier-transport layer (an electron-transport layer or a hole-transport layer) over the light-emitting layer. Alternatively, the layer 133R, the layer 133G, and the layer 133B each preferably include the light-emitting layer and a carrier-blocking layer (a hole-blocking layer or an electron-blocking layer) over the light-emitting layer. Alternatively, the layer 133R, the layer 133G, and the layer 133B each preferably include the light-emitting layer, a carrier-blocking layer over the light-emitting layer, and a carrier-transport layer over the carrier-blocking layer. Since surfaces of the layer 133R, the layer 133G, and the layer 133B are exposed in the manufacturing process of the display device, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting element can be increased.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared by the light-emitting elements 130R, 130G, and 130B.

The side surfaces of the layer 133R, the layer 133G, and the layer 133B are each covered with the insulating layer 125. The insulating layer 127 covers the side surfaces of the layer 133R, the layer 133G, and the layer 133B with the insulating layer 125 therebetween.

The side surfaces (and part of the top surfaces) of the layer 133R, the layer 133G, and the layer 133B are covered with at least one of the insulating layer 125 and the insulating layer 127, so that the common layer 114 (or the common electrode 115) can be inhibited from being in contact with the side surfaces of the pixel electrodes and the layers 133R, 133G, and 133B, leading to inhibition of a short circuit of the light-emitting elements. Thus, the reliability of the light-emitting element can be increased.

The insulating layer 125 is preferably in contact with the side surfaces of the layer 133R, the layer 133G, and the layer 133B. The insulating layer 125 in contact with the layer 133R, the layer 133G, and the layer 133B can prevent film separation of the layer 133R, the layer 133G, and the layer 133B, whereby the reliability of the light-emitting element can be increased.

The insulating layer 127 is provided over the insulating layer 125 to fill a depressed portion of the insulating layer 125. The insulating layer 127 preferably covers at least part of the side surface of the insulating layer 125.

The insulating layer 125 and the insulating layer 127 can fill a gap between adjacent island-shaped layers, whereby the formation surface of the layers (e.g., the carrier-injection layer and the common electrode) provided over the island-shaped layers can have higher flatness with small unevenness. Consequently, coverage with the carrier-injection layer, the common electrode, and the like can be improved.

The common layer 114 and the common electrode 115 are provided over the layer 133R, the layer 133G, the layer 133B, the insulating layer 125, and the insulating layer 127. Before the insulating layer 125 and the insulating layer 127 are provided, there is a step due to a region where the pixel electrode and the island-shaped EL layer are provided and a region where neither the pixel electrode nor the island-shaped EL layer is provided (a region between the light-emitting elements). In the display device of one embodiment of the present invention, the step can be reduced with the insulating layer 125 and the insulating layer 127, and the coverage with the common layer 114 and the common electrode 115 can be improved. Thus, connection defects caused by step disconnection can be inhibited. Alternatively, an increase in electric resistance caused by local thinning of the common electrode 115 due to the step can be inhibited.

The top surface of the insulating layer 127 preferably has a shape with higher flatness. The top surface of the insulating layer 127 may include at least one of a flat surface, a convex surface, and a concave surface. For example, the top surface of the insulating layer 127 preferably has a convex shape with a large radius of curvature.

The insulating layer 125 can be an inorganic insulating film. For the insulating layer 125, an oxide, a nitride, an oxynitride, or a nitride oxide can be used, for example. Specific examples of a material that can be used for the inorganic insulating film are as described above. The insulating layer 125 may have a single-layer structure or a stacked-layer structure. In particular, aluminum oxide is preferable because it has high selectivity with respect to the EL layer in etching and has a function of protecting the EL layer in forming the insulating layer 127 to be described later. In particular, when an inorganic insulating film such as an aluminum oxide film, a hafnium oxide film, or a silicon oxide film formed by an ALD method is used as the insulating layer 125, the insulating layer 125 having few pinholes and an excellent function of protecting the EL layer can be formed. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. The insulating layer 125 preferably has a function of inhibiting diffusion of at least one of water and oxygen. In addition, the insulating layer 125 preferably has a function of capturing or fixing (also referred to as gettering) at least one of water and oxygen.

When the insulating layer 125 has a function of a barrier insulating layer, entry of impurities (typically, at least one of water and oxygen) that might diffuse into the light-emitting elements from the outside can be inhibited. With this structure, a highly reliable light-emitting element and a highly reliable display device can be provided.

The insulating layer 125 preferably has a low impurity element concentration. Accordingly, degradation of the EL layer, which is caused by entry of impurities into the EL layer from the insulating layer 125, can be inhibited. In addition, when an impurity element concentration is reduced in the insulating layer 125, a barrier property against at least one of water and oxygen can be increased. For example, the insulating layer 125 preferably has one of a sufficiently low hydrogen concentration and a sufficiently low carbon concentration, desirably has both of them.

The insulating layer 127 provided over the insulating layer 125 has a function of filling large unevenness of the insulating layer 125, which is formed between the adjacent light-emitting elements. In other words, the insulating layer 127 has an effect of improving the flatness of the formation surface of the common electrode 115.

As the insulating layer 127, an insulating layer containing an organic material can be suitably used. As the organic material, a photosensitive organic resin is preferably used, and for example, a photosensitive resin composite including an acrylic resin is preferably used. Note that in this specification and the like, an acrylic resin refers to not only a polymethacrylic acid ester or a methacrylic resin, but also all the acrylic-based polymers in a broad sense in some cases.

For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like may be used. For the insulating layer 127, an organic material such as polyvinyl alcohol (PVA), polyvinyl butyral, polyvinyl pyrrolidone, polyethylene glycol, polyglycerin, pullulan, water-soluble cellulose, or an alcohol-soluble polyamide resin may be used. A photoresist may be used as the photosensitive resin. As the photosensitive organic resin, either a positive material or a negative material may be used.

For the insulating layer 127, a material absorbing visible light may be used. When the insulating layer 127 absorbs light emitted from the light-emitting element, leakage of light (stray light) from the light-emitting element to an adjacent light-emitting element through the insulating layer 127 can be inhibited. Thus, the display quality of the display device can be improved. Furthermore, since the display quality can be increased even when a polarizing plate is not used in the display device, a lightweight and thin display device can be achieved.

Examples of the material absorbing visible light include materials including pigment of black or the like, materials including dye, light-absorbing resin materials (e.g., polyimide), and resin materials that can be used for color filters (color filter materials). Using a resin material obtained by stacking or mixing color filter materials of two colors or three or more colors is particularly preferable, in which case the effect of blocking visible light can be enhanced. In particular, mixing color filter materials of three or more colors enables the formation of a black or nearly black resin layer.

### [Display Device 50F]

FIG. 54B shows an example of a cross section of the display portion 162 of a display device 50F. The display device 50F is different from the display device 50E mainly in that coloring layers (color filters or the like) are used for the subpixels of different colors. The structure illustrated in FIG. 54B can be combined with the structure of the region including the FPC 172, the circuit portion 164, the stacked-layer structure from the substrate 151 to the insulating layer 235 in the display portion 162, the connection portion 140, and an end portion, which is illustrated in FIG. 54A.

The display device 50F illustrated in FIG. 54B includes the light-emitting elements 130R, 130G, and 130B, the coloring layer 132R transmitting red light, the coloring layer 132G transmitting green light, the coloring layer 132B transmitting blue light, and the like.

Light emitted from the light-emitting element 130R is extracted as red light to the outside of the display device 50F through the coloring layer 132R. Similarly, light emitted from the light-emitting element 130G is extracted as green light to the outside of the display device 50F through the coloring layer 132G. Light emitted from the light-emitting element 130B is extracted as blue light to the outside of the display device 50F through the coloring layer 132B.

The light-emitting elements 130R, 130G, and 130B each include the layer 133. The three layers 133 are formed using the same material in the same step. The three layers 133 are separated from each other. When the EL layer is provided to have an island shape for each light-emitting element, a leakage current between adjacent light-emitting elements can be inhibited. This can prevent unintended light emission due to crosstalk, so that a display device with extremely high contrast can be obtained.

The light-emitting elements 130R, 130G, and 130B illustrated in FIG. 54B emit white light, for example. When white light emitted from the light-emitting elements 130R, 130G, and 130B passes through the coloring layers 132R, 132G, and 132B, light of desired colors can be obtained.

Alternatively, the light-emitting elements 130R, 130G, and 130B illustrated in FIG. 54B emit blue light, for example. In this case, the layer 133 includes one or more light-emitting layers that emit blue light. In the subpixel 11B that emits blue light, blue light emitted from the light-emitting element 130B can be extracted. In each of the subpixel 11R that emits red light and the subpixel 11G that emits green light, a color conversion layer is provided between the light-emitting element 130R or the light-emitting element 130G and the substrate 152 so that blue light emitted from the light-emitting element 130R or the light-emitting element 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. When light transmitted through the color conversion layer is extracted through the coloring layer, light other than light of the desired color can be absorbed by the coloring layer, and color purity of light exhibited by a subpixel can be improved.

### [Display Device 50G]

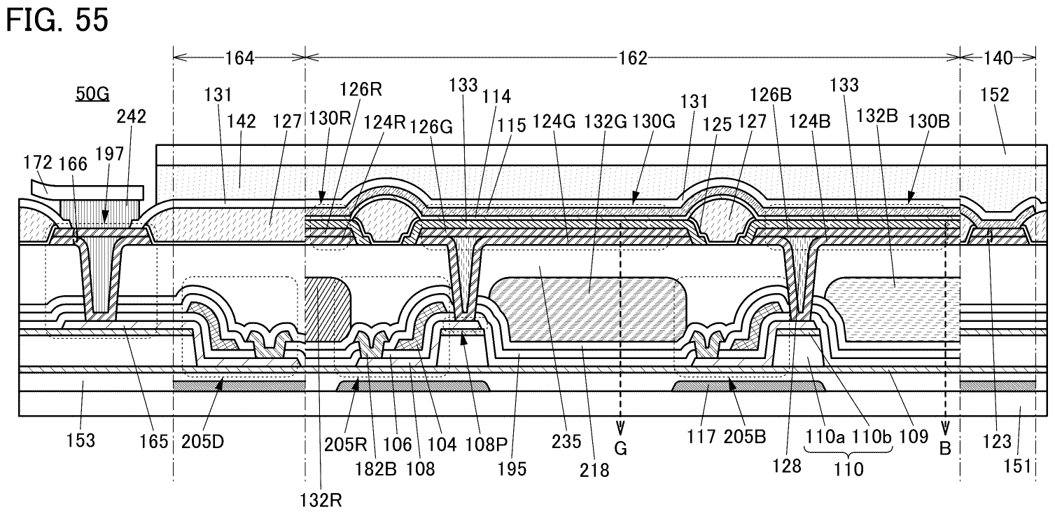

A display device 50G illustrated in FIG. 55 is different from the display device 50F mainly in having a bottom-emission structure.

Light emitted from the light-emitting element is emitted to the substrate 151 side. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor. FIG. 55 shows an example in which the light-blocking layers 117 are provided over the substrate 151, the insulating layer 153 is provided over the light-blocking layers 117, and the transistor 205D, the transistor 205R (not illustrated), the transistor 205G, and the transistor 205B and the like are provided over the insulating layer 153. In addition, the coloring layer 132R, the coloring layer 132G, and the coloring layer 132B are provided over the insulating layer 218, and the insulating layer 235 is provided over the coloring layer 132R, the coloring layer 132G, and the coloring layer 132B.

The light-emitting element 130R overlapping with the coloring layer 132R includes the conductive layer 124R, the conductive layer 126R, the layer 133, the common layer 114, and the common electrode 115.

The light-emitting element 130G overlapping with the coloring layer 132G includes the conductive layer 124G, the conductive layer 126G, the layer 133, the common layer 114, and the common electrode 115.

The light-emitting element 130B overlapping with the coloring layer 132B includes the conductive layer 124B, the conductive layer 126B, the layer 133, the common layer 114, and the common electrode 115.

A material having a high visible-light-transmitting property is used for each of the conductive layers 124R, 124G, 124B, 126R, 126G, and 126B. A material reflecting visible light is preferably used for the common electrode 115. In the display device having a bottom-emission structure, a metal or the like having low electrical resistivity can be used for the common electrode 115; thus, a voltage drop due to the electric resistance of the common electrode 115 can be inhibited and a high display quality can be achieved.

The transistor of one embodiment of the present invention can be miniaturized and the area occupied by the transistor can be reduced, so that the aperture ratio of the pixel can be increased or the pixel size can be reduced in the display device having a bottom-emission structure.

### [Display Device 50H]

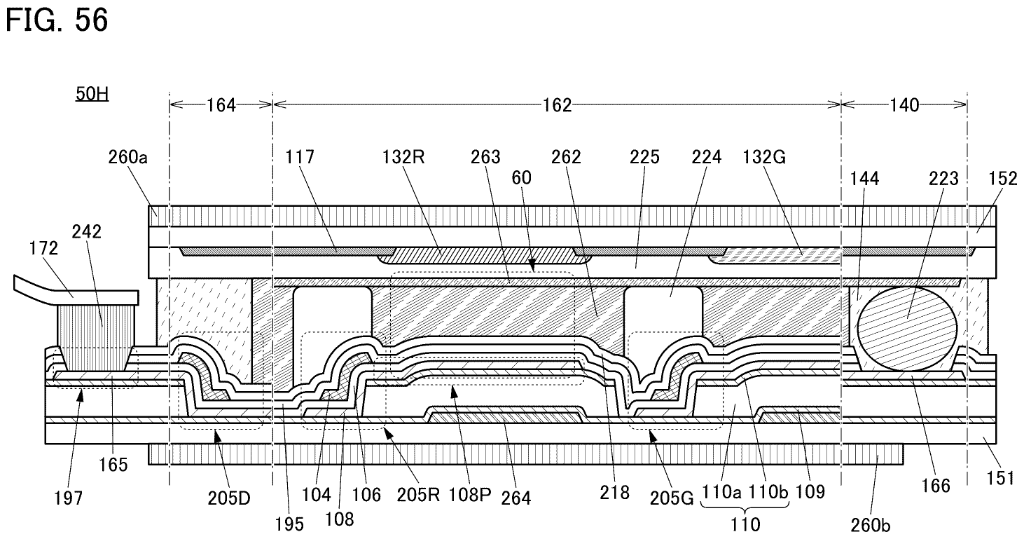

A display device 50H illustrated in FIG. 56 is a liquid crystal display device in a VA mode.

The substrate 151 and the substrate 152 are attached to each other with an adhesive layer 144. Liquid crystal 262 is sealed in a region surrounded by the substrate 151, the substrate 152, and the adhesive layer 144. A polarizing plate 260a is positioned on the outer surface of the substrate 152, and a polarizing plate 260b is positioned on the outer surface of the substrate 151. Although not illustrated, a backlight can be provided outside the polarizing plate 260a or outside the polarizing plate 260b.

The substrate 151 is provided with the transistors 205D, 205R, and 205G, the connection portion 197, a spacer 224, and the like. The transistor 205D is a transistor provided in the circuit portion 164, and the transistors 205R and 205G are transistors provided in the display portion 162. The region 108P included in the layer 108 of each of the transistors 205R and 205G functions as a pixel electrode of a liquid crystal element 60. Although the structure in which the region 108P functions as a pixel electrode is described as an example here, one embodiment of the present invention is not limited thereto. For example, the region 108Q included in the layer 108 may function as the pixel electrode of the liquid crystal element 60.

The substrate 152 is provided with the coloring layer 132R, the coloring layer 132G, the light-blocking layer 117, an insulating layer 225, a conductive layer 263, and the like. The conductive layer 263 functions as a common electrode of the liquid crystal element 60.

The transistors 205D, 205R, and 205G each include the layer 108, the insulating layer 106, and the conductive layer 104. The conductive layer 104 functions as a gate electrode. Part of the insulating layer 106 functions as a gate insulating layer. The layer 108 includes the region 108P in a region in contact with the insulating layer 110b, and the region 108P functions as one of a source electrode and a drain electrode. The layer 108 includes the region 108Q in a region in contact with the insulating layer 109, and the region 108Q functions as the other of the source electrode and the drain electrode.

As described above, this embodiment describes an example in which OS transistors are used as the transistors 205D, 205R, and 205G. The transistor of one embodiment of the present invention can be used as the transistors 205D, 205R, and 205G. In other words, the display device 50H includes the transistor of one embodiment of the present invention in both the display portion 162 and the circuit portion 164. When the transistor of one embodiment of the present invention is used in the display portion 162, the pixel size can be reduced and high definition can be achieved. When the transistor of one embodiment of the present invention is used in the circuit portion 164, the area occupied by the circuit portion 164 can be reduced and a narrower bezel can be achieved. The description in the above embodiment can be referred to for the transistor of one embodiment of the present invention.

A subpixel included in the display portion 162 includes a transistor, the liquid crystal element 60, and a coloring layer. For example, a subpixel that emits red light includes the transistor 205R, the liquid crystal element 60, and the coloring layer 132R that transmits red light. A subpixel that emits green light includes the transistor 205G, the liquid crystal element 60, and the coloring layer 132G that transmits green light. Similarly, although not illustrated, a subpixel that emits blue light includes a transistor, the liquid crystal element 60, and a coloring layer that transmits blue light.

The liquid crystal element 60 includes the region 108P included in the layer 108, the conductive layer 263, and the liquid crystal 262 interposed therebetween.

A conductive layer 264 is provided over the substrate 151. The conductive layer 264 includes a portion overlapping with the region 108P with the insulating layer 110 therebetween. The region 108P, the conductive layer 264, and the insulating layer 110 therebetween form a storage capacitor. Note that the insulating layer 110 may be partly removed as long as at least one insulating layer is provided between the region 108P and the conductive layer 264.

The insulating layer 225 is provided on the substrate 152 side to cover the coloring layers 132R and 132G and the light-blocking layer 117. The insulating layer 225 may have a function as a planarization layer. The conductive layer 263 can have a substantially flat surface owing to the insulating layer 225, resulting in a uniform alignment state of the liquid crystal 262.

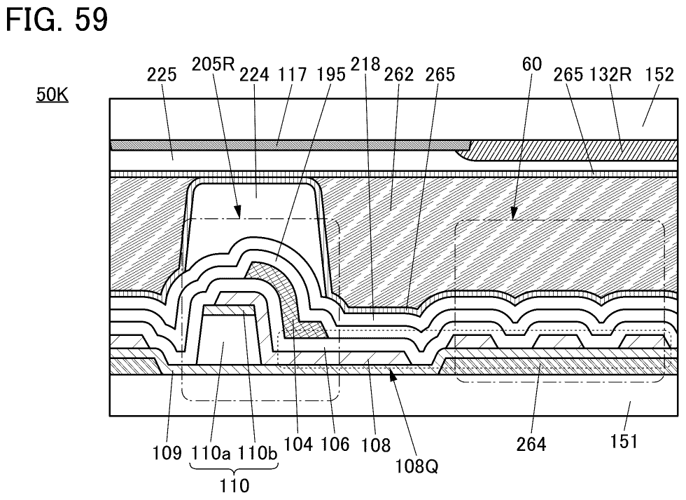

Note that an alignment film for controlling the alignment of the liquid crystal 262 may be provided on surfaces of the conductive layer 263, the insulating layer 218, and the like which are in contact with the liquid crystal 262 (see an alignment film 265 in FIG. 59).

The region 108P, which is an oxide conductor, transmits visible light. A material that transmits visible light can be used for each of the conductive layer 263 and the conductive layer 264. Thus, a transmissive liquid crystal display device can be obtained. For example, in the case where a backlight is provided on the substrate 152 side, light from the backlight which is polarized by the polarizing plate 260a passes through the substrate 152, the conductive layer 263, the liquid crystal 262, the region 108P, and the substrate 151, and then reaches the polarizing plate 260b. Here, the alignment of the liquid crystal 262 is controlled by a voltage applied between the region 108P and the conductive layer 263, whereby optical modulation of light can be controlled. In other words, the intensity of light emitted through the polarizing plate 260b can be controlled. Light other than one in a particular wavelength region is absorbed by the coloring layer, and thus, extracted light is red light, for example.

As the polarizing plate 260b, a linear polarizing plate may be used or a circularly polarizing plate can also be used. As a circularly polarizing plate, a stack including a linear polarizing plate and a quarter-wave retardation plate can be used. Reflection of external light can be reduced with a circularly polarizing plate used as the polarizing plate 260b.

In the case where a circularly polarizing plate is used as the polarizing plate 260b, a circularly polarizing plate or a general linear polarizing plate may be used as the polarizing plate 260a. The cell gap, alignment, drive voltage, and the like of the liquid crystal element used as the liquid crystal element 60 are controlled depending on the kind of the polarizing plate used as the polarizing plate 260a and the polarizing plate 260b so that desirable contrast is obtained.

The conductive layer 263 is electrically connected to the conductive layer 166 provided on the substrate 151 side through a connector 223 in the connection portion 140. Thus, a potential or a signal can be supplied to the conductive layer 263 from the FPC, the IC, or the like placed on the substrate 151 side. FIG. 56 shows an example in which the conductive layer 166 is formed in the same step as the region 108P included in the layer 108. The conductive layer 166 is provided in a region in contact with the uppermost layer of the insulating layer 110 (here, the insulating layer 110b).

As the connector 223, a conductive particle can be used, for example. As the conductive particle, a particle of an organic resin, silica, or the like coated with a metal material can be used. It is preferable to use nickel or gold as the metal material because contact resistance can be reduced. It is also preferable to use a particle coated with layers of two or more kinds of metal materials, such as a particle coated with nickel and further with gold. For the connector 223, a material capable of elastic deformation or plastic deformation is preferably used. At this time, as illustrated in FIG. 56, the conductive particle has a shape that is vertically crushed in some cases. With the crushed shape, the contact area of the connector 223 and a conductive layer electrically connected thereto can be increased, whereby contact resistance can be reduced and occurrence of problems such as connection defects can be inhibited. The connector 223 is preferably placed to be covered with the adhesive layer 144. For example, the connectors 223 can be dispersed in the adhesive layer 144 before curing.

In a region near an end portion of the substrate 151, the connection portion 197 is provided. In the connection portion 197, the conductive layer 165 is electrically connected to the FPC 172 through the connection layer 242. FIG. 56 shows an example in which the conductive layer 165 is formed in the same step as the region 108P included in the layer 108. The conductive layer 165 is provided in a region in contact with the uppermost layer of the insulating layer 110 (here, the insulating layer 110b).

### [Display Device 50I]

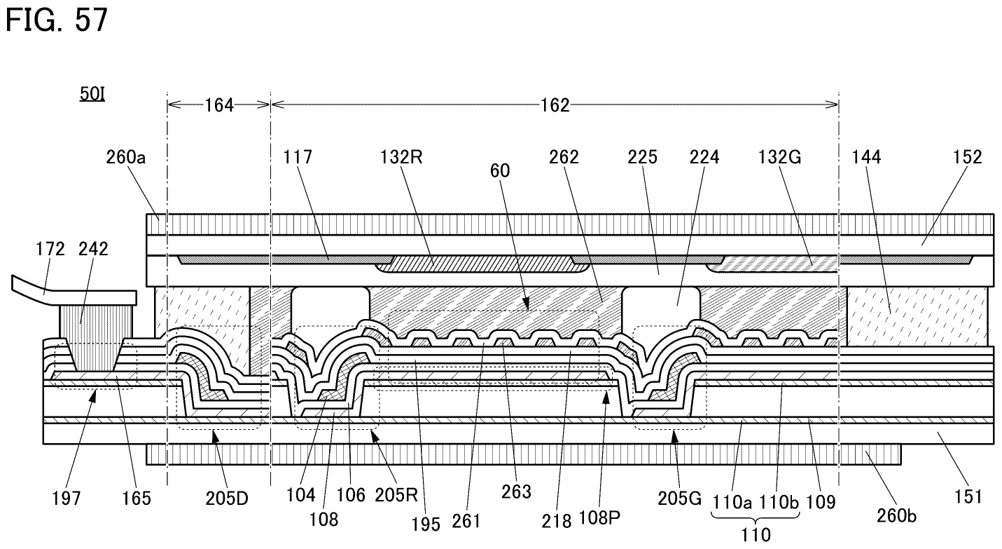

A display device 50I illustrated in FIG. 57 is a liquid crystal display device in an FFS mode. The display device 50I is different from the display device 50H mainly in the structure of the liquid crystal element 60.

The region 108P included in the layer 108 of the transistor functions as one of the source electrode and the drain electrode of the transistor, and functions as the pixel electrode of the liquid crystal element 60. The insulating layer 218 is provided over the transistor, and the conductive layer 263 functioning as the common electrode of the liquid crystal element 60 is provided over the insulating layer 218. Moreover, an insulating layer 261 is provided over the conductive layer 263.

In a plan view, the conductive layer 263 has a comb-like shape or a shape with a slit. The conductive layer 263 is provided to overlap with the region 108P. There is a portion where the conductive layer 263 is not provided over the region 108P in a region overlapping with the coloring layer.

The region 108P and the conductive layer 263 are stacked with the insulating layer 106, insulating layer 195, and the insulating layer 218 therebetween, whereby a capacitor is formed. Therefore, it is not necessary to provide a capacitor additionally, and thus the aperture ratio of the pixel can be increased.

Note that in the liquid crystal element 60, both the region 108P and the conductive layer 263 may each have a comb-like top surface shape. Meanwhile, as illustrated in the display device 50I, when only one of the region 108P and the conductive layer 263 has a comb-like top surface shape in the liquid crystal element 60, the region 108P and the conductive layer 263 partly overlap with each other. In this structure, capacitance between the region 108P and the conductive layer 263 can be used as a storage capacitor, so that another capacitor is not necessarily provided, and thus the aperture ratio of the display device can be increased.

### [Display Device 50J]

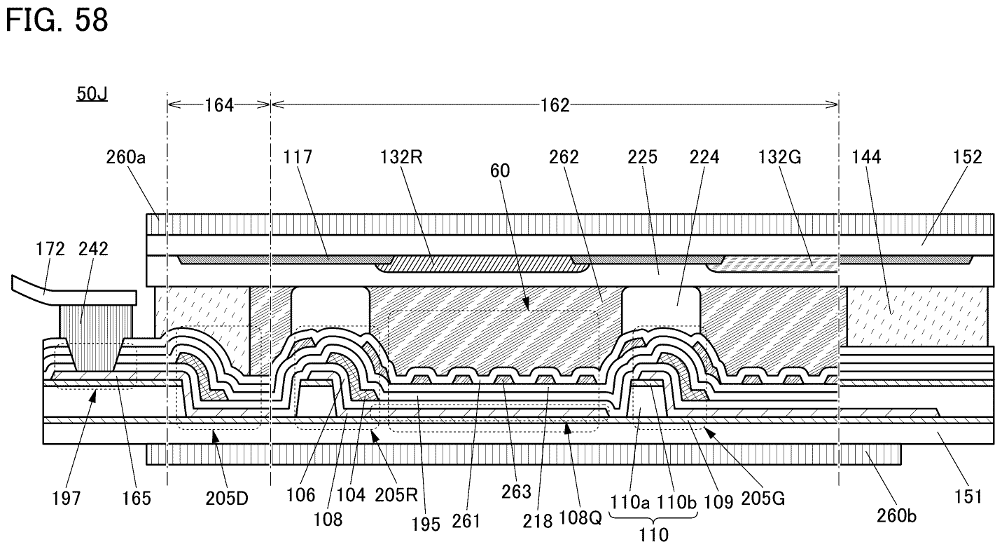

A display device 50J illustrated in FIG. 58 is different from the display device 50I mainly in that the region 108Q included in the layer 108 functions as a pixel electrode.

The region 108Q included in the layer 108 of the transistor functions as one of the source electrode and the drain electrode of the transistor, and functions as the pixel electrode of the liquid crystal element 60.

The conductive layer 263 is provided to overlap with the region 108Q. There is a portion where the conductive layer 263 is not provided over the region 108Q in a region overlapping with the coloring layer.

The region 108Q and the conductive layer 263 are stacked with the insulating layer 106, the insulating layer 195, and the insulating layer 218 therebetween, whereby a capacitor is formed. Therefore, it is not necessary to provide a capacitor additionally, and thus the aperture ratio of the pixel can be increased.

In the display device 50J, the liquid crystal element 60 includes a portion not overlapping with the insulating layer 110. The liquid crystal element 60 and the insulating layer 110 do not overlap with each other, which enables not only an increase in the light transmittance but also a reduction in the number of interfaces positioned on paths of light from the light source; accordingly, influences of interface reflection and interface scattering can be inhibited.

### [Display Device 50K]

A display device 50K illustrated in FIG. 59 is different from the display device 50J mainly in that the pixel electrode is provided over the common electrode.

The region 108Q functions as the pixel electrode of the liquid crystal element 60. The conductive layer 264 functions as a common electrode of the liquid crystal element 60.

Note that a portion of one or more of the insulating layer 106, the insulating layer 195, and the insulating layer 218 that overlaps with the liquid crystal element 60 may be removed by etching. This facilitates transmission of electric fields of the region 108Q and the conductive layer 264 to the liquid crystal 262, which enables high-speed operation of the liquid crystal element 60. Furthermore, light transmittance of a portion overlapping with the liquid crystal element 60 can be increased and the influences of interface reflection and interface scattering can be inhibited. Furthermore, the capacitance between the region 108Q and the conductive layer 264 can be increased in some cases.

In the liquid crystal element 60, both the region 108Q and the conductive layer 264 may each have a comb-like top surface shape.

### Example of Method for Manufacturing Display Device

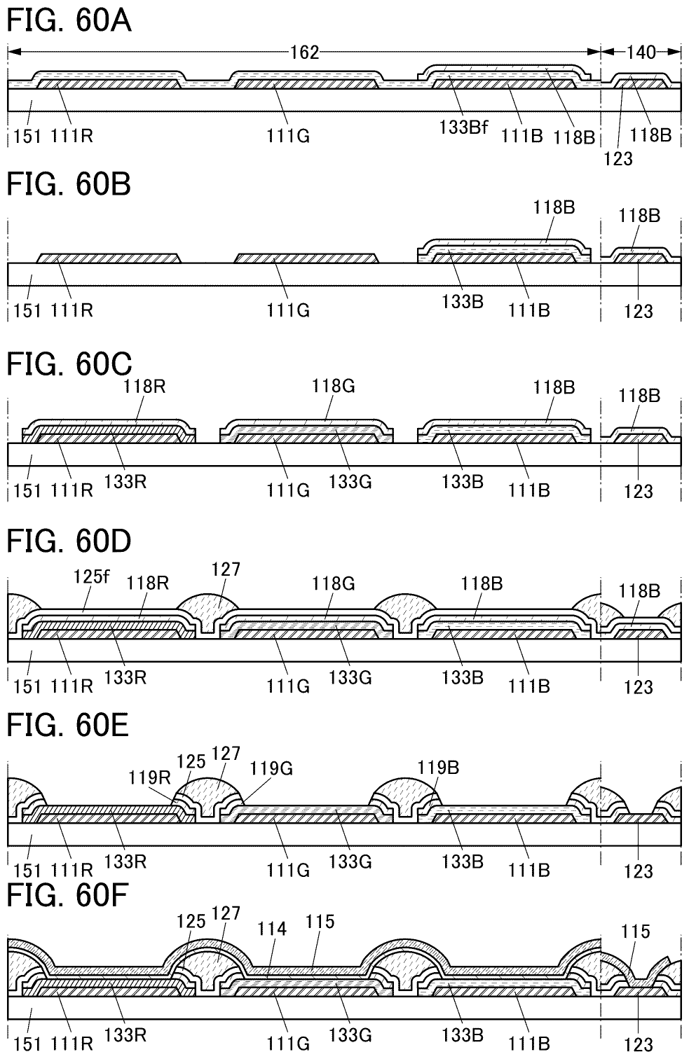

A method for fabricating a display device having an MML (metal maskless) structure will be described below with reference to FIG. 60. Here, steps of manufacturing light-emitting elements without using a fine metal mask will be described in detail. In FIG. 60, cross-sectional views of three light-emitting elements included in the display portion 162 and the connection portion 140 in the manufacturing steps are illustrated.

For manufacture of the light-emitting elements, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a hole-blocking layer, a light-emitting layer, an electron-blocking layer, an electron-transport layer, an electron-injection layer, and a charge-generation layer) included in the EL layer can be formed by a method such as an evaporation method (e.g., a vacuum evaporation method), a coating method (e.g., a dip coating method, a die coating method, a bar coating method, a spin coating method, or a spray coating method), or a printing method (e.g., an inkjet method, a screen printing (stencil) method, an offset printing (planography) method, a flexography (relief printing) method, a gravure method, or a micro-contact printing method).

In the method described below for manufacturing the display device, the island-shaped layer (the layer including the light-emitting layer) is formed not by using a fine metal mask but by forming a light-emitting layer on the entire surface and then processing the light-emitting layer by a photolithography method. Accordingly, a high-definition display device or a display device with a high aperture ratio, which has been difficult to achieve, can be manufactured. Moreover, light-emitting layers can be formed separately for the respective colors, enabling the display device to perform extremely clear display with high contrast and high display quality. In addition, a sacrificial layer provided over a light-emitting layer can reduce damage to the light-emitting layer in the manufacturing process of the display device, increasing the reliability of the light-emitting element.

For example, in the case where the display device includes three kinds of light-emitting elements, which are a light-emitting element that emits blue light, a light-emitting element that emits green light, and a light-emitting element that emits red light, three kinds of island-shaped light-emitting layers can be formed by repeating formation of a light-emitting layer and processing by photolithography three times.

First, the pixel electrodes 111R, 111G, and 111B and the conductive layer 123 are formed over the substrate 151 provided with the transistors 205R, 205G, and 205B and the like (not illustrated) (FIG. 60A).

A conductive film to be the pixel electrodes can be formed by a sputtering method or a vacuum evaporation method, for example. A resist mask is formed over the conductive film by a photolithography process, and then the conductive film is processed, whereby the pixel electrodes 111R, 111G, and 111B and the conductive layer 123 can be formed. For the processing of the conductive film, one or both of a wet etching method and a dry etching method can be used.

Next, a film 133Bf to be the layer 133B later is formed over the pixel electrodes 111R, 111G, and 111B (FIG. 60A). The film 133Bf (to be the layer 133B later) includes a light-emitting layer that emits blue light.

Note that in an example described in this embodiment, an island-shaped EL layer included in the light-emitting element that emits blue light is formed first, and then island-shaped EL layers included in the light-emitting elements that emit light of the other colors are formed.

In the formation process of the island-shaped EL layers, the pixel electrode of the light-emitting element of the color formed second or later is sometimes damaged by the preceding step. In this case, the driving voltage of the light-emitting element of the color formed second or later might be high.

In view of this, in manufacture of the display device of one embodiment of the present invention, it is preferable that an island-shaped EL layer of a light-emitting element that emits light with the shortest wavelength (e.g., the blue-light-emitting element) be formed first. For example, it is preferable that island-shaped EL layers be formed in the order of blue, green, and red or in the order of blue, red, and green.

This enables the blue-light-emitting element to keep the favorable state of the interface between the pixel electrode and the EL layer, thereby inhibiting an increase in the driving voltage of the blue-light-emitting element. Furthermore, the lifetime of the blue-light-emitting element can be prolonged and the reliability can be increased. Note that the red-light-emitting element and the green-light-emitting element have a smaller increase in driving voltage or the like than the blue-light-emitting element, resulting in a lower driving voltage and higher reliability of the whole display device.

Note that the formation order of the island-shaped EL layers is not limited to the above; for example, the island-shaped EL layers may be formed in the order of red, green, and blue.

As illustrated in FIG. 60A, the film 133Bf is not formed over the conductive layer 123. For example, by using an area mask, the film 133Bf can be formed only in a desired region. Employing a film formation step using an area mask and a processing step using a resist mask enables a light-emitting element to be manufactured by a relatively easy process.

The upper temperature limit of each compound contained in the film 133Bf is preferably higher than or equal to 100° C. and lower than or equal to 180° C., further preferably higher than or equal to 120° C. and lower than or equal to 180° C., still further preferably higher than or equal to 140° C. and lower than or equal to 180° C. Thus, the reliability of the light-emitting element can be increased. In addition, the upper limit of the temperature that can be applied in the manufacturing process of the display device can be increased. Thus, the range of choices of the materials and the formation method of the display device can be widened, thereby improving the yield and the reliability.

The upper temperature limit, for example, can be any of the glass transition point, the softening point, the melting point, the thermal decomposition temperature, and the 5% weight loss temperature, preferably the lowest temperature thereof.

The film 133Bf can be formed by an evaporation method, specifically a vacuum evaporation method, for example. Alternatively, the film 133Bf may be formed by a transfer method, a printing method, an inkjet method, a coating method, or the like.

Next, a sacrificial layer 118B is formed over the film 133Bf and the conductive layer 123 (FIG. 60A). A resist mask is formed over a film to be the sacrificial layer 118B by a photolithography process, and then the film is processed, whereby the sacrificial layer 118B can be formed.

The sacrificial layer 118B provided over the film 133Bf can reduce damage to the film 133Bf in the manufacturing process of the display device, increasing the reliability of the light-emitting element.

The sacrificial layer 118B is preferably provided to cover the end portions of the pixel electrodes 111R, 111G, and 111B. Accordingly, an end portion of the layer 133B formed in a later step is positioned outward from the end portion of the pixel electrode 111B. The entire top surface of the pixel electrode 111B can be used as a light-emitting region, so that the aperture ratio of the pixel can be increased. The end portion of the layer 133B might be damaged in a step after the formation of the layer 133B, and thus is preferably positioned outward from the end portion of the pixel electrode 111B, i.e., not used as the light-emitting region. This can inhibit a variation in the characteristics of the light-emitting elements and can improve reliability.

When the layer 133B covers the top surface and the side surface of the pixel electrode 111B, the steps after the formation of the layer 133B can be performed in a state where the pixel electrode 111B is not exposed. When the end portion of the pixel electrode 111B is exposed, corrosion might occur in the etching step or the like. When corrosion of the pixel electrode 111B is inhibited, the yield and characteristics of the light-emitting element can be improved.

The sacrificial layer 118B is preferably provided also at a position overlapping with the conductive layer 123. This can inhibit the conductive layer 123 from being damaged during the manufacturing process of the display device.

As the sacrificial layer 118B, a film that is highly resistant to the process conditions for the film 133Bf, specifically, a film having high etching selectivity with the film 133Bf is used.

The sacrificial layer 118B is formed at a temperature lower than the upper temperature limit of each compound contained in the film 133Bf. The typical substrate temperature in the formation of the sacrificial layer 118B is lower than or equal to 200° C., preferably lower than or equal to 150° C., further preferably lower than or equal to 120° C., still further preferably lower than or equal to 100° C., yet still further preferably lower than or equal to 80° C.

The upper temperature limit of the compound contained in the film 133Bf is preferably high, in which case the film formation temperature of the sacrificial layer 118B can be high. For example, the substrate temperature in formation of the sacrificial layer 118B can be higher than or equal to 100° C., higher than or equal to 120° C., or higher than or equal to 140° C. An inorganic insulating film can have higher density and a higher barrier property as the formation temperature becomes higher. Thus, forming the sacrificial layer at such a temperature can further reduce damage to the film 133Bf and improve the reliability of the light-emitting element.

Note that the same applies to the film formation temperature of another layer formed over the film 133Bf (e.g., an insulating film 125f).

The sacrificial layer 118B can be formed by a sputtering method, an ALD method (including a thermal ALD method and a PEALD method), a CVD method, or a vacuum evaporation method, for example. Alternatively, the aforementioned wet film formation method may be used for the formation.

The sacrificial layer 118B (or a layer that is in contact with the film 133Bf in the case where the sacrificial layer 118B has a stacked-layer structure) is preferably formed by a formation method that causes less damage to the film 133Bf. For example, the sacrificial layer 118B is preferably formed by an ALD method or a vacuum evaporation method rather than a sputtering method.

The sacrificial layer 118B can be processed by a wet etching method or a dry etching method. The sacrificial layer 118B is preferably processed by anisotropic etching.

The use of a wet etching method can reduce damage to the film 133Bf in processing of the sacrificial layer 118B, as compared with the case of using a dry etching method. In the case of using a wet etching method, it is preferable to use a developer, a tetramethylammonium hydroxide (TMAH) aqueous solution, dilute hydrofluoric acid, oxalic acid, phosphoric acid, acetic acid, nitric acid, or a mixed solution containing two or more of these acids, for example. In the case of using a wet etching method, a mixed acid chemical solution containing water, phosphoric acid, diluted hydrofluoric acid, and nitric acid may be used. A chemical solution used for the wet etching treatment may be alkaline or acid.

As the sacrificial layer 118B, one or more kinds of a metal film, an alloy film, a metal oxide film, a semiconductor film, an inorganic insulating film, and an organic insulating film can be used, for example.

For the sacrificial layer 118B, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example.

For the sacrificial layer 118B, it is possible to use a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In addition, in place of gallium described above, an element M (M is one or more kinds selected from of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

For example, a semiconductor material such as silicon or germanium can be used as a material with a high affinity for the semiconductor manufacturing process. Alternatively, an oxide or a nitride of the semiconductor material can be used. Alternatively, a nonmetallic material such as carbon or a compound thereof can be used. Alternatively, a metal, such as titanium, tantalum, tungsten, chromium, or aluminum, or an alloy containing one or more of them can be given. Alternatively, an oxide containing the above-described metal, such as titanium oxide or chromium oxide, or a nitride such as titanium nitride, chromium nitride, or tantalum nitride can be used.

As the sacrificial layer 118B, a variety of inorganic insulating films that can be used as the protective layer 131 can be used. In particular, an insulating film containing an oxide is preferable because its adhesion to the film 133Bf is higher than that of an insulating film containing a nitride. For example, an inorganic insulating material such as aluminum oxide, hafnium oxide, or silicon oxide can be used for the sacrificial layer 118B. As the sacrificial layer 118B, an aluminum oxide film can be formed by an ALD method, for example. The use of an ALD method is preferable because damage to a base (in particular, the film 133Bf) can be reduced.

For example, a stacked-layer structure of an inorganic insulating film (e.g., an aluminum oxide film) formed by an ALD method and an inorganic film (e.g., an In—Ga—Zn oxide film, a silicon film, or a tungsten film) formed by a sputtering method can be employed for the sacrificial layer 118B.

Note that the same inorganic insulating film can be used for both the sacrificial layer 118B and the insulating layer 125 to be formed later. For example, an aluminum oxide film formed by an ALD method can be used for both the sacrificial layer 118B and the insulating layer 125. Here, for the sacrificial layer 118B and the insulating layer 125, the same film formation condition may be used or different film formation conditions may be used. For example, when the sacrificial layer 118B is formed under conditions similar to those of the insulating layer 125, the sacrificial layer 118B can be an insulating layer having a high barrier property against at least one of water and oxygen. Meanwhile, the sacrificial layer 118B is a layer most or all of which is to be removed in a later step, and thus is preferably easy to process. Thus, the sacrificial layer 118B is preferably formed with a substrate temperature lower than that for formation of the insulating layer 125.

An organic material may be used for the sacrificial layer 118B. For example, as the organic material, a material that can be dissolved in a solvent chemically stable with respect to at least the uppermost film of the film 133Bf may be used. Specifically, a material that is dissolved in water or alcohol can be suitably used. In forming a film of such a material, it is preferable to apply the material dissolved in a solvent such as water or alcohol by a wet film formation method and then perform heat treatment for evaporating the solvent. At this time, the heat treatment is preferably performed under a reduced-pressure atmosphere, in which case the solvent can be removed at a low temperature in a short time and thermal damage to the film 133Bf can be accordingly reduced.

For the sacrificial layer 118B, an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluororesin like perfluoropolymer may be used.

For example, a stacked-layer structure of an organic film (e.g., a PVA film) formed by an evaporation method or the above wet film formation method and an inorganic film (e.g., a silicon nitride film) formed by a sputtering method can be employed for the sacrificial layer 118B.

Note that in the display device of one embodiment of the present invention, part of the sacrificial film remains as the sacrificial layer in some cases.

Then, the film 133Bf is processed using the sacrificial layer 118B as a hard mask, so that the layer 133B is formed (FIG. 60B).

Accordingly, as illustrated in FIG. 60B, the stacked-layer structure of the layer 133B and the sacrificial layer 118B remains over the pixel electrode 111B. In addition, the pixel electrode 111R and the pixel electrode 111G are exposed. In a region corresponding to the connection portion 140, the sacrificial layer 118B remains over the conductive layer 123.

The film 133Bf is preferably processed by anisotropic etching. Anisotropic dry etching is particularly preferable. Alternatively, wet etching may be employed.

After that, steps similar to the formation step of the film 133Bf, the formation step of the sacrificial layer 118B, and the formation step of the layer 133B are repeated twice under the condition where at least light-emitting substances are changed, whereby a stacked-layer structure of the layer 133R and a sacrificial layer 118R is formed over the pixel electrode 111R and a stacked-layer structure of the layer 133G and a sacrificial layer 118G is formed over the pixel electrode 111G (FIG. 60C). Specifically, the layer 133R is formed to include a light-emitting layer that emits red light, and the layer 133G is formed to include a light-emitting layer that emits green light. The sacrificial layers 118R and 118G can be formed using a material that can be used for the sacrificial layer 118B, and the sacrificial layers 118R and 118G may be formed using the same material or different materials.

Note that the side surfaces of the layer 133B, the layer 133G, and the layer 133R are preferably perpendicular or substantially perpendicular to their formation surfaces. For example, the angle between the formation surfaces and these side surfaces is preferably greater than or equal to 60° and less than or equal to 90°.

As described above, the distance between two adjacent layers among the layer 133B, the layer 133G, and the layer 133R formed by a photolithography method can be shortened to less than or equal to 8 μm, less than or equal to 5 μm, less than or equal to 3 μm, less than or equal to 2 μm, or less than or equal to 1 μm. Here, the distance can be determined by, for example, the distance between opposite end portions of two adjacent layers among the layer 133B, the layer 133G, and the layer 133R. When the distance between the island-shaped EL layers is shortened in this manner, a display device with a high definition and a high aperture ratio can be provided.

Next, the insulating film 125f to be the insulating layer 125 later is formed to cover the pixel electrodes, the layer 133B, the layer 133G, the layer 133R, the sacrificial layer 118B, the sacrificial layer 118G, and the sacrificial layer 118R, and then the insulating layer 127 is formed over the insulating film 125f (FIG. 60D).

As the insulating film 125f, an insulating film is preferably formed to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The insulating film 125f is preferably formed by an ALD method, for example. An ALD method is preferably used, in which case damage due to the film formation can be reduced and a film with high coverage can be formed. As the insulating film 125f, an aluminum oxide film is preferably formed by an ALD method, for example.

Alternatively, the insulating film 125f may be formed by a sputtering method, a CVD method, or a PECVD method that provides a higher film formation speed than an ALD method. In this case, a highly reliable display device can be manufactured with high productivity.

For example, an insulating film to be the insulating layer 127 is preferably formed by the aforementioned wet film formation method (e.g., spin coating) using a photosensitive resin composite containing an acrylic resin. After the formation, heat treatment (also referred to as pre-baking) is preferably performed to eliminate a solvent contained in the insulating film. Next, part of the insulating film is irradiated with visible light or ultraviolet rays, so that the insulating film is partly exposed to light. Subsequently, the region of the insulating film exposed to light is removed by development. After that, heat treatment (also referred to as post-baking) is performed. Accordingly, the insulating layer 127 illustrated in FIG. 60D can be formed. Note that the shape of the insulating layer 127 is not limited to the shape illustrated in FIG. 60D. For example, the top surface of the insulating layer 127 can include one or more of a convex surface, a concave surface, and a flat surface. The insulating layer 127 may cover the side surface of an end portion of at least one of the insulating layer 125, the sacrificial layer 118B, the sacrificial layer 118G, and the sacrificial layer 118R.

Next, as illustrated in FIG. 60E, etching treatment is performed using the insulating layer 127 as a mask to remove the insulating film 125f and parts of the sacrificial layers 118B, 118G, and 118R. Consequently, openings are formed in the sacrificial layers 118B, 118G, and 118R, and the top surfaces of the layer 133B, the layer 133G, the layer 133R, and the conductive layer 123 are exposed. Note that parts of the sacrificial layers 118B, 118G, and 118R may remain in positions overlapping with the insulating layer 127 and the insulating layer 125 (see sacrificial layers 119B, 119G, and 119R).

The etching treatment can be performed by dry etching or wet etching. Note that the insulating film 125f is preferably formed using a material similar to that for the sacrificial layers 118B, 118G, and 118R, in which case etching treatment can be performed collectively.

As described above, providing the insulating layer 127, the insulating layer 125, the sacrificial layer 118B, the sacrificial layer 118G, and the sacrificial layer 118R can inhibit the common layer 114 and the common electrode 115 between the light-emitting elements from having connection defects due to a disconnected portion and an increase in electric resistance due to a locally thinned portion. Thus, the display quality of the display device of one embodiment of the present invention can be improved.

Next, the common layer 114 and the common electrode 115 are formed in this order over the insulating layer 127, the layer 133B, the layer 133G, and the layer 133R (FIG. 60F).

The common layer 114 can be formed by a method such as an evaporation method (including a vacuum evaporation method), a transfer method, a printing method, an inkjet method, or a coating method.

The common electrode 115 can be formed by a sputtering method or a vacuum evaporation method, for example. Alternatively, a film formed by an evaporation method and a film formed by a sputtering method may be stacked.

As described above, in the method for manufacturing the display device of one embodiment of the present invention, the island-shaped layer 133B, the island-shaped layer 133G, and the island-shaped layer 133R are formed not by using a fine metal mask but by forming a film over the entire surface and processing the film; thus, the island-shaped layers can be formed to have a uniform thickness. Consequently, a high-definition display device or a display device with a high aperture ratio can be obtained. Furthermore, even when the definition or the aperture ratio is high and the distance between the subpixels is extremely short, the layer 133B, the layer 133G, and the layer 133R can be inhibited from being in contact with each other in the adjacent subpixels. Accordingly, generation of a leakage current between the subpixels can be inhibited. This can prevent unintended light emission due to crosstalk, so that a display device with extremely high contrast can be obtained.

Provision of the insulating layer 127 having a tapered end portion between adjacent island-shaped EL layers can inhibit formation of step disconnection and prevent formation of a locally thinned portion in the common electrode 115 at the time of forming the common electrode 115. This can inhibit the common layer 114 and the common electrode 115 from having connection defects due to the disconnected portion and an increased electric resistance due to the locally thinned portion. Thus, the display device of one embodiment of the present invention can have both a higher definition and higher display quality.

This embodiment can be combined with the other embodiments as appropriate.

### Embodiment 4

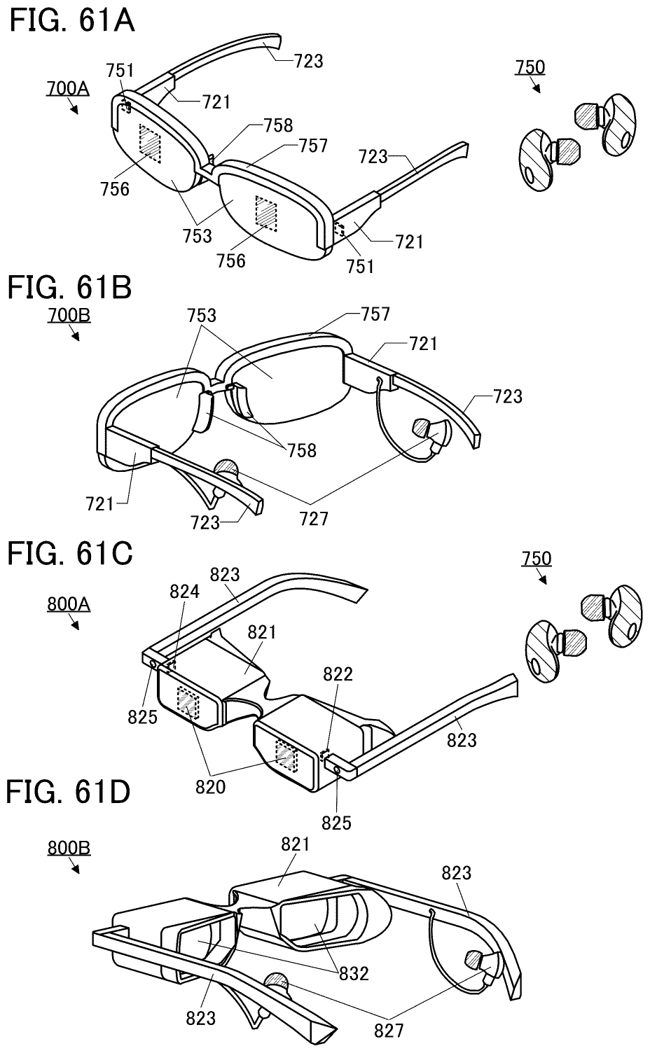

In this embodiment, electronic devices of one embodiment of the present invention will be described with reference to FIG. 61 to FIG. 63.

Electronic devices of this embodiment each include the display device of one embodiment of the present invention in a display portion. The display device of one embodiment of the present invention can be easily increased in definition and resolution. Thus, the display device of one embodiment of the present invention can be used for a display portion of a variety of electronic devices.

The semiconductor device of one embodiment of the present invention can also be applied to any other portion of an electronic device than a display portion. For example, the semiconductor device of one embodiment of the present invention is preferably used for a control portion or the like of an electronic device because lower power consumption can be achieved.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or laptop personal computer, a monitor of a computer or the like, digital signage, and a large game machine such as a pachinko machine.

In particular, the display device of one embodiment of the present invention can have high definition, and thus can be suitably used for an electronic device including a relatively small display portion. Examples of such an electronic device include watch-type and bracelet-type information terminals (wearable devices) and wearable devices capable of being worn on a head, such as a VR device like a head-mounted display, a glasses-type AR device, and an MR device.

The resolution of the display device of one embodiment of the present invention is preferably as high as HD (number of pixels: 1280× 720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the resolution is preferably 4K, 8K, or higher. The pixel density (definition) of the display device of one embodiment of the present invention is preferably higher than or equal to 100 ppi, further preferably higher than or equal to 300 ppi, further preferably higher than or equal to 500 ppi, further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. The use of the display device having one or both of such high resolution and high definition can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device of this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device of this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data recorded in a recording medium.

Examples of a wearable device capable of being worn on a head are described with reference to FIG. 61A to FIG. 61D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables a user to feel a higher sense of immersion.

An electronic device 700A illustrated in FIG. 61A and an electronic device 700B illustrated in FIG. 61B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758. Note that the display panels 751 are omitted in FIG. 61B.

The display device of one embodiment of the present invention can be used for the display panels 751. Thus, the electronic device can perform display with extremely high definition.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In each of the electronic device 700A and the electronic device 700B, a camera capable of capturing images of the front side may be provided as the image capturing portion. Furthermore, when the electronic device 700A and the electronic device 700B are each provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Note that instead of the wireless communication device or in addition to the wireless communication device, a connector to which a cable for supplying a video signal and a power supply potential can be connected may be provided.

The electronic device 700A and the electronic device 700B are each provided with a battery (not illustrated) so that they can be charged wirelessly and/or by wire.

A touch sensor module may be provided in the housing 721. The touch sensor module has a function of detecting touch on the outer surface of the housing 721. A tap operation, a slide operation, or the like by the user can be detected with the touch sensor module, whereby a variety of processing can be executed. For example, processing such as a pause or a restart of a moving image can be executed by a tap operation, and processing such as fast forward or fast rewind can be executed by a slide operation. The touch sensor module is provided in each of the two housings 721, whereby the range of the operation can be increased.

A variety of touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 61C and an electronic device 800B illustrated in FIG. 61D each include a pair of display portions 820, a housing 821, a communication portion 822, a pair of wearing portions 823, a control portion 824, a pair of image capturing portions 825, and a pair of lenses 832. Note that the display portions 820, the communication portion 822, and the image capturing portions 825 are omitted in FIG. 61D. The display device of one embodiment of the present invention can be used for the display portions 820. Thus, the electronic device can perform display with extremely high definition. This enables a user to feel high sense of immersion.

The display portions 820 are provided at a position inside the housing 821 so as to be seen through the lenses 832. When the pair of display portions 820 display different images, three-dimensional display using parallax can be performed.

The electronic device 800A and the electronic device 800B can be regarded as VR electronic devices. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B each preferably include a mechanism for adjusting focus by changing the distance between the lenses 832 and the display portions 820.

The electronic device 800A or the electronic device 800B can be worn on the user's head with the wearing portions 823. FIG. 61C and the like show examples in which the wearing portion has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided to cover a plurality of fields of view, such as a telescope field of view and a wide field of view.

Although an example of including the image capturing portion 825 is described here, a range sensor (hereinafter also referred to as a sensing portion) that is capable of measuring a distance from an object is provided. That is, the image capturing portion 825 is one embodiment of the sensing portion. As the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be employed for any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 61A has a function of transmitting information to the earphones 750 with the wireless communication function. As another example, the electronic device 800A illustrated in FIG. 61C has a function of transmitting information to the earphones 750 with the wireless communication function.

The electronic device may include an earphone portion. The electronic device 700B illustrated in FIG. 61B includes earphone portions 727. For example, the earphone portion 727 and the control portion can be connected to each other by wire. Part of a wiring that connects the earphone portion 727 and the control portion may be positioned inside the housing 721 or the wearing portion 723.

Similarly, the electronic device 800B illustrated in FIG. 61D includes earphone portions 827. For example, the earphone portion 827 and the control portion 824 can be connected to each other by wire. Part of a wiring that connects the earphone portion 827 and the control portion 824 may be positioned inside the housing 821 or the wearing portion 823. The earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

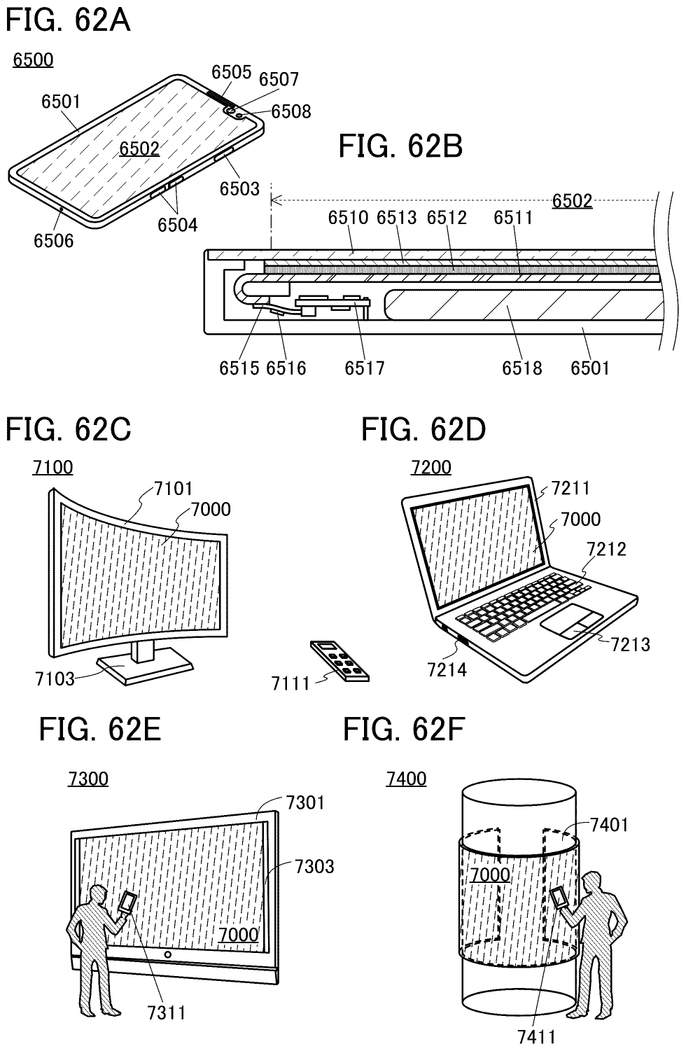

An electronic device 6500 illustrated in FIG. 62A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used for the display portion 6502.

FIG. 62B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted while an increase in thickness of the electronic device is reduced. Moreover, part of the display panel 6511 is folded back so that a connection portion with the FPC 6515 is provided on the back side of a pixel portion, whereby an electronic device with a narrow bezel can be achieved.

FIG. 62C shows an example of a television device. In a television device 7100, a display portion 7000 is incorporated in a housing 7101. Here, a structure in which the housing 7101 is supported by a stand 7103 is illustrated.

The display device of one embodiment of the present invention can be used for the display portion 7000.

Operation of the television device 7100 illustrated in FIG. 62C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and videos displayed on the display portion 7000 can be controlled.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 62D shows an example of a laptop personal computer. A laptop personal computer 7200 includes a housing 7211, a keyboard 7212, a pointing device 7213, an external connection port 7214, and the like. In the housing 7211, the display portion 7000 is incorporated.

The display device of one embodiment of the present invention can be used for the display portion 7000.

FIG. 62E and FIG. 62F show examples of digital signage.

Digital signage 7300 illustrated in FIG. 62E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 62F is digital signage 7400 attached to a cylindrical pillar 7401. The digital signage 7400 includes the display portion 7000 provided along a curved surface of the pillar 7401.

The display device of one embodiment of the present invention can be used for the display portion 7000 in FIG. 62E and FIG. 62F.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 62E and FIG. 62F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operating the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

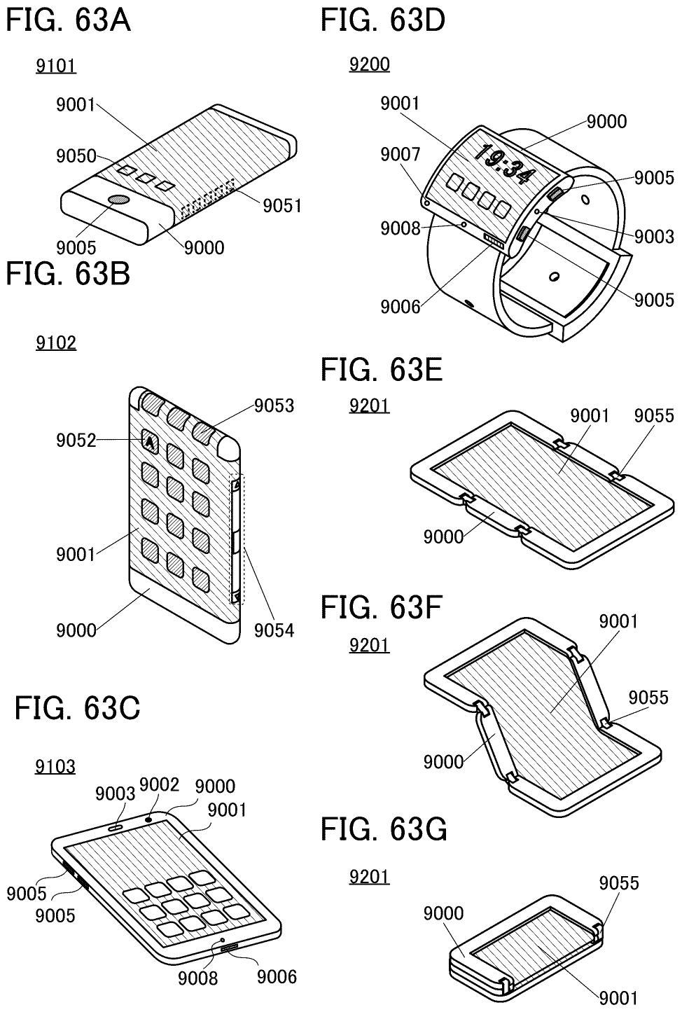

Electronic devices illustrated in FIG. 63A to FIG. 63G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The display device of one embodiment of the present invention can be used for the display portion 9001 in FIG. 63A to FIG. 63G.

The electronic devices illustrated in FIG. 63A to FIG. 63G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data recorded in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image and storing the taken image in a recording medium (an external recording medium or a recording medium incorporated in the camera), a function of displaying the taken image on the display portion, or the like.

The electronic devices illustrated in FIG. 63A to FIG. 63G are described in detail below.

FIG. 63A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display characters and image information on its plurality of surfaces. FIG. 63A shows an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 63B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is shown. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 63C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the side surface of the housing 9000; and the connection terminal 9006 on the bottom surface of the housing 9000.

FIG. 63D is a perspective view illustrating a watch-type portable information terminal 9200. For example, the portable information terminal 9200 can be used as a Smartwatch (registered trademark). The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 63E to FIG. 63G are perspective views illustrating a foldable portable information terminal 9201. FIG. 63E is a perspective view of an opened state of the portable information terminal 9201, FIG. 63G is a perspective view of a folded state thereof, and FIG. 63F is a perspective view of a state in the middle of change from one of FIG. 63E and FIG. 63G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate.

[Reference Numerals]

10A: semiconductor device, 10B: semiconductor device, 10C: semiconductor device, 10D:
semiconductor device, 10E: semiconductor device, 10F: semiconductor device, 10G:
semiconductor device, 10H: semiconductor device, 10I: semiconductor device, 10: semiconductor
device, 11B: subpixel, 11G: subpixel, 11R: subpixel, 20A: semiconductor device, 20B:
semiconductor device, 20C: semiconductor device, 20D: semiconductor device, 20E:
semiconductor device, 20F: semiconductor device, 20: semiconductor device, 30: semiconductor
device, 50A: display device, 50B: display device, 50C: display device, 50D: display device, 50E:
display device, 50F: display device, 50G: display device, 50H: display device, 50I: display device,
50J: display device, 50K: display device, 60: liquid crystal element, 100_1: transistor, 100_2:
transistor, 100_3: transistor, 100_4: transistor, 100_r: transistor, 100A: transistor, 100a: transistor,
100B: transistor, 100b: transistor, 100C: transistor, 100c: transistor, 100D: transistor, 100F:
transistor, 100H: transistor, 100: transistor, 102: substrate, 103: conductive layer, 104a:
conductive layer, 104b: conductive layer, 104c: conductive layer, 104: conductive layer, 106a:
insulating layer, 106b: insulating layer, 106: insulating layer, 107: insulating layer, 108a:: layer,
108b:: layer, 108c:: layer, 108C: region, 108C_1: region, 108C_2: region, 108C_3: region,
108C_4: region, 108Ca: region, 108f: metal oxide film, 108P: region, 108P_1: region, 108P_2:
region, 108P_3: region, 108Pa: region, 108Q: region, 108Q_1: region, 108Q_2: region, 108Qa:
region, 108:: layer, 109: insulating layer, 110a: insulating layer, 110af: insulating film, 110b:
insulating layer, 110bf: insulating film, 110c: insulating layer, 110d: insulating layer, 110:
insulating layer, 111B: pixel electrode, 111G: pixel electrode, 111R: pixel electrode, 111S: pixel
electrode, 113B: EL layer, 113G: EL layer, 113R: EL layer, 113S: functional layer, 113: EL layer,
114: common layer, 115: common electrode, 117: light-blocking layer, 118B: sacrificial layer,
118G: sacrificial layer, 118R: sacrificial layer, 119B: sacrificial layer, 119G: sacrificial layer, 123:
conductive layer, 124B: conductive layer, 124G: conductive layer, 124R: conductive layer, 125f:
insulating film, 125: insulating layer, 126B: conductive layer, 126G: conductive layer, 126R:
conductive layer, 127: insulating layer, 128: layer, 130B: light-emitting element, 130G: light-
emitting element, 130R: light-emitting element, 130S: light-receiving element, 130: metal oxide
layer, 131: protective layer, 132B: coloring layer, 132G: coloring layer, 132R: coloring layer,
133B: layer, 133Bf: film, 133G: layer, 133R: layer, 133: layer, 139: film, 140: connection portion,
142: adhesive layer, 144: adhesive layer, 151: substrate, 152: substrate, 153: insulating layer, 162:
display portion, 164: circuit portion, 165: conductive layer, 166: conductive layer, 172: FPC, 173:
IC, 177: groove, 179: opening, 182A: conductive layer, 182Aa: conductive layer, 182Ab:
conductive layer, 182Ac: conductive layer, 182B: conductive layer, 182Ba: conductive layer,
182Bb: conductive layer, 182Bc: conductive layer, 187A: opening, 187Aa: opening, 187Ab:
opening, 187Ac: opening, 187B: opening, 187Ba: opening, 187Bb: opening, 187Bc: opening, 189:
opening, 190: capacitor, 191: conductive layer, 195: insulating layer, 197: connection portion,
201: pixel, 205B: transistor, 205D: transistor, 205G: transistor, 205R: transistor, 205S: transistor,
218: insulating layer, 223: connector, 224: spacer, 225: insulating layer, 235: insulating layer, 237:
insulating layer, 242: connection layer, 260a: polarizing plate, 260b: polarizing plate, 261:
insulating layer, 262: liquid crystal, 263: conductive layer, 264: conductive layer, 265: alignment
film, 352: finger, 353: layer, 355: circuit layer, 357: layer, 700A: electronic device, 700B:
electronic device, 721: housing, 723: wearing portion, 727: earphone portion, 750: earphone, 751:
display panel, 753: optical member, 756: display region, 757: frame, 758: nose pad, 800A:
electronic device, 800B: electronic device, 820: display portion, 821: housing, 822:
communication portion, 823: wearing portion, 824: control portion, 825: image capturing portion,
827: earphone portion, 832: lens, 6500: electronic device, 6501: housing, 6502: display portion,
6503: power button, 6504: button, 6505: speaker, 6506: microphone, 6507: camera, 6508: light
source, 6510: protection member, 6511: display panel, 6512: optical member, 6513: touch sensor
panel, 6515: FPC, 6516: IC, 6517: printed circuit board, 6518: battery, 7000: display portion,
7100: television device, 7101: housing, 7103: stand, 7111: remote control, 7200: laptop personal
computer, 7211: housing, 7212: keyboard, 7213: pointing device, 7214: external connection port,
7300: digital signage, 7301: housing, 7303: speaker, 7311: information terminal, 7400: digital
signage, 7401: pillar, 7411: information terminal, 9000: housing, 9001: display portion, 9002:
camera, 9003: speaker, 9005: operation key, 9006: connection terminal, 9007: sensor, 9008:
microphone, 9050: icon, 9051: information, 9052: information, 9053: information, 9054:
information, 9055: hinge, 9101: portable information terminal, 9102: portable information
terminal, 9103: tablet terminal, 9200: portable information terminal, 9201: portable information
terminal

1. A semiconductor device comprising:
a first insulating layer;
a second insulating layer over the first insulating layer; and
a first transistor comprising:
a metal oxide layer in contact with a top surface of the first insulating layer and a top surface and a side surface of the second insulating layer;
a third insulating layer over the metal oxide layer; and
a first conductive layer overlapping with the side surface of the second insulating layer with the metal oxide layer and the third insulating layer therebetween,
wherein the second insulating layer comprises a fourth insulating layer and a fifth insulating layer over the fourth insulating layer,
wherein the metal oxide layer is in contact with a side surface of the fourth insulating layer and a top surface and a side surface of the fifth insulating layer,
wherein the first insulating layer and the fifth insulating layer each comprise nitrogen, and
wherein the fourth insulating layer comprises oxygen.

2. The semiconductor device according to claim 1, further comprising a second transistor,
wherein the second transistor comprises the metal oxide layer, the third insulating layer, and a second conductive layer,
wherein the first conductive layer and the second conductive layer overlap with a first region and a second region, respectively, of the side surface of the second insulating layer with the third insulating layer and the metal oxide layer therebetween,
wherein the first transistor and the second transistor share a region of the metal oxide layer, and
wherein the region is in contact with the top surface of the first insulating layer.

3. The semiconductor device according to claim 1, further comprising a second transistor,
wherein the second transistor comprises the metal oxide layer, the third insulating layer, and a second conductive layer,
wherein the first conductive layer and the second conductive layer overlap with a first region and a second region, respectively, of the side surface of the second insulating layer with the third insulating layer and the metal oxide layer therebetween,
wherein the first transistor and the second transistor share a region of the metal oxide layer, and
wherein the region is in contact with the top surface of the fifth insulating layer.

4. The semiconductor device according to claim 1, further comprising a capacitor,
wherein the capacitor comprises the metal oxide layer, the third insulating layer, and a third conductive layer over the third insulating layer,
wherein the third conductive layer overlaps with a region of the metal oxide layer, and
wherein the region is in contact with the top surface of the first insulating layer.

5. The semiconductor device according to claim 1, further comprising a capacitor,
wherein the capacitor comprises the metal oxide layer, the third insulating layer, and a third conductive layer over the third insulating layer,
wherein the third conductive layer overlaps with a region of the metal oxide layer, and
wherein the region is in contact with the top surface of the fifth insulating layer.

6. The semiconductor device according to claim 1,
wherein the second insulating layer comprises a sixth insulating layer,
wherein the sixth insulating layer is between the first insulating layer and the fourth insulating layer,
wherein the sixth insulating layer comprises nitrogen, and
wherein the first insulating layer comprises a region having a higher hydrogen concentration than a region of the sixth insulating layer.

7. The semiconductor device according to claim 1,
wherein the second insulating layer comprises a seventh insulating layer,
wherein the seventh insulating layer is between the fourth insulating layer and the fifth insulating layer,
wherein the seventh insulating layer comprises nitrogen, and
wherein the fifth insulating layer comprises a region having a higher hydrogen concentration than a region of the seventh insulating layer.

8. The semiconductor device according to claim 1,
wherein the third insulating layer comprises aluminum oxide or silicon nitride.

9. A semiconductor device comprising:
a first insulating layer;
a second insulating layer over the first insulating layer;
a first transistor comprising:
a metal oxide layer in contact with a top surface of the first insulating layer and a top surface and a side surface of the second insulating layer;
a third insulating layer over the metal oxide layer; and
a first conductive layer overlapping with the side surface of the second insulating layer with the metal oxide layer and the third insulating layer therebetween;
a protective layer over the first conductive layer;
a first wiring electrically connected to a first region of the metal oxide layer through a first opening of the protective layer,
wherein the first conductive layer serves as a gate electrode of the first transistor,
wherein the first region of the metal oxide layer serves as one of a source electrode and a drain electrode of the first transistor,
wherein the second insulating layer comprises a fourth insulating layer and a fifth insulating layer over the fourth insulating layer,
wherein the metal oxide layer is in contact with a side surface of the fourth insulating layer and a top surface and a side surface of the fifth insulating layer,
wherein the first insulating layer and the fifth insulating layer each comprise nitrogen, and
wherein the fourth insulating layer comprises oxygen.

10. The semiconductor device according to claim 9, further comprising a second wiring electrically connected to a second region of the metal oxide layer through a second opening of the protective layer,
wherein the second region of the metal oxide layer serves as the other of the source electrode and the drain electrode of the first transistor.

11. The semiconductor device according to claim 9,
wherein the second insulating layer comprises a sixth insulating layer,
wherein the sixth insulating layer is between the first insulating layer and the fourth insulating layer,
wherein the sixth insulating layer comprises nitrogen, and
wherein the first insulating layer comprises a region having a higher hydrogen concentration than a region of the sixth insulating layer.

12. The semiconductor device according to claim 9,
wherein the second insulating layer comprises a seventh insulating layer,
wherein the seventh insulating layer is between the fourth insulating layer and the fifth insulating layer,
wherein the seventh insulating layer comprises nitrogen, and
wherein the fifth insulating layer comprises a region having a higher hydrogen concentration than a region of the seventh insulating layer.

13. The semiconductor device according to claim 9,
wherein the third insulating layer comprises aluminum oxide or silicon nitride.
